(19) United States
(12) Patent Application Publication
(10) Pub. No.: US 2006/0159286 A1
(43) Pub. Date: Jul. 20, 2006

(54) Bessel array with non-empty null positions

(76) Inventors: Enrique M. Stiles, Imperial Beach, CA (US); Patrick M. Turnmire, Arroyo Seco, NM (US); Richard C. Calderwood, Portland, OR (US)

Correspondence Address: RICHARD C. CALDERWOOD, 2775 NW 126TH AVE, PORTLAND, OR, 97229-8381, US

(21) Appl. No.: 11/358,810

(22) Filed: Feb. 21, 2006

Related U.S. Application Data
(63) Continuation-in-part of application No. 11/220,935, filed on Sep. 6, 2005.
Application No. 11/220,935 is a continuation-in-part of application No. 10/896,215, filed on Jul. 20, 2004.

(51) Int. Cl. H04R 3/00; H04R 1/40; H03G 5/00

(52) U.S. Cl. 381/111; 381/117; 381/97; 381/98

(57) ABSTRACT

An e.g. 7-element Bessel Array in which the null or zero positions are occupied with sound producing means producing sound outside the Bessel functional frequency range, such as a higher frequency Bessel Array, a higher frequency MTM, or a port.

### RELATED APPLICATION

This application is a continuation-in-part of application 11/220,935 entitled “Improved Bessel Array” filed Sep. 6, 2005 by Enrique M. Stiles, Patrick M. Turnmire, and Richard C. Calderwood. That application was in turn a continuation-in-part of application 10/896,215 entitled “Single-Sided Bessel Array” filed Jun. 20, 2004 by Enrique M. Stiles. All are commonly assigned to STEP Technologies, Inc.

### BACKGROUND OF THE INVENTION

1. Technical Field of the Invention

This invention relates generally to transducers such as audio speakers, and more specifically to an array of transducers which operate as a Bessel array in higher frequencies and as a conventional array in lower frequencies, and to other such Bessel-related novel technologies.

2. Background Art

It is well known to organize two or more transducers together into a variety of array configurations. One popular configuration is the line array.

FIG. 1 illustrates a conventional line array system 10. A plurality of transducers 12 are arranged in a linear fashion. In some instances, the transducers may be substantially identical. Although five transducers are shown, line arrays may use any number of transducers. Commonly, the transducers are coupled to a single, common enclosure 14. The transducers are driven in phase by a common signal (as indicated by the “+1” indication at the input to each transducer) from an amplifier 16.

As compared to a single transducer, a line array composed of multiple units of that same transducer offers the advantage of increased maximum sound pressure (sometimes referred to as loudness or volume), due simply to there being more transducers moving air, and also offers the advantage of higher efficiency, due to mutual air coupling between the transducers leading to improved impedance matching. However, line arrays can suffer from undesirable effects, such as interference patterns, which are observed at off-axis listening positions. In this context, “off-axis” refers to positions which are removed in a direction parallel to the “line” of the line array; for example, in FIG. 1 the off-axis positions are up and down, rather than left and right of the line array. These effects result, in large measure, from the listener being at slightly different distances from each of the respective transducers, and sound from the closer transducers arriving sooner than sound from the farther transducers. The farther off-axis the listener moves, the greater the differences between the listener and each of the transducers. At various off-axis positions, some frequencies will be subject to constructive interference while other frequencies will be subject to destructive interference. At other off-axis positions, different sets of frequencies will be subject to constructive or destructive interference. In general, because high frequencies have shorter wavelengths than low frequencies, these off-axis effects are more pronounced in the higher frequencies and begin to significantly occur when the frequency is sufficiently high such that its wavelength is only twice as long as the spacing between adjacent transducers in the array. At this frequency, the output of two adjacent transducers will completely cancel each other out at an angle of 90 degrees off-axis, because the output of one will be exactly 180 degrees out of phase with the output of the other.

FIG. 2 is a graph that illustrates the performance of one example of a line array, with five transducers on 4 cm center-to-center spacing. The horizontal (X) axis is frequency, and the vertical (Y) axis is sound pressure. Sixteen response curves are plotted; the on-axis curve is shown as a solid line, and the dotted lines represent fifteen response curves measured at 2 degree increments off-axis. The line array exhibits very good performance, with 98 dB sound pressure and minimal interference effects below about 1 kHz. Above about 1 kHz, however, the line array begins to exhibit significant comb filter interference patterns.

U.S. Pat. No. 4,399,328 to Franssen teaches the known but little-used Bessell array of speakers, which was designed to address exactly this problem. Its principles will be explained with reference to FIGS. 2-4.

FIG. 3 illustrates a Bessel array 20 of transducers 12 coupled to an enclosure 14 and driven by an amplifier 16. Rather than simply being provided directly to each transducer, as in a line array, the audio signal from the amplifier is altered to be suitable for the Bessel array by a circuit 22. The amplifier may be a pre-amplifier, and the final power amplification may be performed between the Bessel circuit and the transducers through the use of multiple power amplifiers.

The advantage offered by a Bessel array is control of constructive and destructive interference patterns in listening positions which are off-axis in the direction of the line array—vertically in the example of FIG. 3. A Bessel array reduces this effect by powering the various speaker drivers with differently conditioned signals, rather than by merely splitting the same signal equally five ways. In the common five-driver Bessel array, the first driver 12-1 receives a half-strength, in-phase signal (referred to as “+½”); the second driver 12-2 receives a full-strength, inverted-phase signal (referred to as “−1”); the third and fourth drivers 12-3 and 12-4 each receives a full-strength, in-phase signal (“+1”); and the fifth driver 12-5 receives a half-strength, in-phase signal (“+½”).

One method of providing the “−1” signal is simply to reverse the connections at the +and − terminals of the second driver. One method of providing the “+½” signals is to connect the first and fifth drivers in series with each other, and that series combination in parallel with each of the other drivers, as taught by Franssen. In other embodiments, the Bessel circuit may be e.g. a digital logic device.

In some embodiments, a single amplifier's output is used to drive all of the transducers in the Bessel array. In other embodiments, each transducer may be driven by its own, dedicated amplifier; in such embodiments, each amplifier's output may be adjusted such that its output corresponds to the required Bessel coefficient for that particular driver. In that case, the amplifier settings themselves function as the Bessel circuit.

A Bessel array sacrifices maximum sound pressure and efficiency versus a line array configuration of the same drivers, to gain improved off-axis sound performance. In low frequencies, a five-driver Bessel array uses five speaker drivers to generate the same sound pressure level that would be generated by two speaker drivers in a conventional line array.

FIG. 4 is a graph illustrating the frequency response of a conventional 5-driver Bessel array with 4 cm center-to-center spacing, in 2 degree increments from 30 degrees below to 30 degrees above center. Comparing FIG. 4 to FIG. 2, it is readily seen that the Bessel array has significantly reduced off-axis interference patterns compared to the conventional line array. However, it is also readily seen that the Bessel array has significantly reduced sound pressure than the conventional line array using the same transducers, the same amplifier (although only being driven at ⅘ths relative output), and the same signal—the conventional line array offers roughly 98 dB on-axis, while the Bessel array offers only 90 dB, an 8 dB reduction in the sound pressure level.

Furthermore, it is also seen that the conventional Bessel array performs the same interference pattern reduction, and loss of sound pressure, across the entire frequency range, whereas the interference pattern is really only a problem in the higher frequencies. At lower frequencies, the wavelengths are sufficiently long to swamp the distance difference between the off-axis listener and the respective speaker drivers.

Franssen teaches Bessel arrays having five, seven, or nine driver positions, which may be referred to as 5-Element, 7-Element, and 9-Element Bessel Arrays. Franssen teaches driving these arrays with the following signals (after converting from Franssen's terminology to Applicant's):

| | 5-Element | 7-Element | 9-Element |
|---|---|---|---|
| Driver | Signal | Signal | Signal |
| 1 | +½ | +½ | +½ |
| 2 | +1 | +1 | +1 |
| 3 | +1 | +1 | +1 |
| 4 | −1 | 0 | 0 |
| 5 | +½ | −1 | −1 |
| 6 | n/a | +1 | 0 |
| 7 | n/a | −½ | +1 |
| 8 | n/a | n/a | −1 |
| 9 | n/a | n/a | +½ |

What is desirable, then, is a Bessel array which performs its interference pattern reduction function more in higher frequencies than in lower frequencies and which has more overall sound pressure and efficiency than a conventional Bessel array.

For convenience, the remainder of this disclosure will use a reverse numbering system for transducer positions, putting the (endmost) −1 transducer nearer the top of the loudspeaker; in most applications, the loudspeaker is not mounted higher than a typical seated person's ear, and it is desirable to aim the preferential (positive angle) off-axis response direction of an Improved or Super Bessel Array toward the listener. The order of the transducers can be selected according to the needs of the application at hand.

FIG. 48 illustrates a conventional 7-Element Bessel array loudspeaker 330. For convenience and clarity, only a front panel 332 of the enclosure is shown. Those skilled in the art are familiar with enclosure construction. The 7-Element Bessel array includes six transducers 334-1 to 334-3 and 334-5 to 334-7, with an unpopulated (no transducer) location at position 334-4. The transducers are driven with signals having relative amplitudes and phases of +½, +1, +1, 0, −1, +1, and −½, including the empty middle position.

In order for a Bessel array to achieve its maximum effect, the transducers should be as identical as possible, and they should be on as equal center-to-center spacing (including the empty location) as possible.

Unfortunately, the empty location contributes nothing to the sound, and increases the size of the enclosure. What is desirable, then, is an improved Bessel array loudspeaker system which makes some use of the empty Bessel location.

FIG. 57 illustrates a conventional MTM loudspeaker 340. For convenience, only the front panel 342 of the enclosure is shown; those skilled in the art are well aware of the construction of the remainder of the enclosure. The MTM loudspeaker includes a tweeter transducer 344 surrounded by two midrange transducers 346, 348. Most commonly, the three transducers are arranged with their centers or axes on the same line, as shown. Typically, they are packed as closely together as the manufacturing and assembly technology allows, to control directivity and dispersion.

In most instances, the loudspeaker will be positioned such that its transducers are in a vertical line, as shown. Occasionally, such as in a center channel loudspeaker of a home theater system, the MTM may be horizontally oriented. Hereinafter, an MTM will be referred to as a “vertical MTM” when its midrange, tweeter, and midrange transducers are arranged as shown in FIG. 57, and as a “horizontal MTM” when its transducers are arranged 90° to that orientation.

A point source provides a spherical wave front which has dispersion in all directions. In a room, reflections off side walls arrive at different times at the listener's two ears. Humans have psychoacoustic ability to discern direct signals from reflected signals, from time delay, phase shift, and frequency response differential; key to these is the horizontal displacement of human ears. However, reflections off the floor (or ceiling) arrive at both ears simultaneously, with the same phase, and with the same frequency response, giving the listener essentially no psychoacoustic clues to discern between the direct energy and the energy reflected by the floor or ceiling. The brain interprets this as time smear.

A line source provides a cylindrical wave front which has horizontal dispersion but very little vertical dispersion. Line sources have significantly reduced vertical dispersion, and therefore significantly reduced floor and ceiling reflections. Therefore, it can in many instances be desirable to have a loudspeaker which functions as a line source rather than as a point source.

FIG. 76 may be considered (by looking only at the top transducer on each side) as illustrating a surround channel loudspeaker 350. Surround speakers are used in e.g. home theater systems, to produce sound represented in the surround audio channels, typically located at the left rear and right rear of the listening room. Unlike the front, center, and right (primary) audio channels, it is not always desirable for the listener to be able to too readily discern the direction from which the surround audio content is coming—it is meant to surround the listener.

One method of achieving this has been to use a “dipole” loudspeaker which is configured such that it has a first transducer 352-1 coupled to the loudspeaker's cabinet so as to face forward (generally toward a video display screen) and a second transducer 354-1 coupled to the opposite face of the loudspeaker's cabinet so as to face backward (generally away from the display screen). The loudspeaker is placed, as much as possible, in line with the primary listening position such that both transducers are firing at 90 ° angles to the listener. In the example shown, the side panel (removed to show the internal partition structure of the cabinet) is facing the listener. The first and second transducers are wired in opposite phase, with one receiving a +1 signal and the other a −1 signal. Thus configured, any sound which is projected directly toward the listener by one transducer will be significantly cancelled by an opposite-phase sound projected directly toward the listener by the other transducer. But sounds which have different arrival times due to taking different echo paths from the respective transducers, will not be cancelled and will typically be heard as coming from somewhere other than the loudspeaker. Some dipole transducers have used an all-pass filter on the transducer on one side e.g. the forward-facing one, such that in the low frequencies (which are non-directional) the two transducers' sound is in phase and sums rather than cancels.

The larger the diameter of the dipole transducers, the farther the enclosure sticks out into the listening space.

### BRIEF DESCRIPTION OF THE DRAWINGS

FIG. 1 shows a line array according to the prior art.

FIG. 2 is a graph showing the frequency response of the 5-driver line array of FIG. 1.

FIG. 3 shows a 5-Element Bessel Array according to the prior art.

FIG. 4 is a graph showing the frequency response of the conventional 5-Element Bessel Array of FIG. 3.

FIG. 5 shows an Improved 5-Element Bessel Array according to one embodiment of this invention.

FIGS. 6A and 6B are graphs showing the frequency response of the Improved 5-Element Bessel array of FIG. 5.

FIG. 7 shows a 5×5-Element Bessel Square Array according to the prior art.

FIG. 8 shows an Improved 5×5-Element Bessel Square Array according to another embodiment of this invention.

FIG. 9 shows another embodiment of an Improved 5-Element Bessel Square Array with the frequency-dependent Bessel coefficient feature applied in both row and column circuitry.

FIG. 10 shows yet another embodiment of an Improved 5×5-Element Bessel Square Array.

FIG. 11 shows another embodiment of an Improved 5-Element Bessel Array with an additional improvement in that both the inverted Bessel coefficient and the half-amplitude Bessel coefficients are provided in a frequency dependent manner.

FIG. 12 shows a 7-Element Bessel Array according to the prior art.

FIG. 13 shows an Improved 7-Element Bessel Array according to another embodiment of this invention.

FIG. 14 shows a 9-Element Bessel Array according to the prior art.

FIG. 15 shows an Improved 9-Element Bessel Array according to another embodiment of this invention.

FIG. 16 shows an Improved 7×7 Bessel Square Array according to another embodiment of this invention.

FIGS. 17-18 show various Improved 7-Element Bessel Arrays according to other embodiments of this invention.

FIG. 19 shows a 7-Element Bessel Array used as the woofer section of a 2-way speaker system.

FIG. 20 shows an Improved 7-Element Bessel Array used as the woofer section of a 2-way speaker system.

FIG. 21 shows an another Improved 5-Element Bessel Array according to another embodiment of this invention, used as the woofer section of a 2-way speaker system.

FIG. 22 shows an another Improved 9-Element Bessel Array according to another embodiment of this invention, used as the woofer section of a 2-way speaker system.

FIG. 23 shows a frequency response simulation graph of a modeled full range transducer. This reference transducer is used as the basis for modeling the systems of FIGS. 24-36.

FIG. 24 shows a conventional 5-driver line array using the reference transducer whose frequency response is given in FIG. 23, and FIGS. 24UP and 24 DOWN are frequency response simulation graphs of frequency response measured in 10-degree increments from 0° to +40° off-axis, and 0° to −40° off-axis, respectively. Subsequent FIGxxUP and FIGxxDOWN charts are similarly constructed.

FIG. 25 shows a conventional 5-driver Bessel array, and FIGS. 25UP and 25 DOWN are its frequency response simulation graphs.

FIG. 26 shows another conventional 5-driver Bessel array, and FIGS. 26UP and 26 DOWN are its frequency response simulation graphs.

FIG. 27 shows a 5-driver Bessel array enhanced with a 1^{st} order high-pass filter, and FIGS. 27UP and 27DOWN are its frequency response simulation graphs.

FIG. 28 shows a 5-driver Bessel array enhanced with a 2^{nd} order high-pass filter, and FIGS. 28UP and 28DOWN are its frequency response simulation graphs.

FIG. 29 shows of a 5-driver Bessel array enhanced with a shelf circuit, and FIGS. 29UP and 29DOWN are its frequency response simulation graphs.

FIG. 30 shows a 5-driver Bessel array enhanced with a different shelf circuit, and FIGS. 30UP and 30DOWN are its frequency response simulation graphs.

FIG. 31 shows a 5-driver Bessel array enhanced with an all-pass filter, and FIGS. 31UP and 31DOWN are its frequency response simulation graphs.

FIG. 32 shows a 5-driver Bessel array enhanced with both a shelf circuit and an all-pass filter, and FIGS. 32UP and 32DOWN are its frequency response simulation graphs.

FIG. 33 shows a frequency response graph of a transducer whose output is biased toward the high frequencies, such as a horn loaded driver, or a driver with an extremely powerful motor and a very light moving mass. FIGS. 33UP and 33DOWN are frequency response simulation graphs for a 5-driver Improved Bessel Array using the high frequency biased driver rather than the full range driver of FIG. 23.

FIG. 34 shows a conventional 4-driver line array, and FIGS. 34UP and 34DOWN are its frequency response simulation graphs. FIGS. 34 to 37 use the full range transducer of FIG. 23, not the horn loaded driver of FIG. 33.

FIG. 35 shows a 4-driver Reduced-Bessel Array, and FIGS. 35UP and 35DOWN are its frequency response simulation graphs.

FIG. 36 shows a 4-driver Reduced Bessel Array, and FIGS. 36UP and 36DOWN are its frequency response simulation graphs.

FIG. 37 shows a comparison of the UP sides of the output of the Reduced Bessel Arrays of FIGS. 34 and 35.

FIG. 38 shows an Improved 4-driver Reduced Bessel Array, and FIGS. 38UP and 38DOWN are its frequency response simulation graphs.

FIG. 39 shows another Improved 4-driver Reduced Bessel Array, and FIGS. 39UP and 39DOWN are its frequency response simulation graphs.

FIG. 40 shows another Improved 4-driver Reduced Bessel Array, and FIGS. 40UP and 40DOWN are its frequency response simulation graphs.

FIG. 41 shows an Improved 9-Element Bessel Array in which the amplifiers are located between the Bessel circuit and the transducers.

FIG. 42 shows an Improved 5-Element Bessel Array using dual-voice-coil transducers.

FIG. 43 shows another Improved 5-Element Bessel Array using dual-voice-coil transducers.

FIG. 44 shows another Improved 5-Element Bessel Array using dual-voice-coil transducers.

FIG. 45 shows a conventional 5-driver line array having a cabinet with a single enclosed air volume shared by all the transducers.

FIG. 46 shows a 5-Element Bessel Array having a cabinet with each transducer having a separate enclosed air volume.

FIG. 47 shows an Improved 5-Element Bessel Array having a split cabinet arrangement by which the reduced amplitude signals are achieved by angling the transducers rather than by altering their signal strength or BL.

FIG. 48 shows a conventional 7-Element Bessel array loudspeaker.

FIG. 49 shows a 7-Element Bessel array loudspeaker according to one embodiment of this invention, with the 0 location filled with an MTM set of transducers.

FIG. 50 shows a 7-Element Bessel array loudspeaker with the 0 position filled with a 5-Element Bessel array arranged perpendicular to the 7-Element Bessel array.

FIG. 51 shows a 7-Element Bessel array loudspeaker with the 0 position filled with a 5×5-Element Bessel Square Array.

FIG. 52 shows a 7-Element Bessel array loudspeaker with the 0 position filled with a 7-Element Bessel array arranged perpendicular to the main 7-Element Bessel array.

FIG. 53 shows a 7-Element Bessel array loudspeaker with the 0 position filled with an MTM of Bessel arrays arranged perpendicular to the 7-Element Bessel array.

FIG. 54 shows a 7-Element woofer Bessel array loudspeaker with the 0 position filled with a 7-Element midrange Bessel array arranged perpendicular to the woofer Bessel array, and a 5-Element tweeter Bessel array in turn arranged perpendicular to the midrange Bessel array.

FIG. 55 shows a 7-Element Bessel array loudspeaker with the 0 position filled with a 5-Element midrange Bessel array oriented diagonally in order to fit larger midrange drivers into the enclosure. A tweeter is also included.

FIG. 56 shows a 9-Element Bessel array loudspeaker with the upper 0 position filled with a 7-Element midrange Bessel array and a crossing 5-Element tweeter Bessel array, and the lower 0 position filled with a port.

FIG. 57 shows an MTM loudspeaker according to the prior art.

FIG. 58 shows a Bessel MTM loudspeaker according to one embodiment of this invention, in which the tweeter transducer has been replaced with a Bessel array of tweeters.

FIG. 59 shows a Bessel MTM loudspeaker according to another embodiment of this invention, in which the midrange transducers have also been replaced with Bessel arrays of midrange transducers.

FIG. 60 shows a Bessel MTM loudspeaker according to another embodiment of this invention, in which the acoustic center of the tweeter Bessel array is not in line with the acoustic centers of the midrange Bessel arrays, for packing.

FIG. 61 shows a Bessel MTM loudspeaker according to another embodiment of this invention, in which the tweeter has been replaced with a 7-Element Bessel array and the midrange transducers have been replaced with 5-Element Bessel arrays.

FIG. 62 shows a Bessel MTM loudspeaker according to another embodiment of this invention, in which the 7-Element Bessel tweeter array has been augmented with a supertweeter at the center null position.

FIG. 63 shows a Bessel MTM loudspeaker in which the midrange arrays are not strictly in line, to improve packing.

FIG. 64 shows another Bessel MTM loudspeaker in which the midrange arrays are not strictly linear, and using the largest tweeters that will fit, to improve packing and output.

FIG. 65 shows a Reduced Bessel MTM loudspeaker in which the midrange arrays are of the Reduced Bessel form.

FIG. 66 shows a Bessel MTM using racetrack-shaped midrange drivers arranged vertically.

FIG. 67 shows a Bessel MTM using racetrack-shaped midrange drivers arranged horizontally.

FIG. 68 shows a Bessel MTM using racetrack-shaped midrange drivers arranged diagonally.

FIG. 69 shows a Bessel MTM using racetrack-shaped midrange drivers arranged in a herringbone pattern.

FIG. 70 shows a television set having Bessel Array LCR speakers.

FIG. 71 shows a television set having Bessel Array LCR speakers with improved lateral separation for improved stereo effect.

FIG. 72 shows a television set having 7-Element Bessel Array LCR speakers of the midrange/tweeter form.

FIG. 73 shows a television set having LCR speakers in which the L and R speakers are Reduced Bessel Arrays, to narrow the total width of the LCR.

FIG. 74 shows a television set having LCR speakers in which the L and C Bessel Arrays share a transducer, and the C and R Bessel Arrays share a transducer.

FIG. 75 (comprising FIGS. 75A and 75 B) shows one wiring diagram for an LCR soundbar such as that of FIG. 74.

FIG. 76 shows an embodiment of a Bessel Array dipole surround speakers.

FIG. 77 shows another embodiment of a Bessel Array dipole speaker, using shared, off-axis, angled transducers to reduce the transducer parts count.

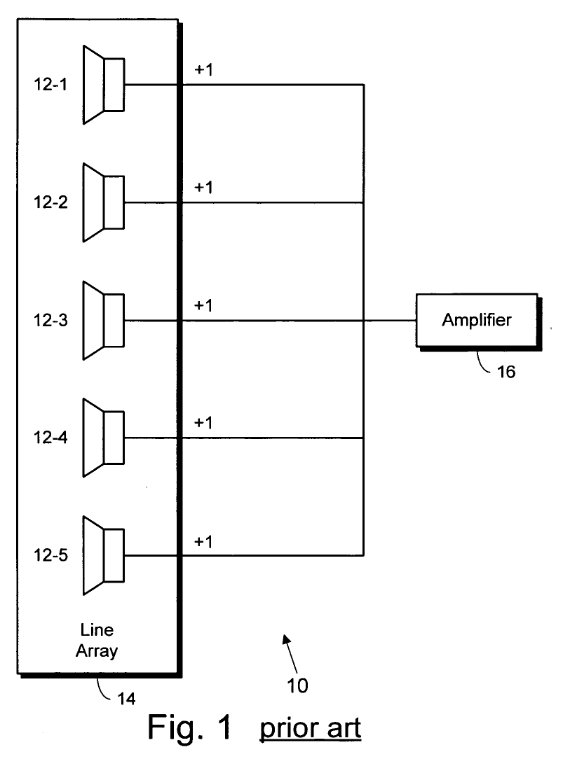

### DETAILED DESCRIPTION

The invention will be understood more fully from the detailed description given below and from the accompanying drawings of embodiments of the invention which, however, should not be taken to limit the invention to the specific embodiments described, but are for explanation and understanding only.

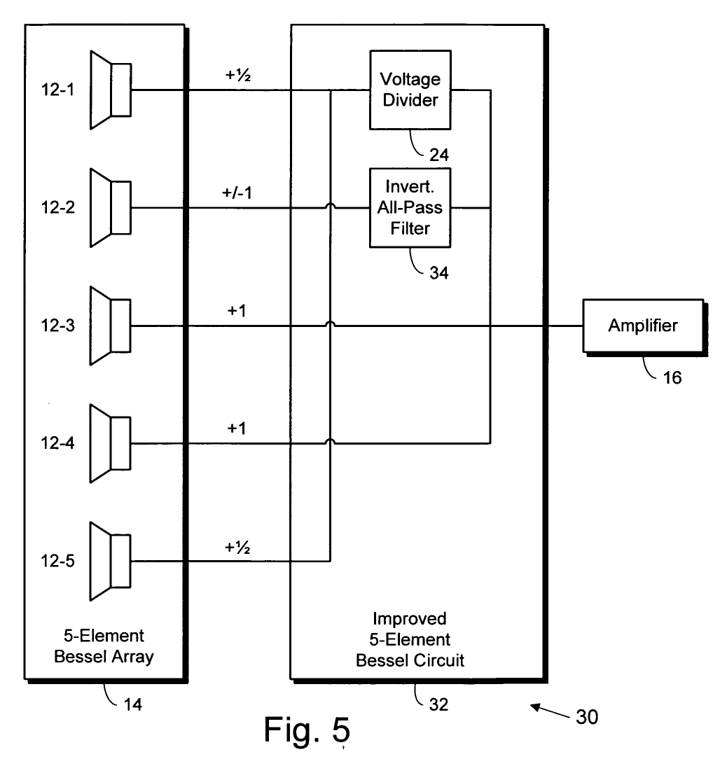

FIG. 5 illustrates one embodiment of an Improved 5-Element Bessel Array 30 according to this invention. The Bessel array may use a conventionally configured array of speaker drivers 12-1 to 12-5 mounted in an enclosure 14 and powered by a conventional source such as an amplifier 16.

The improvement lies in the Bessel circuit 32 which conditions the amplifier output to apply the required Bessel coefficients to the signals supplied to each of the respective drivers. In the five-driver Bessel array shown, the first driver 12-1 and fifth driver 12-5 each receives an in-phase, half-strength (“+½”) signal whose strength is reduced by a conventional voltage divider 24 or other suitable means (such as being coupled in series); the second driver 12-2 receives its signal (“±1”) from an inverting all-pass filter 34 or other such circuit which performs the desired function; and the third driver 12-3 and fourth driver 12-4 each receives a simple pass-through of the amplifier signal (“+1”).

The inverting all-pass filter inverts the phase of high-frequency signals, but does not invert the phase of low-frequency signals; thus, the signal is identified as “±1” suggesting that it is “+1” in lower frequencies and “−1” in higher frequencies. The designer can select the phase-inverting cross-over point to be at any frequency, based on driver spacing and desired off-axis response control.

Thus, the improved Bessel array is a “single-sided” Bessel array, in that it behaves like a Bessel array on one side (the high-frequency side) of its frequency range, but more like a conventional line array on the other side (the low-frequency side). It may also be thought of as being single-sided in that, in some embodiments, it will exhibit better performance in one off-axis direction than in the other.

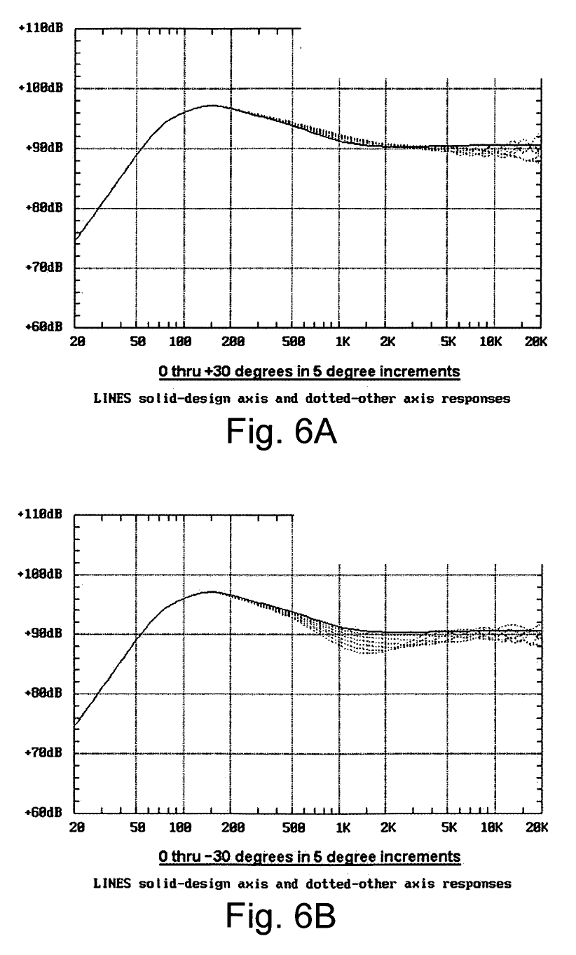

FIGS. 6A and 6B are graphs illustrating the off-axis performance of the improved Bessel array of FIG. 5, which has 5 drivers on 4 cm center-to-center spacing. FIGS. 6A and 6B show the performance from center to 30 degrees above and below center, respectively, in 5 degree increments.

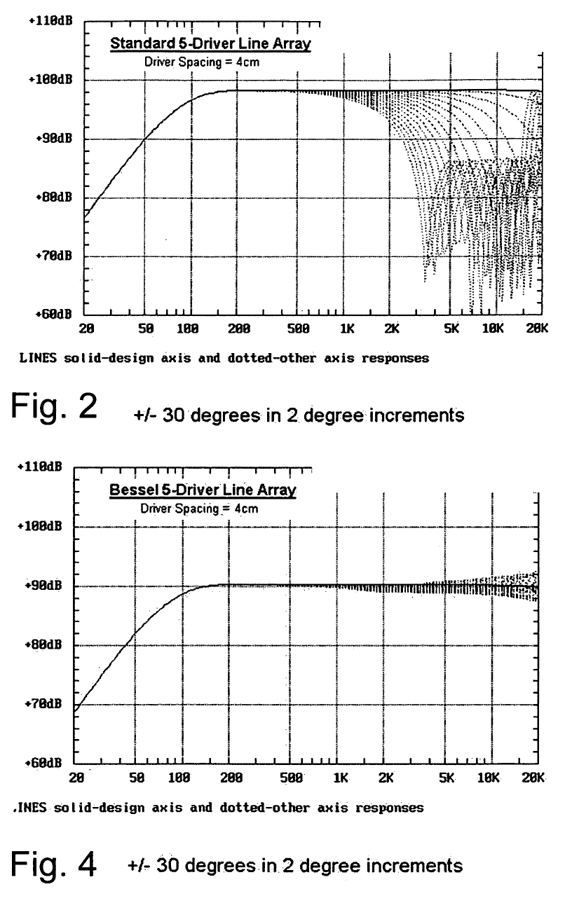

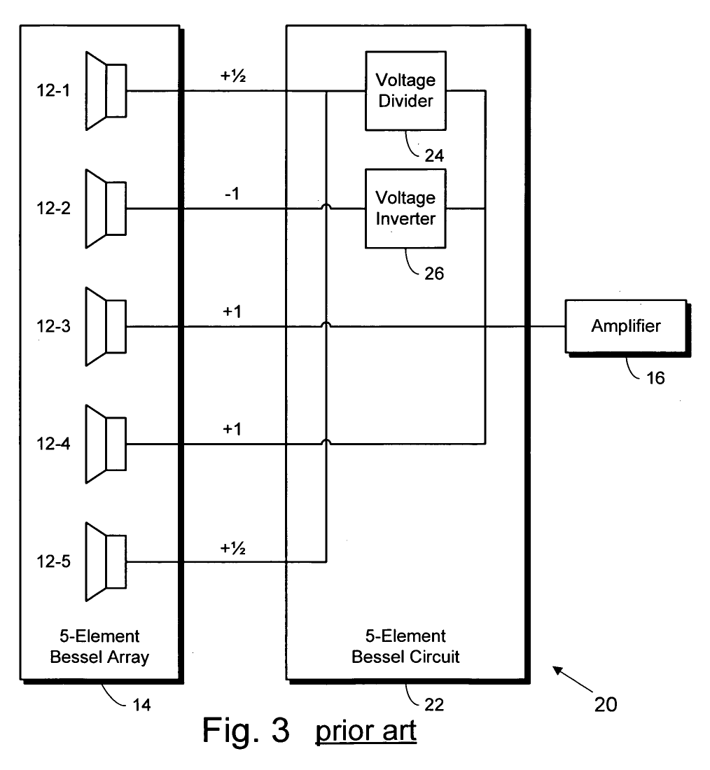

Comparing FIGS. 6, 4, and 2, it is seen that in the lower frequencies, the sound pressure level of the improved Bessel array of this invention is significantly better than that of the conventional Bessel array, and in the higher frequencies, the interference exhibited by the improved Bessel array of this invention is significantly better than that of a conventional line array and nearly as good as the conventional Bessel array. The improved Bessel array is somewhat asymmetrical, as seen by comparing FIG. 6A to FIG. 6B, in that it has a different amount of off-axis interference control in one off-axis direction than in the other.

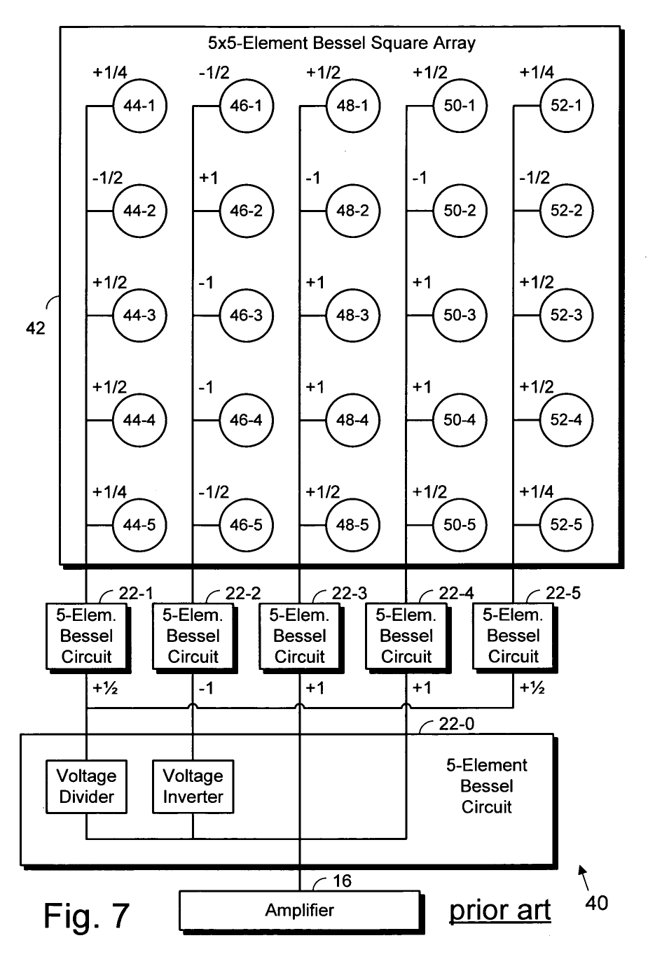

FIG. 7 illustrates a Bessel square array 40 according to the prior art, including an array of speaker drivers coupled to an enclosure 42. The Bessel square array is a “Bessel of Bessels”. The speaker drivers are arranged in a two-dimensional array, typically but not necessarily having equal numbers of rows and columns. The speaker drivers within each given column are driven in Bessel array fashion, and the columns themselves are driven in Bessel array fashion.

The amplifier output is provided to a main Bessel circuit 22-0. Each output of the main Bessel circuit is provided as an input to a respective secondary or column Bessel circuit 22-1 through 22-5. Each of the secondary Bessel circuits drives a corresponding Bessel array of drivers arranged in a column. The first column Bessel circuit 22-1 drives a first Bessel array of drivers 44, the second column Bessel circuit 22-2 drives a second Bessel array of drivers 46, and so forth. Each secondary Bessel circuit applies the Bessel function to whatever input signal it receives from its respective output of the main Bessel circuit. Thus, the signal provided to any given speaker driver is the product of its main and column Bessel signal values.

The five drivers 44 in the first column are driven in Bessel array fashion, with the first driver 44-1 and the fifth driver 44-5 each receives a quarter-strength, in-phase signal “+¼”; the second driver 44-2 receives a half-strength, opposite-phase signal “−½”; and the third driver 44-3 and the fourth driver 44-4 each receives a half-strength, in-phase signal “+½”. The five drivers 52 in the fifth column are driven the same as those in the first column.

The five drivers 46 in the second column are driven collectively by the “−1” of the main Bessel, which is fed through the second column Bessel circuit 22-2. The first driver 46-1 and the fifth driver 46-5 each receives a half-strength, opposite-phase signal “−½”; the second driver 46-2 receives a full-strength, in-phase signal “+1” (a double negative); and the third driver 46-3 and the fourth driver 46-4 each receives a full-strength, opposite-phase signal “−1”.

The third column Bessel circuit 22-3 receives a “+1” signal from the main Bessel circuit. The first driver 48-1 and the fifth driver 48-5 each receives a half-strength, in-phase signal “+½”; the second driver 48-2 receives a full-strength, opposite-phase signal “−1”; and the third driver 48-3 and the fourth driver 48-4 each receives a full-strength, in-phase signal “+1”. The five drivers 50 in the fourth column are driven the same as those in the third column.

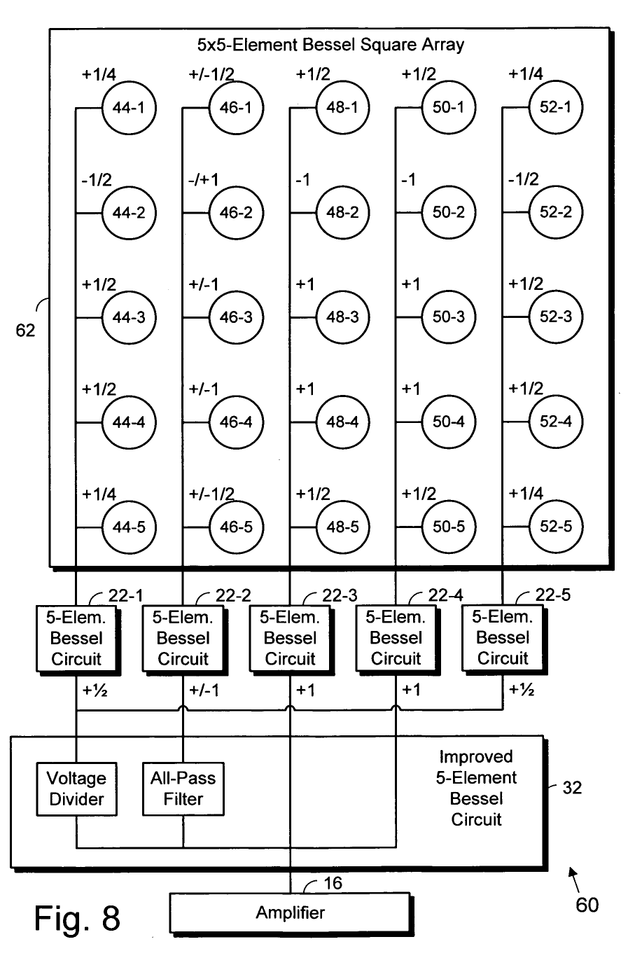

FIG. 8 illustrates the improved Bessel square array 60 according to one embodiment of this invention. In the embodiment shown, the inverting all-pass filter improvement is applied to only the primary Bessel circuit, with the five column Bessel circuits being conventional Bessel circuits which simply invert the phase of their input signals to generate their second drivers' respective signals

The first, third, fourth, and fifth columns' drivers receive the same signals as in the conventional Bessel square array of FIG. 7. The improvement lies in the signals applied to the second column—the position which, in a conventional Bessel array receives the “−1” signal but which, in this invention such as shown in FIG. 5, receives the “±1” signal.

The operation of the second column is slightly more complex than in the conventional Bessel square array, because according to this invention it receives a single-sided all-pass filter phase shifted signal “±1” from the second output of the primary Bessel circuit.

In the low frequencies, the primary Bessel circuit is outputting a “+1” signal at its second output, and the second column Bessel circuit 22-2 provides a “+½” signal (main “+1” times column “+½”) to the first driver 46-1 and to the fifth driver 46-5; a “−1” (main “+1” times column “−1”) signal to the second driver 46-2; and a “+1” (main “+1 ” times column “+1”) signal to each of the third driver 46-3 and the fourth driver 46-4.

In the high frequencies, the primary Bessel circuit is outputting a “−1” signal at its second output, and the second column Bessel circuit 22-2 provides a “−½” signal (main “−1” times column “+½”) to the first driver 46-1 and to the fifth driver 46-5; a “+1” (main “−1” times column “−1”) signal to the second driver 46-2; and a “−1” (main “−1” times column “+1”) signal to each of the third driver 46-3 and the fourth driver 46-4.

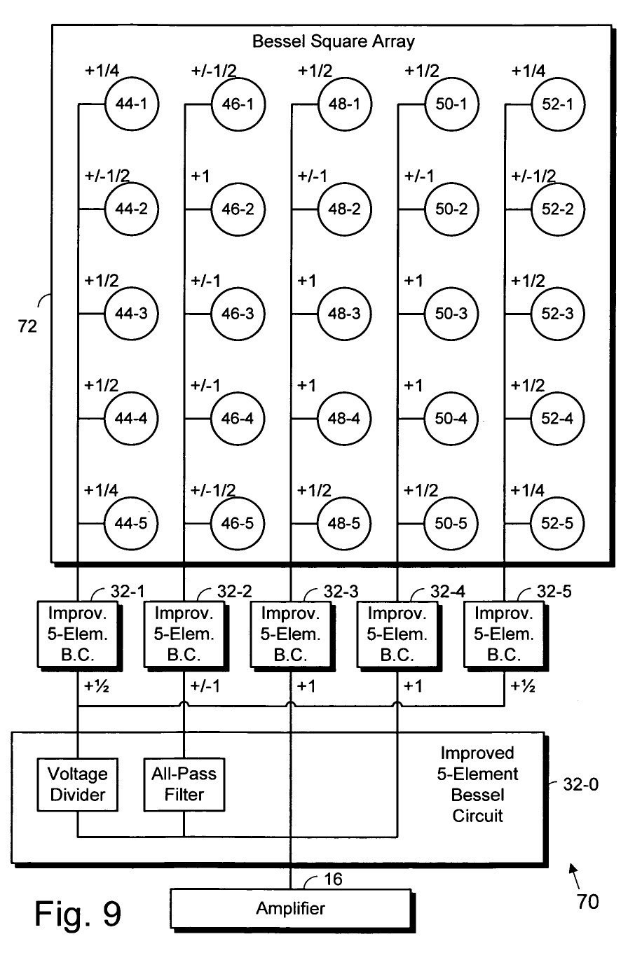

FIG. 9 illustrates another embodiment of an improved Bessel square array 70 in which the improved Bessel circuit is used in both the main (row) Bessel and the column Bessel functions. The output from the amplifier(s) is fed into an improved main Bessel circuit 32-0. The outputs of the main Bessel circuit are fed into respective improved column Bessel circuits 32-1 through 32-5.

The advantage gained over the embodiment of FIG. 8 lies in the second row of transducers. In the low frequencies, each of those five drivers 44-2, 46-2, 48-2, 50-2, and 52-2 receives an in-phase “+” signal, whereas in FIG. 8 each received an opposite phase “−” signal in the low frequencies. In the FIG. 8 configuration, the second row transducers contribute to low frequency sound pressure, rather than diminishing it. The disadvantage is that there are now six instances of the inverting all-pass filter circuitry-one in the main Bessel circuit, and five in the respective column Bessel circuits.

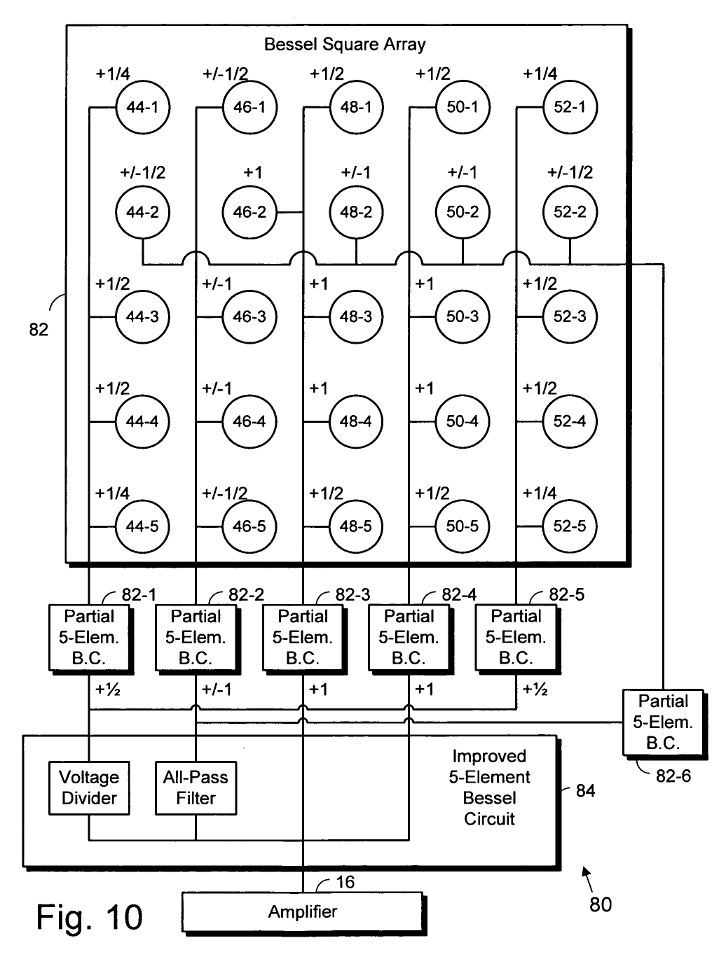

FIG. 10 illustrates another embodiment of a Bessel square array 80 which retains the low frequency performance advantage of FIG. 9, but which requires only a single inverting all-pass filter circuit. The amplifier output is provided to an improved main Bessel circuit 84. The five Bessel coefficient outputs of the main Bessel circuit are fed into five respective column partial Bessel circuits 82-1 through 82-5. These are partial Bessel circuits in that they lack the inverting (second) Bessel output. A sixth partial Bessel circuit 82-6 is driven, in parallel with the second column partial Bessel circuit 82-2, with the frequency-dependent inverting output of the main Bessel circuit. This sixth partial Bessel circuit drives transducers 44-2, 48-2, 50-2, and 52-2 as indicated. The transducer 44-2 which lies at the missing inverting output of both the second column partial Bessel circuit 82-2 and the sixth partial Bessel circuit 82-6 is driven with a “+1” signal, which may be supplied by any handy source such as any other “+1” output or by its own amplifier or what have you.

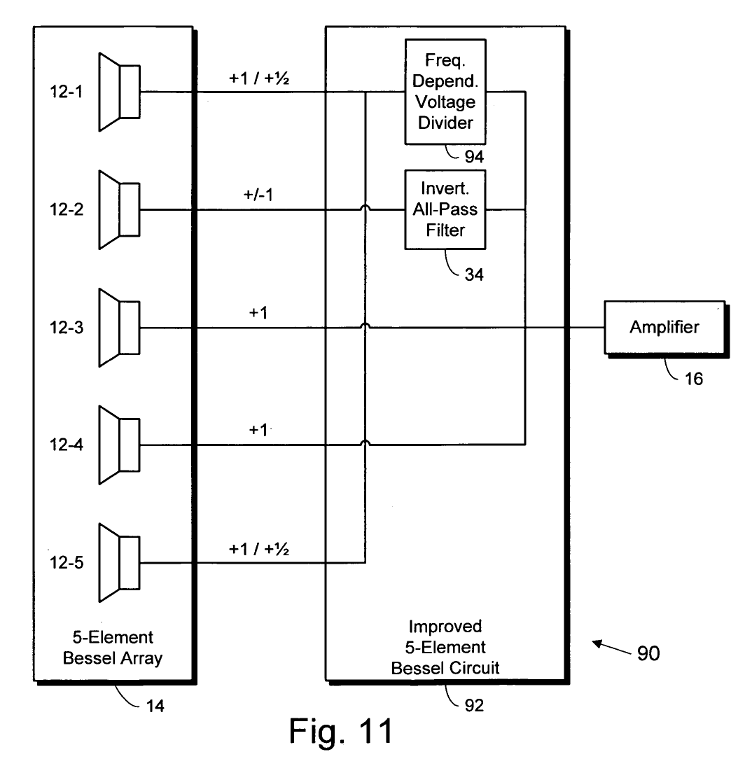

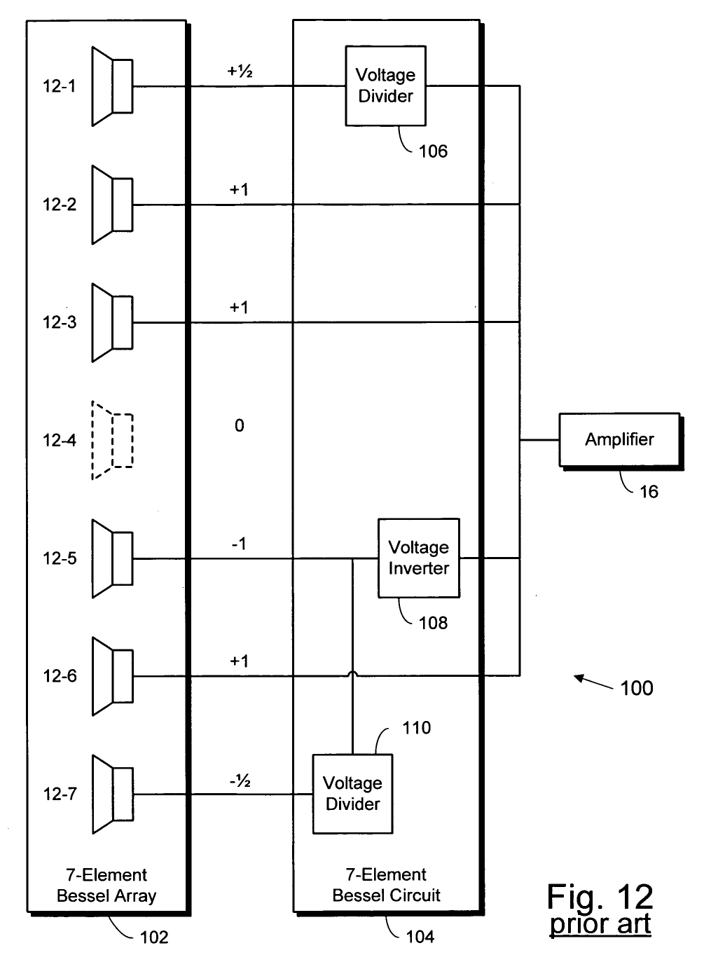

FIG. 11 illustrates the frequency-dependent improvement applied not only to the inverting (second) Bessel signal but also to the half-strength (first and fifth) Bessel signals, as well. The improved Bessel system 90 includes an improved Bessel circuit 92, which includes the inverting all-pass filter 34 providing its second output and the straight pass-through paths providing its third and fourth outputs. In place of a conventional voltage divider (or series connection) at its first and fifth outputs, it includes a frequency-dependent voltage divider 94 providing its first and fifth outputs.

In low frequencies, the frequency-dependent voltage divider does not perform any significant voltage division, and the first and fifth transducers receive full-strength, in-phase “+1” signals; the inverting all-pass filter does not perform phase inversion, and the second transducer receives a full-strength, in-phase “+1” signal; and, as always, the third and fourth transducers receive full-strength, in-phase “+1” signals. Thus, in low frequencies, the improved Bessel array performs substantially like a conventional line array, offering maximum sound pressure and efficiency.

In high frequencies, the frequency-dependent voltage divider performs voltage division, such that the first and fifth transducers receive half-strength, in-phase “+½” signals; the inverting all-pass filter provides a full-strength, opposite-phase “−1” signal to the second transducer; and the third and fourth transducers continue to receive full-strength, in-phase “+1” signals. Thus, in high frequencies, the improved Bessel array performs substantially like a conventional Bessel array, reducing interference patterns in off-axis listening positions.

This frequency-dependent voltage divider improvement can, of course, be applied to a Bessel square array, as well.

FIG. 12 illustrates a 7-Element Bessel Array 100 according to the prior art, including an array of transducers 12-1 through 12-3, and 12-5 through 12-7 coupled to an enclosure 102 equal on-center vertical spacing. The transducers are powered by a Bessel circuit 104 which receives an input signal from an amplifier 16. The Bessel circuit includes a voltage divider 106 which drives the first transducer 12-1 with an in-phase, half-amplitude “+½” signal. Second and third transducers 12-2 and 12-3 are driven by in-phase, full-amplitude “+1” signal directly from the amplifier: The fourth transducer 12-4 is driven with a null signal “0” and, consequently, is omitted from the array. The Bessel circuit further includes a first voltage inverter 108 drives a fifth transducer 12-5 with an opposite-phase, full-amplitude “−1” signal, which can also be accomplished by simply connecting the wires to the transducers in reverse polarity. The distance between the fifth transducer and the third transducer is twice the distance between other transducers, because although the fourth transducer (12-4) is not present, its position is used in maintaining the correct spacing for the Bessel array to function correctly. A sixth transducer 12-6 is driven by an in-phase, full-amplitude “+1” signal. The Bessel circuit includes a second voltage 11 divider 110 which receives the opposite-phase signal from the voltage inverter, and drives a seventh transducer 12-7 with an opposite-phase, half-amplitude “−½” signal.

This conventional 7-Element Bessel Array uses six transducers but produces only two transducers' worth of sound pressure level. The first and seventh transducers cancel each other, and the fifth and sixth transducers cancel each other.

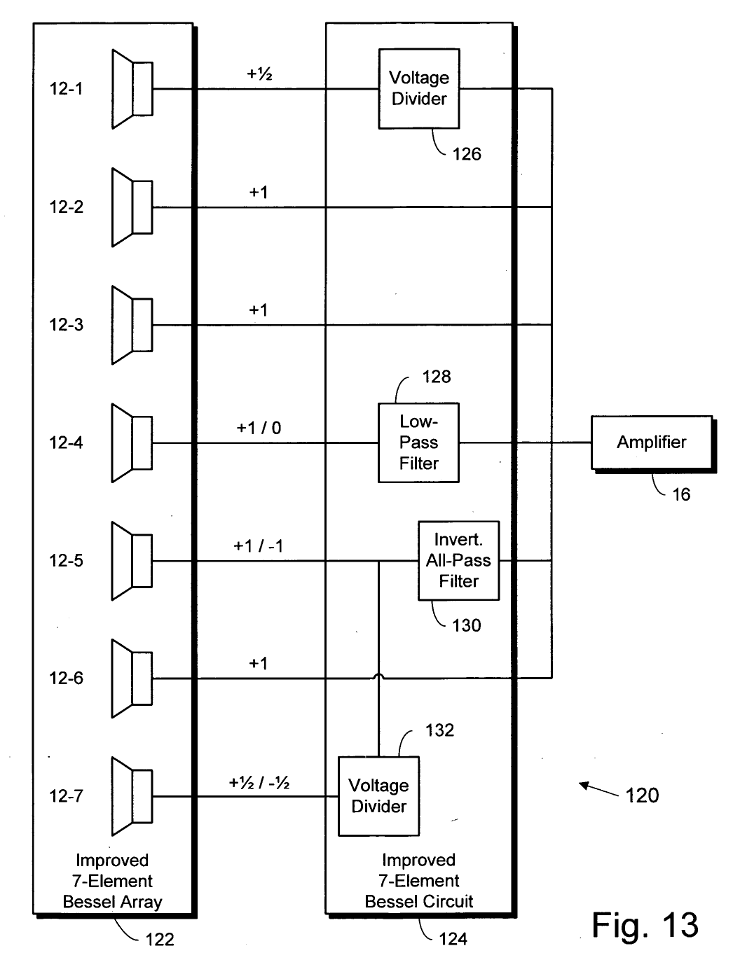

FIG. 13 illustrates an Improved 7-Element Bessel Array 120 according to another embodiment of this invention. Seven transducers 12-1 through 12-7 are coupled to an enclosure 122, as compared to only six transducers in the prior art system. An Improved 7-Element Bessel Circuit 124 includes a first voltage divider 126 coupled to drive the first transducer 12-1 with an in-phase, half-amplitude “+½” signal. The second, third, and sixth transducers 12-2, 12-3, and 12-6 are coupled to be driven with an in-phase, full-amplitude “+1” signal from the amplifier 16. The circuit includes an inverting all-pass filter 130 which is coupled to drive the fifth 12-5 transducer with a full-amplitude “±1” signal which is in-phase in a low frequency range and opposite-phase in a high frequency range. A second voltage divider 132 also receives the output of the inverting all-pass filter and drives the seventh transducer 12-7 with a half-amplitude “±½” signal which is in-phase in a low frequency range and opposite-phase in a high frequency range. To this point, it is similar to the Improved 5-Element Bessel Arrays described above.

However, the 7-Element Bessel differs from the 5-Element Bessel in that it includes a “0” signal. In this configuration, the circuit includes a low-pass filter 128 coupled to drive the fourth transducer 12-4 with a signal which is in-phase, full-amplitude “+1” in a low frequency range, and a substantially null “0” in a high frequency range.

This improved 7-Element Bessel uses seven transducers and produces six transducers' worth of sound pressure in a low frequency range, and two transducers' worth of sound pressure in a high frequency range. If the voltage dividers were replaced by frequency-dependent voltage dividers, it would produce seven transducers' worth of sound pressure in the low frequency range.

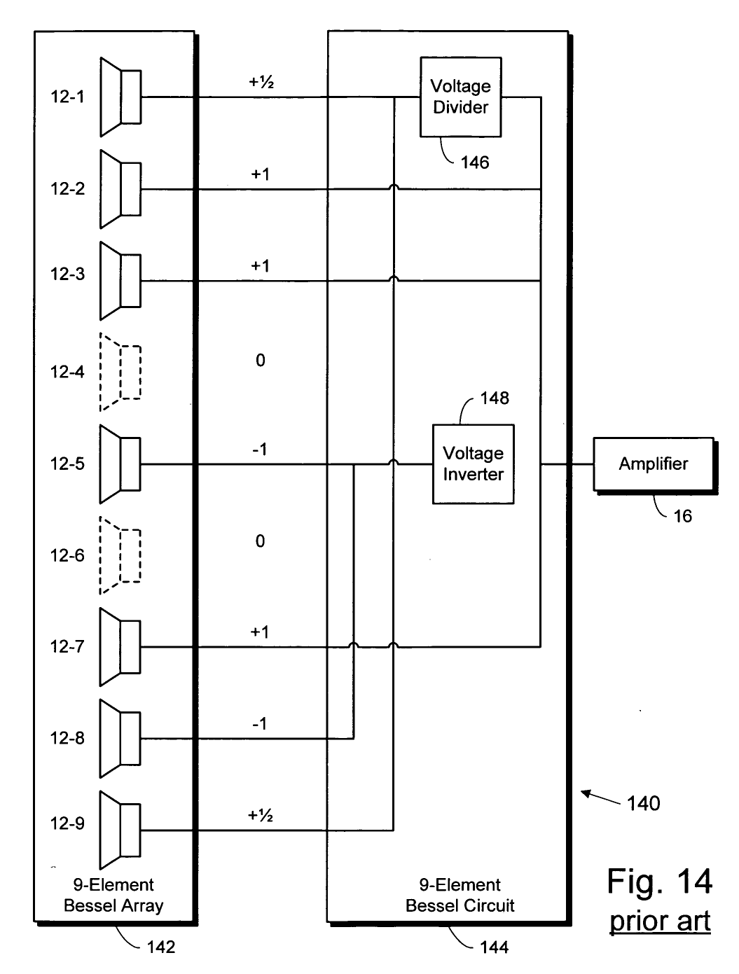

FIG. 14 illustrates a 9-Element Bessel Array 140 according to the prior art. Seven transducers 12-1 through 12-3, 12-5, and 12-7 through 12-9 are coupled to an enclosure with two positions (12-4 and 12-6) being unoccupied. The transducers are driven by a 9-Element Bessel Circuit 144 which receives a signal from an amplifier 16. A voltage divider 146 provides an in-phase, half-amplitude “+½” signal to the first and ninth transducers 12-1 and 12-9. The second, third, and seventh transducers 12-2, 12-3, and 12-7 are driven by in-phase, full-amplitude “+1” signals directly from the amplifier. A voltage inverter 148 provides an opposite-phase, full-amplitude “−1” signal to the fifth and eighth transducers 12-5 and 12-8.

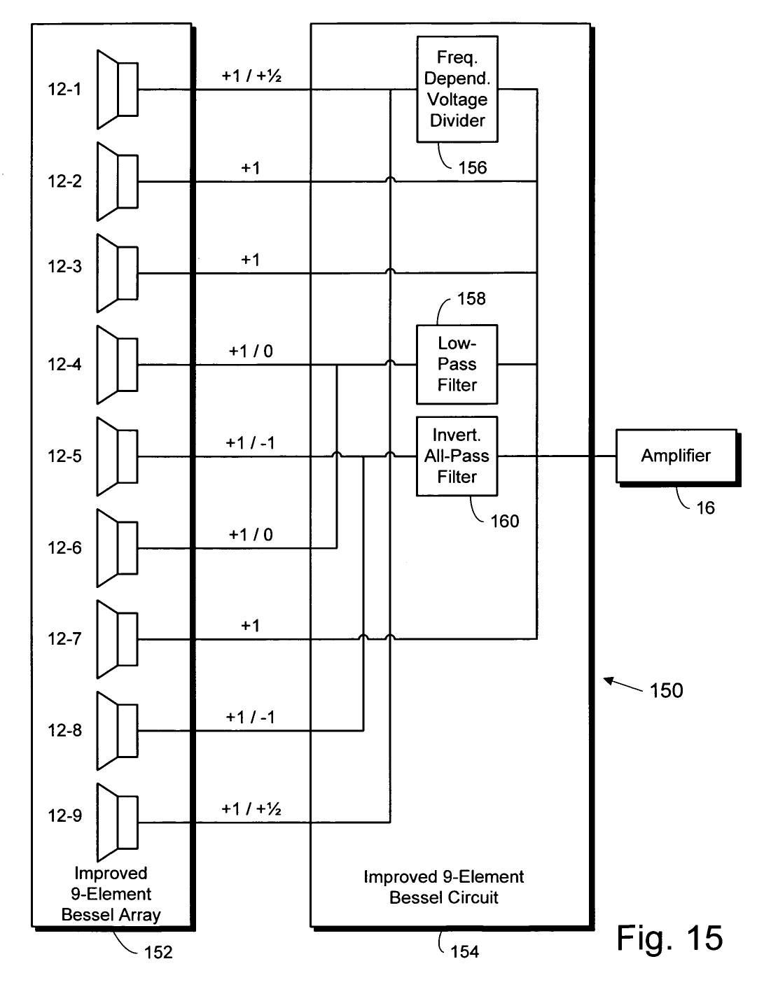

FIG. 15 illustrates an Improved 9-Element Bessel Array 150 according to another embodiment of this invention. Nine transducers 12-1 through 12-9 are coupled to an enclosure 152 and are driven by an Improved 9-Element Bessel Circuit 154 which receives an input signal from an amplifier 16. The second, third, and seventh transducers are driven by in-phase, full-amplitude “+1” signals from the amplifier. The circuit includes a frequency-dependent voltage divider 156, such as a simple shelf circuit, which drives the first transducer 12-1 and the ninth transducer 12-9 with an in-phase “+1/+½” signal which is full-amplitude in a low frequency range and half-amplitude in a high frequency range. A low-pass filter 158 drives the fourth and sixth transducers 12-4, 12-6 with a “+1/0” signal which is in-phase, full-amplitude in a low frequency range and substantially null in a high frequency range. An inverting all-pass filter 160 drives the fifth transducer 12-5 and the eighth transducer 12-8 with a full-amplitude “±1” signal which is in-phase in a low frequency range and opposite-phase in a high frequency range.

This version of the improved 9-Element Bessel uses nine transducers and produces nine transducers' worth of sound pressure in a low frequency range, and two transducers' worth of sound pressure in a high frequency range. If conventional voltage dividers were used in place of the frequency-dependent voltage divider, only eight transducers' worth of sound pressure would be produced in the low frequency range.

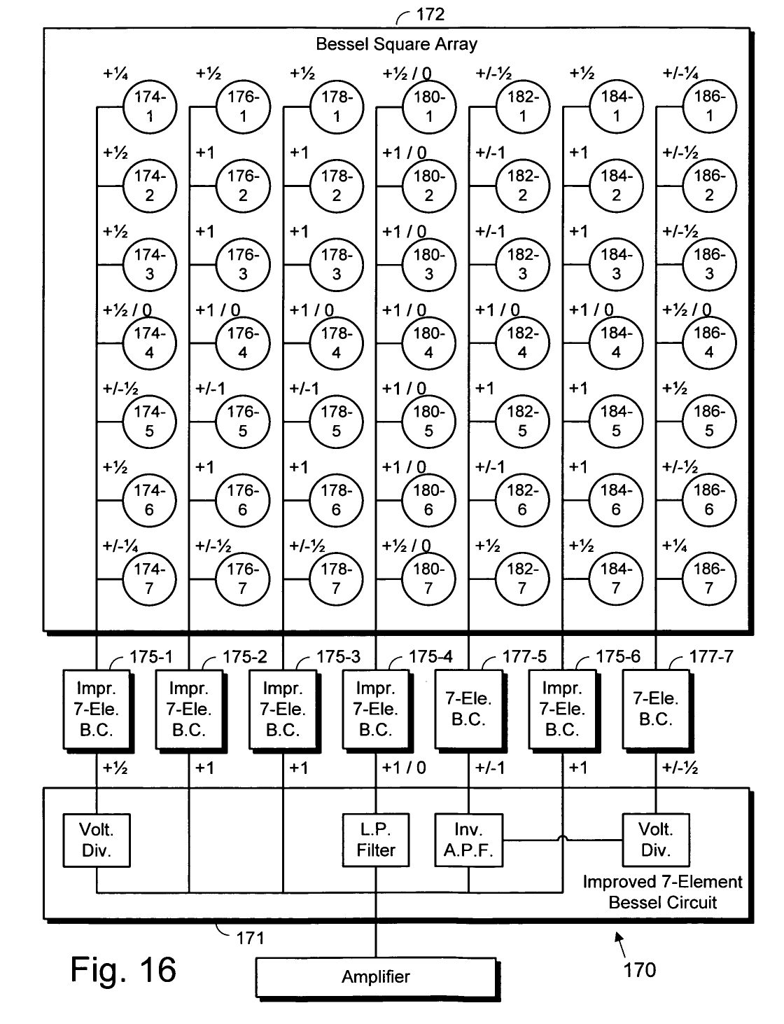

FIG. 16 illustrates an improved 7-Element Bessel square array 170 according to yet another embodiment of the invention. The output of the amplifier is provided to an improved main 7-Element Bessel Circuit 171 which drives five improved 7-Element Bessel Circuits 175 and two conventional 7-Element Bessel Circuits (without the all-pass filter) 177, which in turn drive the transducers 174 to 186 of the array 172 as indicated.

The main Bessel circuit includes a voltage divider which provides a “+½” signal to the first column Bessel circuit 175-1, a low pass filter which provides a “+1/0” signal to the fourth column Bessel circuit 175-4, an inverting all-pass filter which provides a “±1” signal to the fifth column Bessel circuit 177-5, and a voltage divider in series with the inverting all-pass filter to provide a “±½” signal to the seventh column Bessel circuit 177-7. The second, third, and sixth column Bessel circuits are fed with the “+1” output of the amplifier.

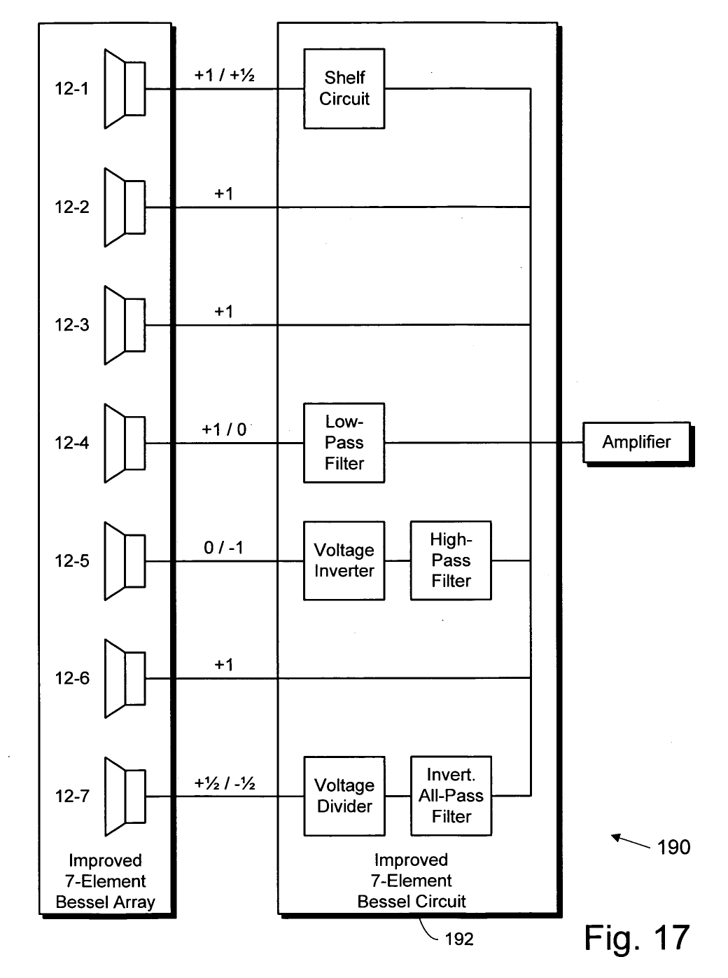

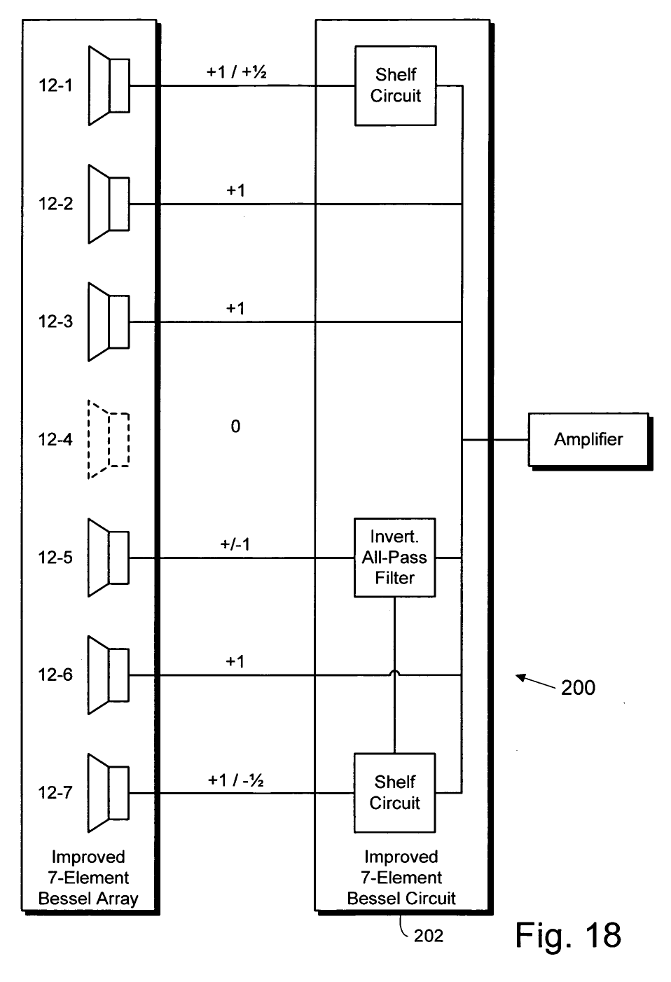

FIG. 17 illustrates another embodiment of an improved 7-Element Bessel array 190, in which an improved Bessel circuit 192 drives seven transducers 12-1 to 12-7. The first transducer 12-1 is driven by a “+1/+½” signal from a shelf circuit. The fourth transducer 12-4 is driven by a “+1/0” signal from a low pass filter, such that it contributes “+1” in the low frequencies, but has the appropriate “0” contribution in the higher frequencies where the Bessel effect is important. The fifth transducer 12-5 is driven by a voltage inverter and high-pass filter in series, such that it contributes “0” (rather than the conventional Bessel “−1”) in the low frequencies, and the desired “−1” in the high frequencies. Alternatively, the fifth transducer could be driven by an inverting all-pass filter to have a “±1” characteristic (as shown in FIG. 18). The seventh transducer 12-7 is driven by an inverting all-pass filter and a voltage divider in series, such that it has a “±½” characteristic; alternatively, it could be driven by a shelf circuit and an inverting all-pass filter in series to have a “+1/−½” characteristic (as shown in FIG. 18). The second, third, and sixth transducers are directly driven by the amplifier with “+1/+1” signals.

FIG. 18 illustrates a different 7-Element Improved Bessel Array 200 using a different Improved Bessel Circuit 202. A first transducer 12-1 is driven with a “+1/+½” signal provided by a first shelf circuit. A fourth transducer (12-4) would be driven with a “0” signal and is therefore omitted in this embodiment. A fifth transducer 12-5 is driven with a “±1” signal from an inverting all-pass filter. The output of the all-pass filter is also fed to a second shelf circuit, to drive a seventh transducer 12-7 with a “+1/−½” signal. The other transducers are driven with “+1” signals directly from the amplifier.

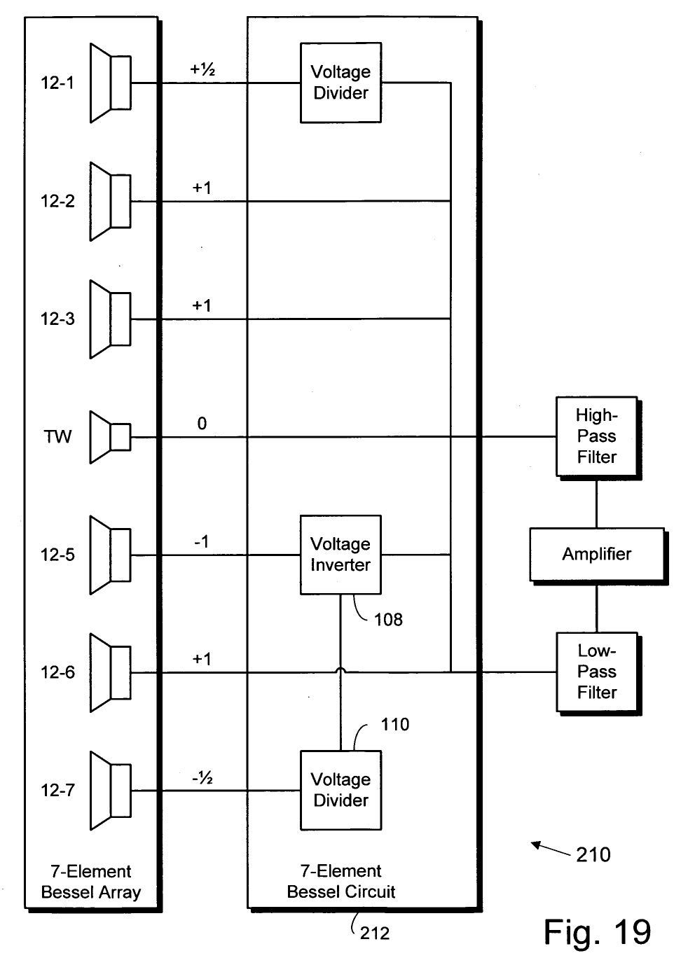

FIG. 19 illustrates another 7-Element Improved Bessel Array 210 used in a 2-way speaker system. The amplifier does not directly power the Bessel circuit. A low-pass filter is designed such that it blocks frequencies above about 2 kHz or whatever crossover frequency the designer selects. The Bessel circuit 212 receives the output of the low-pass filter. A first transducer 12-1 is driven with a “+½” signal from a first voltage divider. A fifth transducer 12-5 is driven with a “−1” signal from a voltage inverter (typically amounting to nothing more than the transducer being wired oppositely versus the others). A second voltage divider is also coupled to receive the output of the voltage inverter, and provides a “−½” signal to a seventh transducer 12-7. The second, third, and sixth transducers are driven directly with “+1” signals.

A high-pass filter is designed such that it blocks frequencies below about 2 kHz or whatever crossover frequency the designer selects. The high-pass filter drives a high frequency transducer, such as a tweeter. In one embodiment, the tweeter is advantageously placed in the position where the fourth transducer would be—that is, the “0” signal position in the Bessel array. (Note that the “0” does not mean that there is no signal provided to the tweeter, only that the Bessel circuit is not providing a signal to it.)

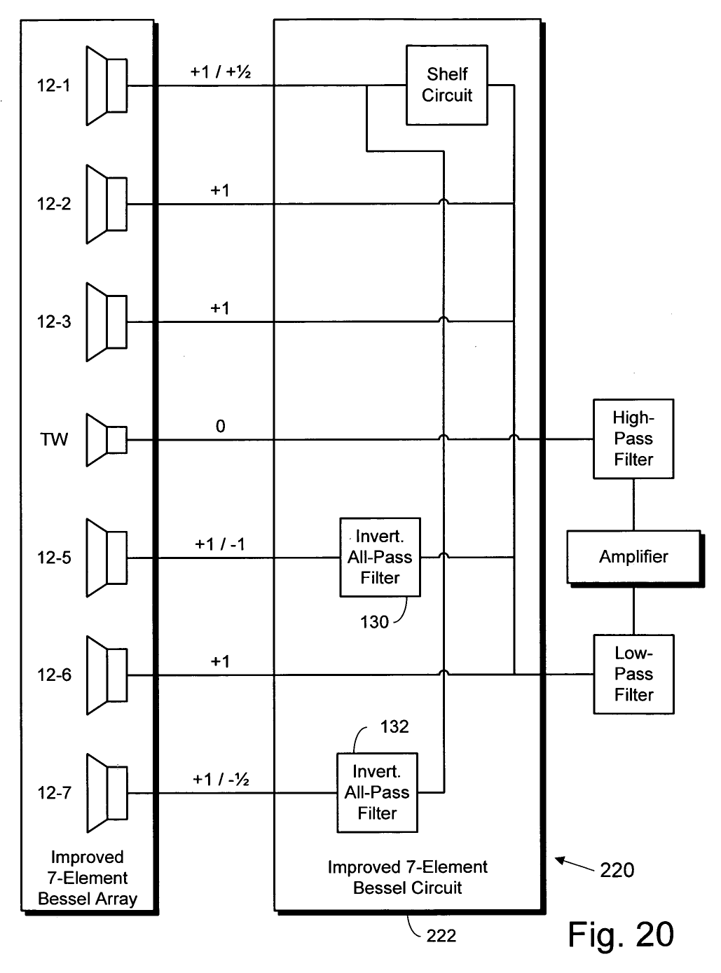

FIG. 20 illustrates an Improved 7-Element Bessel Array 220 using the same tweeter-equipped transducer configuration as in FIG. 19. The tweeter is driven by a high-pass filter, and an Improved Bessel Circuit 222 is driven by a low-pass filter. The first transducer is driven with a “+1/+½” signal from a shelf circuit, the fifth transducer is driven with a “±1” signal from an inverting all-pass filter, and the seventh transducer is driven with a “+1/−½” signal from a shelf circuit and an inverting all-pass filter in series. In one embodiment, as shown, there is one shelf circuit for the first and seventh transducers. In other embodiments, the seventh transducer's inverting all-pass filter may be driven by its own shelf circuit.

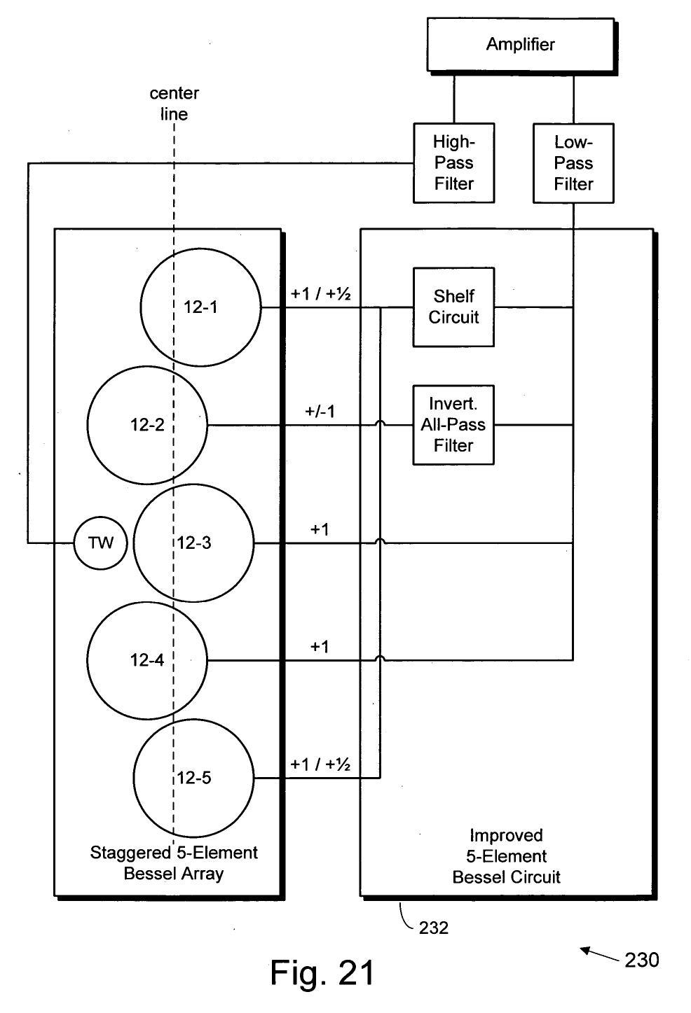

FIG. 21 illustrates a Staggered Bessel Array system 230. A transducer array includes five transducers 12-1 to 12-5 which, rather than being arranged in a conventional straight line, are staggered alternately from an imaginary vertical center line shown as a dashed line in FIG. 21. The odd-numbered transducers are offset in one direction from the center line, and the even-numbered transducers are offset in the opposite direction. In order to maintain the desirable Bessel functionality, the transducers are on equal vertical center-to-center spacing. Offsetting them in the horizontal direction does not significantly affect the Bessel off-axis performance improvement, as long as they are not offset too far. In one embodiment, they are horizontally offset less than one half the radius of one of the transducers. In another embodiment, they are horizontally offset less than the radius. In another embodiment, they are offset less than three-quarters the diameter of one of the transducers. And in yet another embodiment, they are offset less than the diameter.

In some embodiments, a tweeter is added, preferably on the same vertical positioning as II the center transducer, which is where the acoustical center of the Bessel array appears to be located. In some such embodiments, the tweeter is advantageously offset in the opposite direction than the center transducer, putting it as close to the center line as possible.

In one such system, there are five transducers in the Bessel array, and a low-pass filter governs the input to the Improved Bessel circuit. The circuit includes a shelf circuit providing a “+1/+½” signal to the first and fifth transducers, and an inverting all-pass filter providing a “±1” signal to the second transducer. Other systems may use 7-Element or 9-Element Bessel arrays. The offset may be as shown, with every other transducer offset in an opposite direction. Or, the first, fourth, etc. transducers may be offset left, the second, fifth, etc. transducers may be on the center line, and the third, sixth, etc. transducers may be offset right. Or, the transducers may be offset in a zigzag pattern.

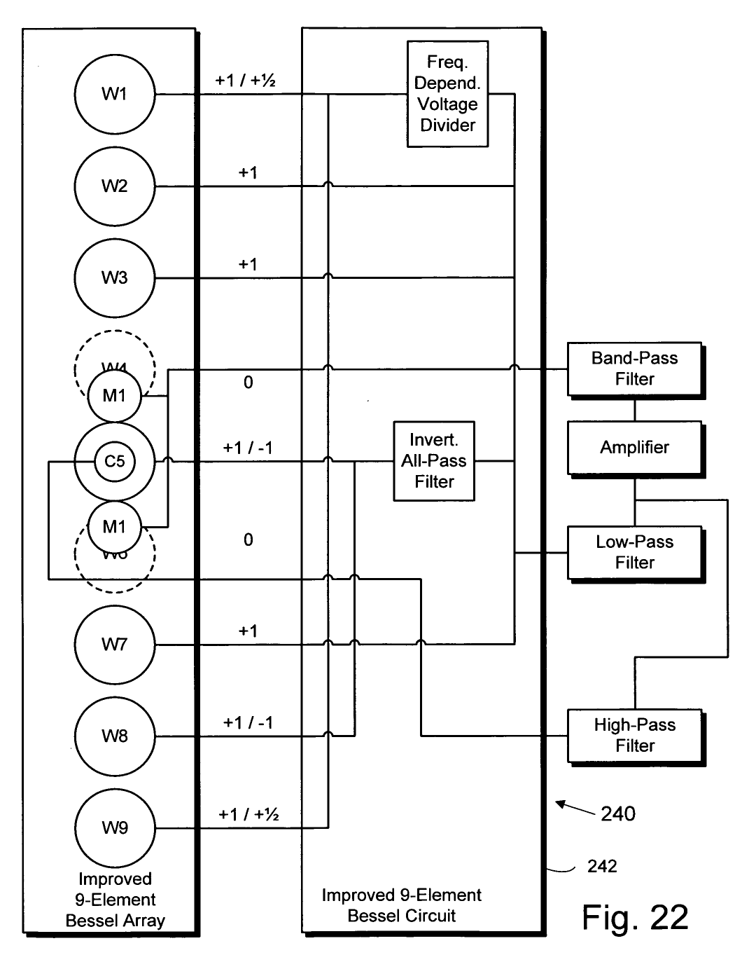

FIG. 22 illustrates an improved 9-Element Bessel Array system 240 according to yet another embodiment of this invention, with an Improved 9-Element Bessel Circuit 242. The Improved Bessel Array includes woofer or full-range transducers in the first, second, third, seventh, eighth, and ninth positions. The fifth position is occupied by a coaxial transducer whose tweeter is driven by a high-pass filter. The first and ninth transducers W1, W9 are driven with a “+1/+½” signal from a frequency-dependent voltage divider such as a shelf circuit. The woofer of the coaxial in the fifth position, and the eighth transducer W8 are driven by a “±1” signal from an inverting all-pass filter. The second, third, and seventh transducers are driven with “+1” signals from the low-pass filter.

The fourth and sixth “0” positions (whose physical positions are marked by dashed circles W4 and W6, partially obscured) are not occupied by the same type of transducer as the first, second, etc. positions. Rather, a pair of mid-range transducers M1, M2 are positioned as close to the coaxial transducer as possible, which puts them closer to the fifth position than the fourth and sixth positions are. That is, the mid-range transducers do not need to be on the same on-center spacing as the woofers. The mid-range transducers are driven by a band-pass filter whose lower cutoff frequency could be set in the 200-10000 Hz range and whose upper cutoff frequency could be set in the 1000-8000 Hz range, or both could be set to whatever frequency ranges the designer chooses.

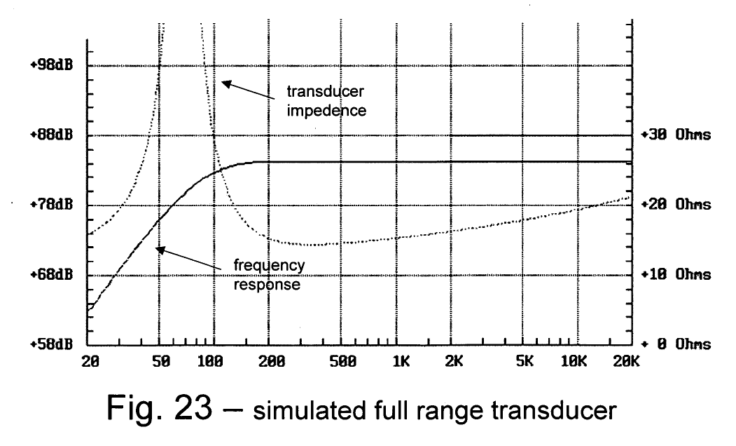

FIG. 23 illustrates a frequency response of a simulated full range transducer modeled as an idealized omni-directional point source. In other words, there is no real-world driver directivity taken into account in the following simulations.

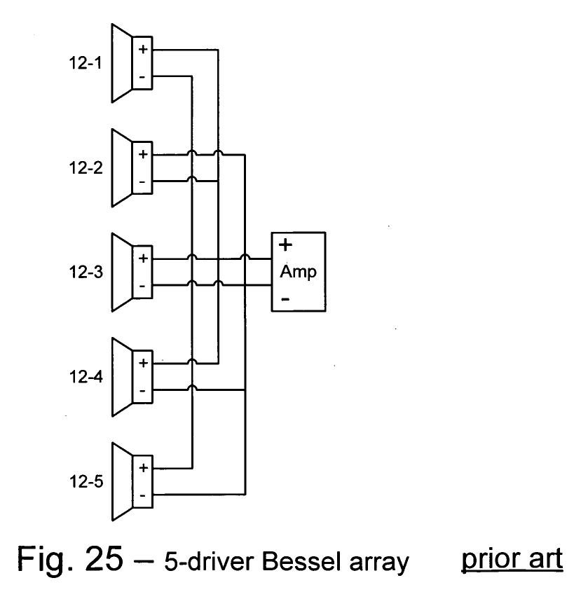

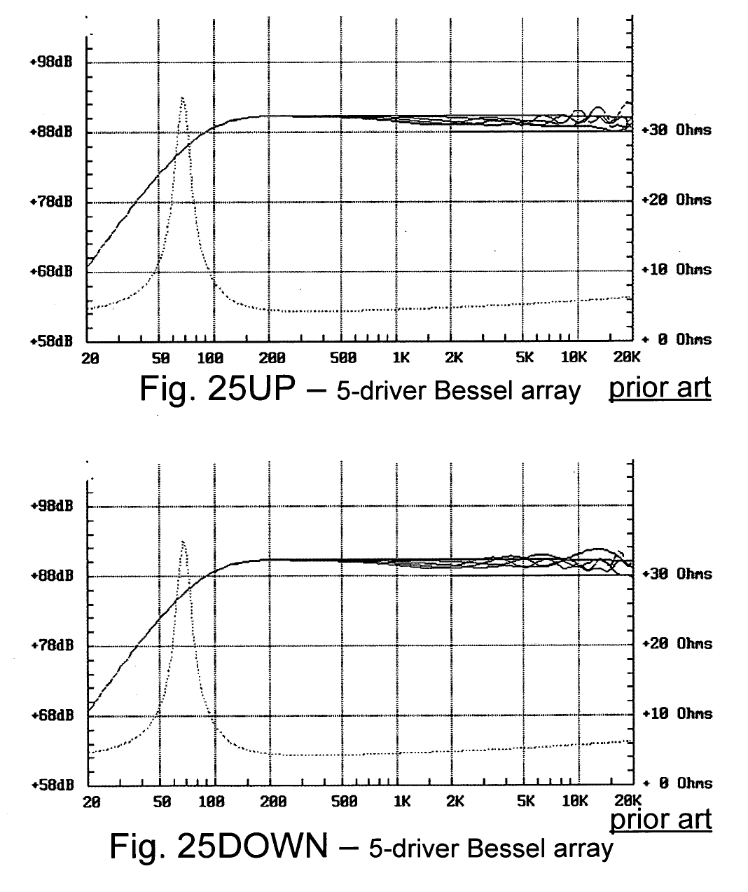

The darker, heavier line is the frequency response, shown from 20 Hz to 20 kHz. The lighter, dotted line is the impedance of the transducer. The frequency response is essentially flat at 84 dB from approximately 150 Hz to 20 kHz. This simulated transducer is used as the basis for the simulated systems whose frequency response is illustrated in FIGS. 25-36.

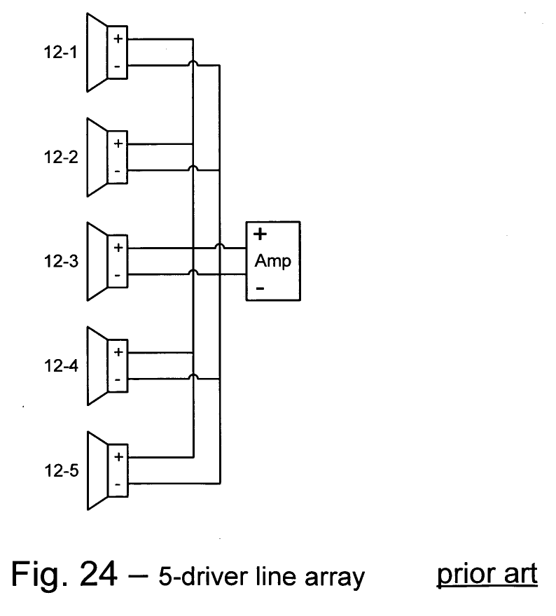

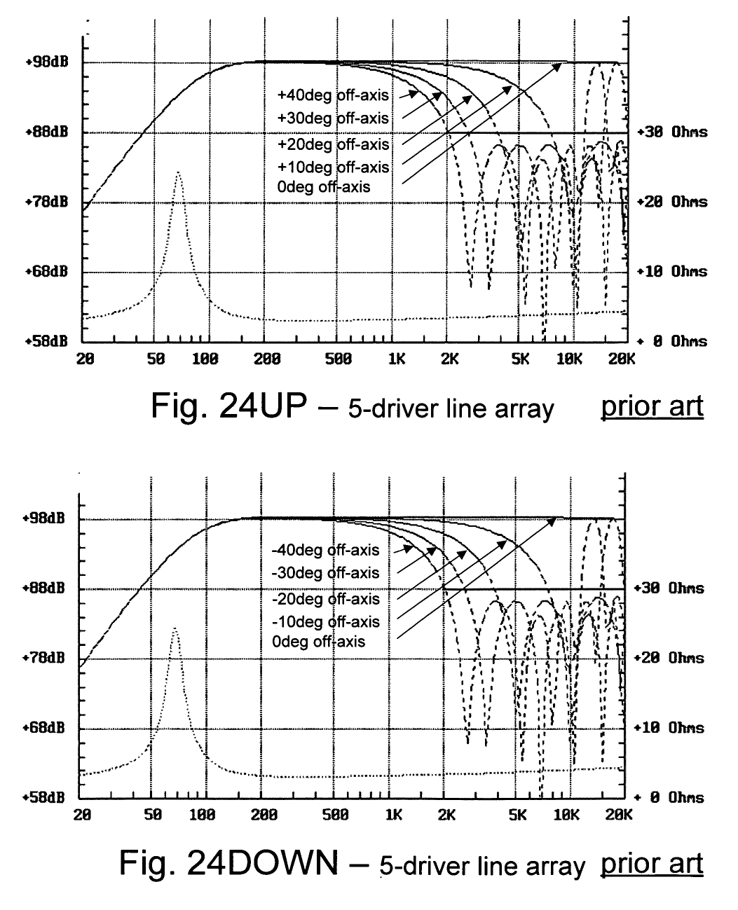

FIG. 24 illustrates 5-transducer simple line array using five copies of the transducer of FIG. 23 with a center-to-center spacing of 4 cm.

FIGS. 24UP and 24DOWN are frequency response graphs generated by a computer simulation analysis of the line array of FIG. 24. The upper graph shows five frequency response curves, measured at 0°, +10°, +20°, +30+, and +40° off-axis, and the lower graph shows frequency response curves, measured at 0°, −10°, −20°, −30°, and −40° off-axis. 0° (on-axis) is defined to be the position where the axis is centered on the middle (in this case third) driver and perpendicular to the line array.

For purposes of consistency, the line array is (and subsequent arrays in FIGS. 25 etc. are) modeled as a vertical array such as those described elsewhere in this patent, and the positive off-axis angles are those above horizontal and the negative off-axis angles are those below horizontal. The upper (positive) angles are more significant than the lower (negative) angles in typical applications in which the listener's ear is more likely to be above the center of the array than below it. In other words, most speakers are placed on the floor rather than on the ceiling. And if a ceiling-mounted array is to be used, it is simply inverted, such that the positive angles are those pointing downward toward the listener and the negative angles are those pointing toward the ceiling.

The frequency response graphs demonstrate the very significant comb filtering and interference patterns which occur in a line array in the higher frequencies—above about 600 Hz in the present example. The farther off-axis, the worse these effects are, and the worse the audible frequency response distortion will be. In the case of the simple line array, the off-axis performance is symmetrical with respect to the positive and negative angles.

In the range roughly between 150 Hz and 600 Hz, the line array's output is extremely flat at 98 dB, a 14 dB improvement over the 84 dB output of the single transducer. The array's impedance is significantly lower than the single transducer, as the five drivers are all coupled in parallel.

FIG. 25 illustrates a modeled conventional 5-transducer Bessel array. The first and fifth transducers are wired in series to achieve the “+ 1/2” signal for each, the second transducer is wired backward to achieve the “−1” signal, and the third and fourth transducers are wired in parallel to achieve the “+1” signal.

FIGS. 25UP and 25DOWN illustrate the simulated frequency response at positive off-axis angles (0°, +10°, +20°, +30°, and +40°) and negative off-axis angles (0°, −10°, −20°, −30°, and −40°), respectively. As can be readily observed by comparing FIGS. 25UP and 25DOWN to FIGS. 24UP and 25DOWN, the Bessel array provides a truly remarkable improvement in off-axis performance versus the line array. Unfortunately, however, the output has been rather drastically reduced from 98 dB to 90 dB across the flat region of the frequency range.

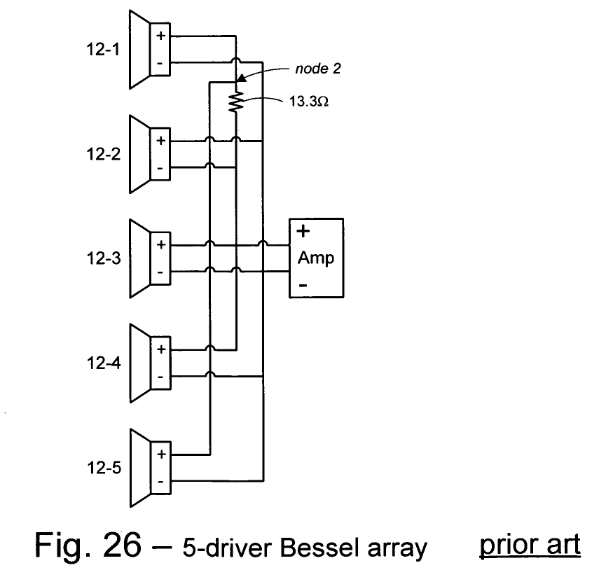

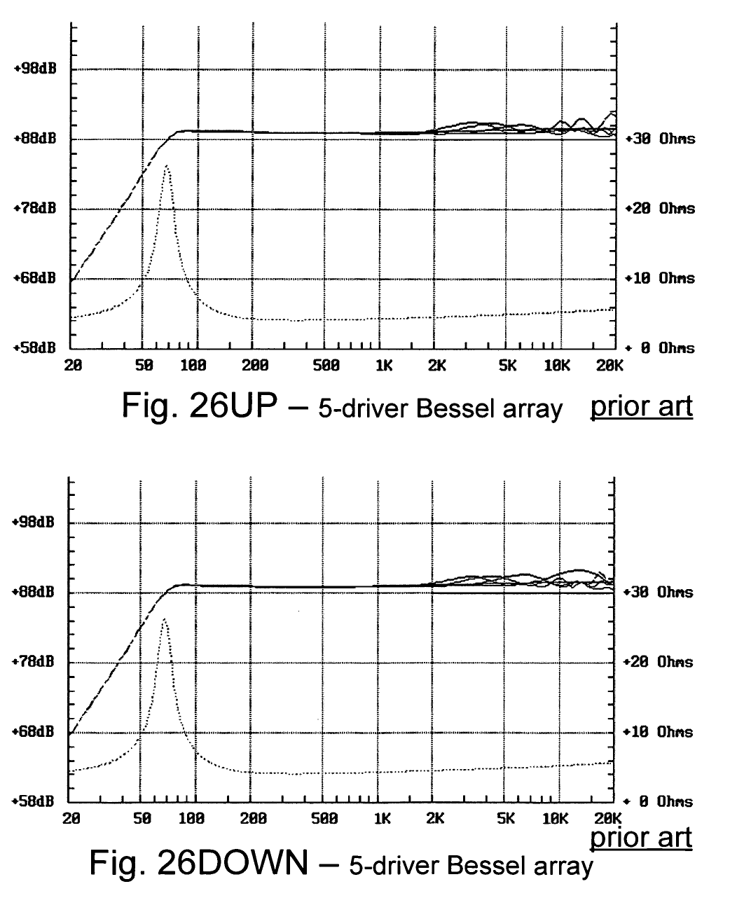

FIG. 26 illustrates a modeled 5-driver Bessel array whose Bessel circuit uses a 13 ohm resistor which connects the “+” amplifier output to the “+” terminals of both the first and fifth transducers, which are connected in parallel.

FIGS. 26UP and 26DOWN illustrate the simulated off-axis frequency response. Compared to the Bessel array of FIG. 25, the array's output has been reduced slightly, by roughly 1 dB, but in exchange for the bass roll-off frequency being extended down from roughly 150 Hz to roughly 75 Hz, and in exchange for the Bessel transition frequency being pushed from roughly 600 Hz to roughly 2000 Hz.

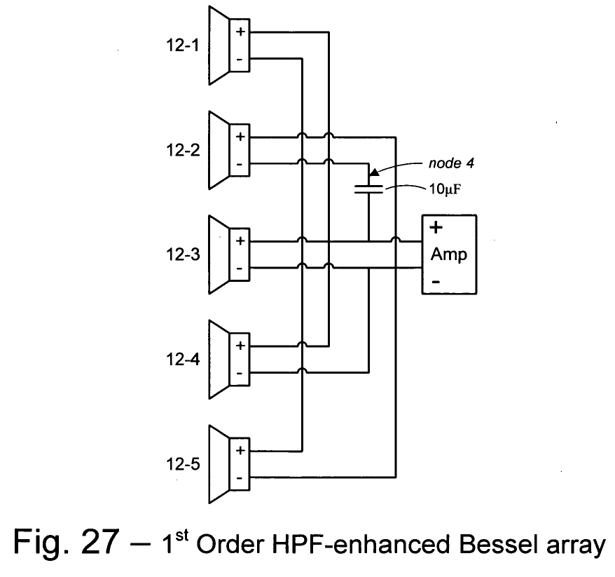

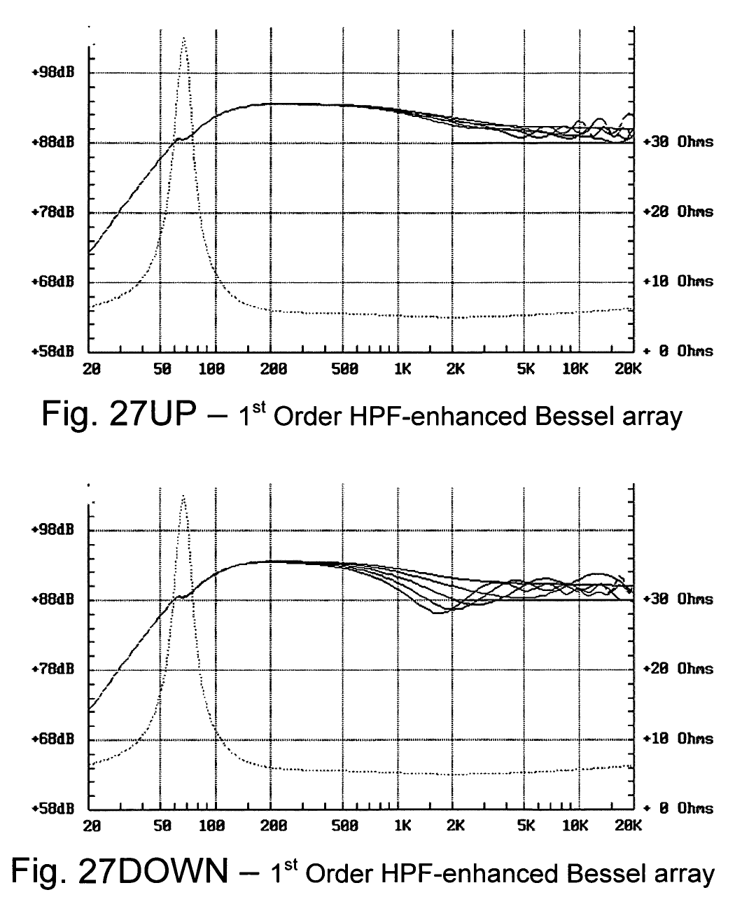

FIG. 27 illustrates a modeled improved Bessel array which adds a first order high-pass filter to its Bessel circuit. In the example shown, the HPF consists of a 10 μF capacitor coupled between the amplifier's “+” output and the second transducer's “−” terminal, providing the “0/−1” input.

FIGS. 27UP and 27 DOWN illustrate that the simulated output of the array has been raised from around 90 dB of FIG. 25 to almost 94 dB for much of the mid-bass frequency range between 100 Hz and 1 kHz. The negative off-axis angle frequency response shows a less uniform upper end response than that of the conventional Bessel array, in exchange for this very desirable 4 dB improvement in output.

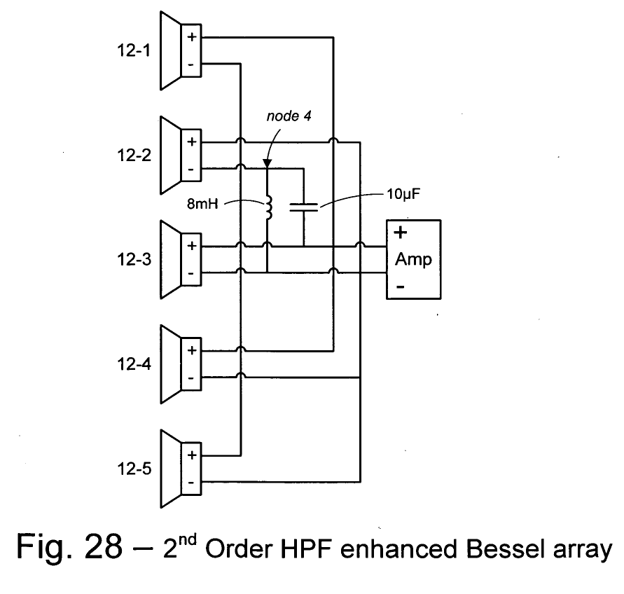

FIG. 28 illustrates a modeled improved Bessel array having a second order high pass filter, which consists of a 10 μF capacitor coupled between the amplifier's “+” output and the “−” terminal of the second transducer, and an 8 mH inductor coupled between the amplifier's “−” output and the “−” terminal of the second transducer.

FIGS. 28UP and 28DOWN illustrate the simulated frequency response. The notch around 60 Hz has been removed, and there is almost a 1 db increase from 200 Hz to 500 Hz.

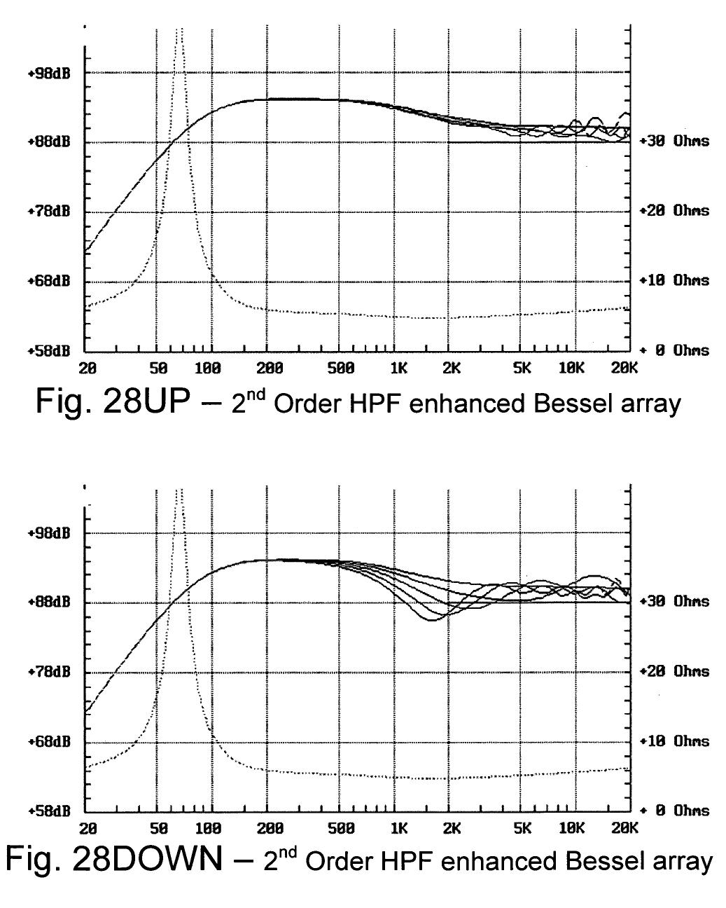

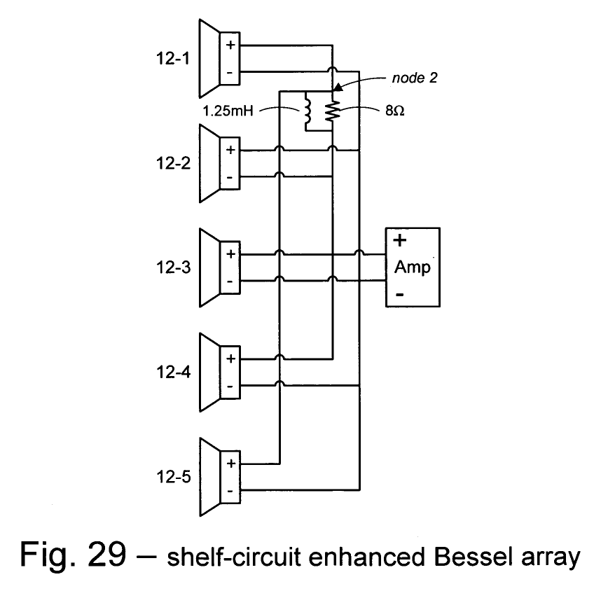

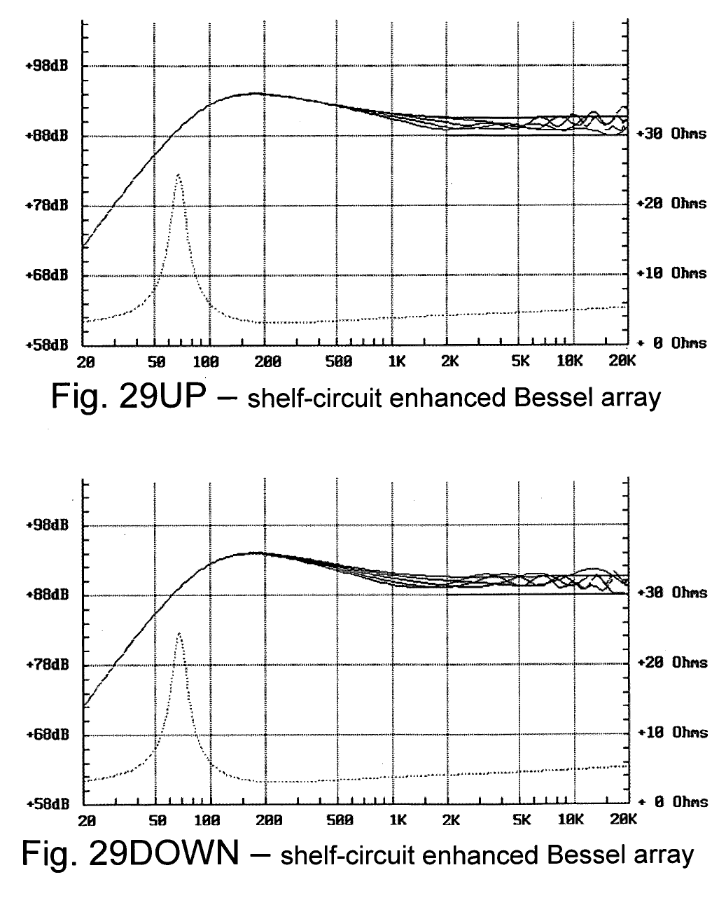

FIG. 29 illustrates an improved Bessel array in which the Bessel circuit includes a shelf circuit. A 1.25 mH inductor and an 8 ohm resistor are coupled in parallel between the amplifier's “+” output and the “+” terminals of the first and fifth transducers.

FIGS. 29UP and 29DOWN illustrate the simulated frequency response. As compared to FIG. 27, the negative off-axis frequency response has been significantly improved, and the anomalous notch around 65 Hz has been removed, but the tradeoff is that the output gain begins to taper off rather quickly above 200 Hz, whereas in FIG. 27 it stayed fairly flat out to 800 Hz or so.

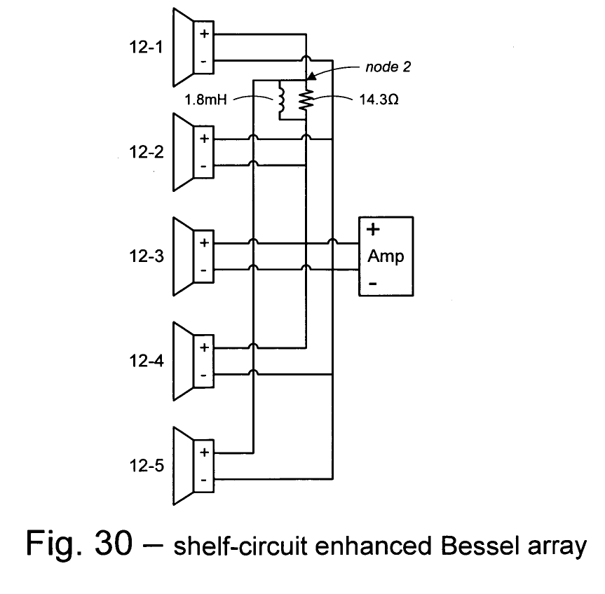

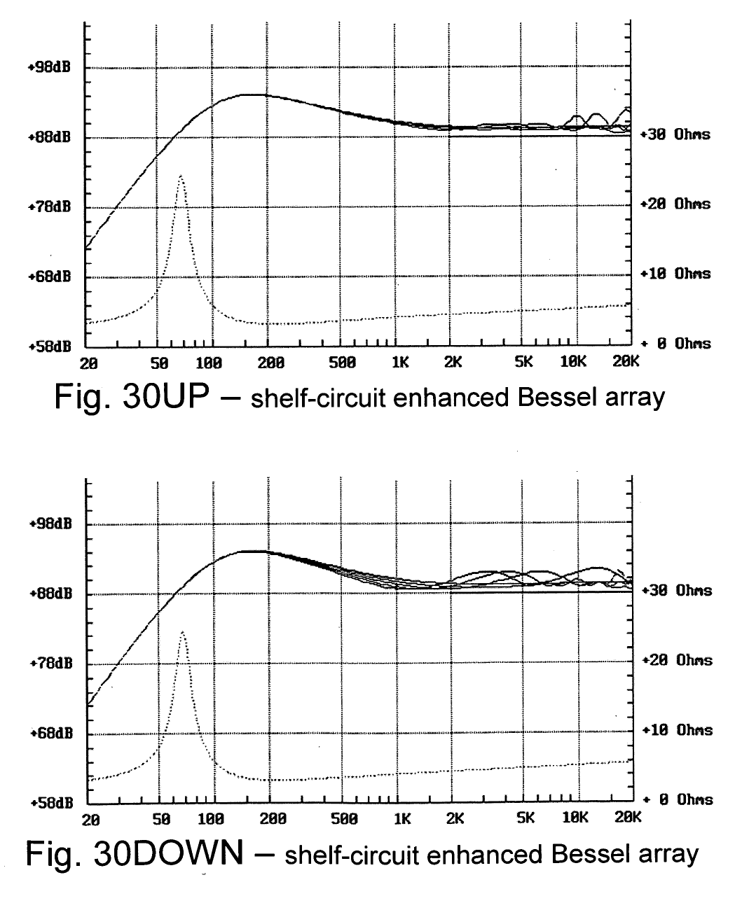

FIG. 30 illustrates a similar, improved Bessel array in which the Bessel circuit includes a shelf circuit consisting of a 1.8 mH inductor and a 14.3 ohm resistor, and which is otherwise the same as that of FIG. 29. FIGS. 30UP and 30DOWN demonstrate that the positive off-axis frequency response has been tightened up.

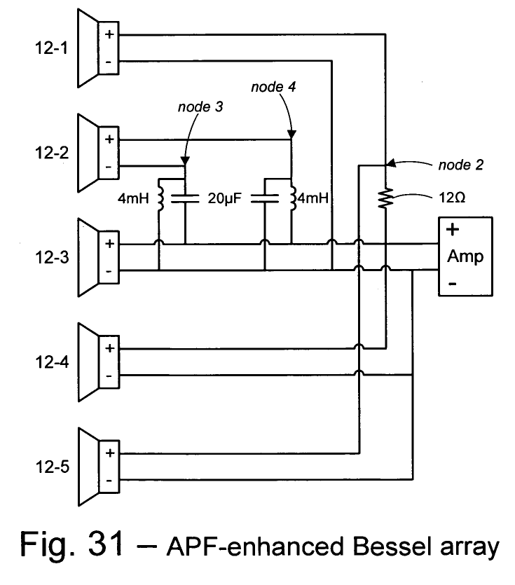

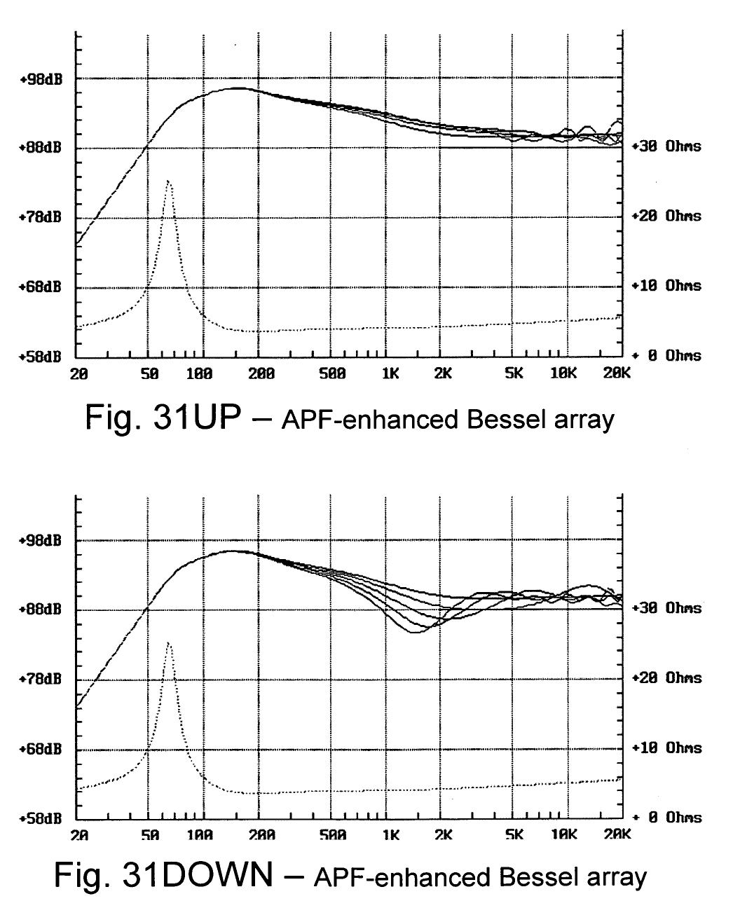

FIG. 31 illustrates an improved Bessel array including an all-pass filter. A 20 μF capacitor is coupled between the amplifier's “+” output and the “−” terminal of the second transducer. A 4 mH inductor is coupled between the amplifier's “−” input and the “−” terminal of the second transducer. A second 20 μF capacitor is coupled between the “+” terminal of the second transducer and the amplifier's “−” output. A second 4 mH inductor is coupled between the amplifier's “+” output and the “+” terminal of the second transducer. A 12 ohm resistor is coupled between the amplifier's “+” output and the “+” terminals of the first and fifth transducers.

FIGS. 31UP and 31DOWN demonstrate that, as compared to FIG. 30, the peak output has been increased from 94 dB to 96 dB.

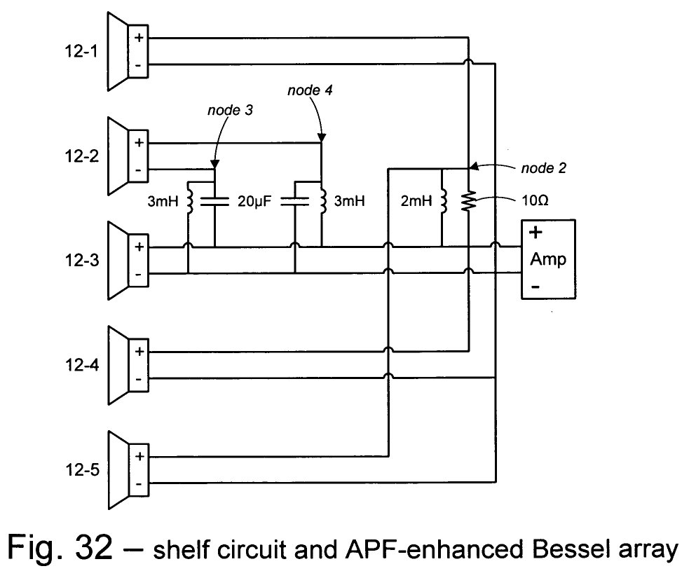

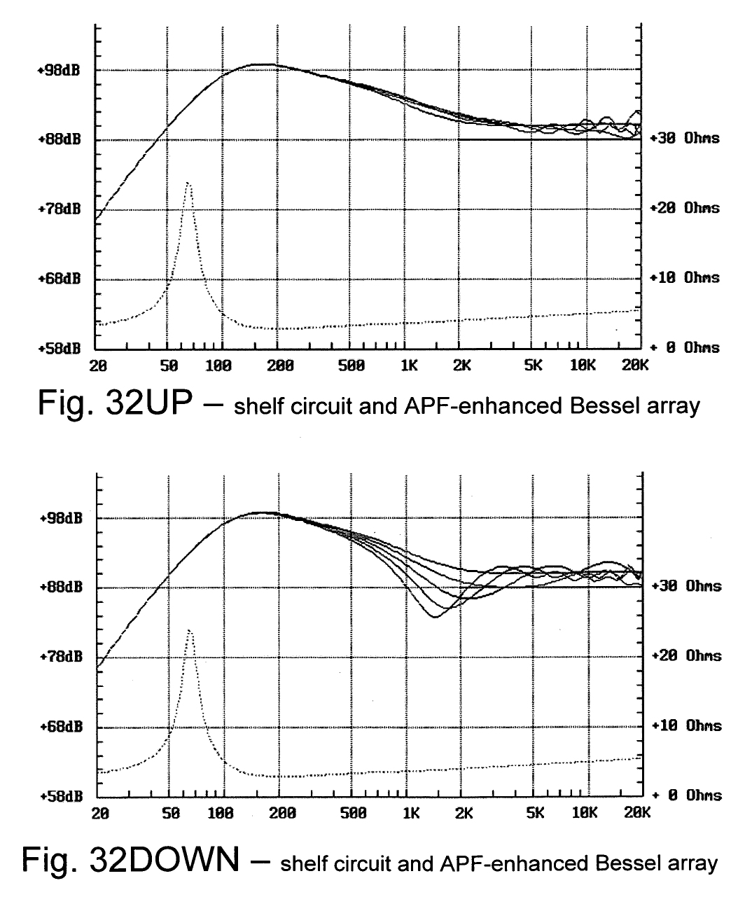

FIG. 32 illustrates an improved Bessel array in which the Bessel circuit uses both a shelf circuit and an all-pass filter. The circuit is very similar to that of FIG. 31, except that the inductors have been reduced from 4 mH to 3 mH, the resistor has been reduced from 12 ohm to 10 ohm, and a 2 mH inductor has been added in parallel with it, between the amplifier's “+” output and the “+” terminals of the first and fifth transducers.

FIGS. 32UP and 32DOWN demonstrate that, as compared to FIG. 31, the peak output has further been increased to almost 99 dB.

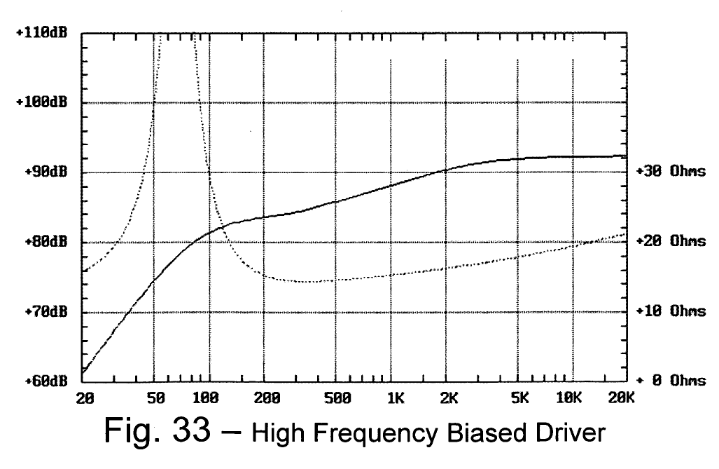

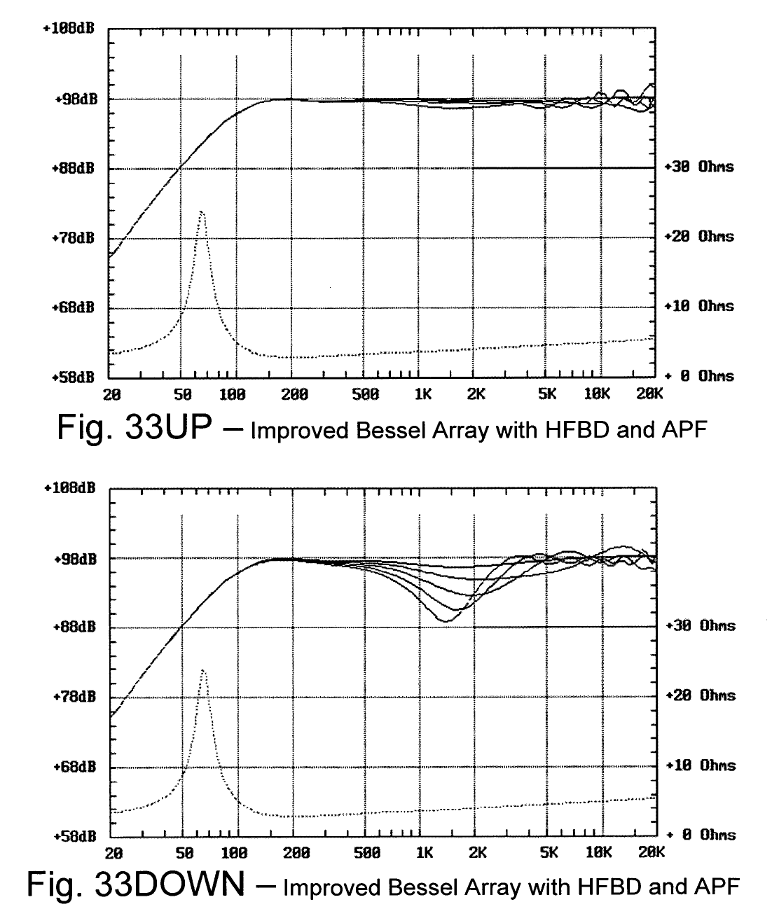

FIG. 33 illustrates a frequency response of a simulated high frequency biased driver modeled as an idealized omni-directional point source. Horn loaded drivers are one example of this sort of “bright” transducer.

In the Improved Bessel Array of FIG. 5, the output is 4 transducer units in the low frequencies, and 2 transducer units in the high frequencies. In FIG. 11, the output is 5 transducer units in the low frequencies, and 2 transducer units in the high frequencies. In FIG. 13, the output is 6 transducer units in the low frequencies, and 2 transducer units in the high frequencies. In FIG. 15, the output is 9 transducer units in the low frequencies, and 2 transducer units in the high frequencies. Using a “bright” transducer, whose high frequency output is louder than its low frequency output, is one way for the designer to balance the output of the Improved Bessel Array.

FIGS. 33UP and 33DOWN illustrate the simulated frequency response of a 5-driver Improved Bessel Array using an all-pass filter (such as in FIG. 5) and the high frequency biased driver of FIG. 33. At positive off-axis listening angles, the output is remarkably flat at 98 dB from 150 Hz upward.

### 4-Transducer Reduced Bessel Array

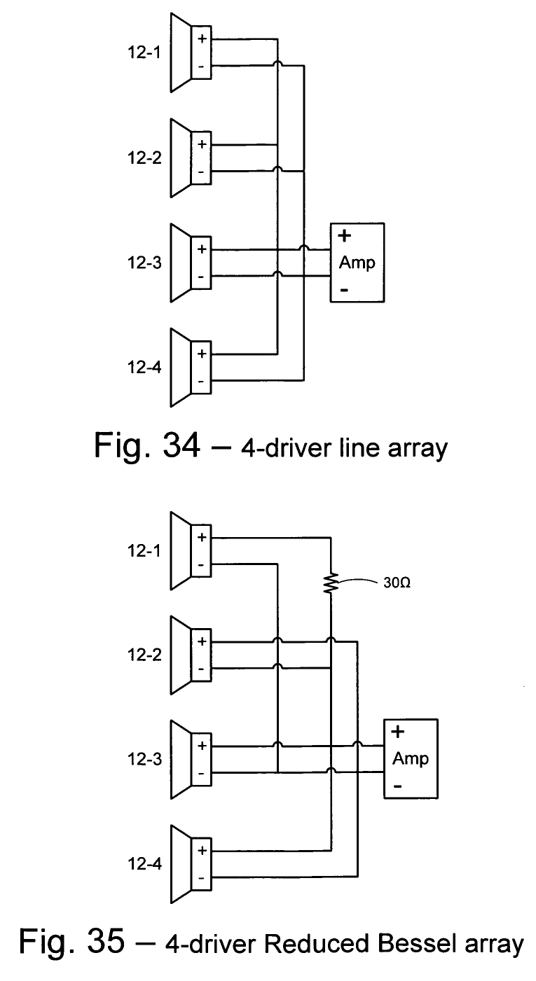

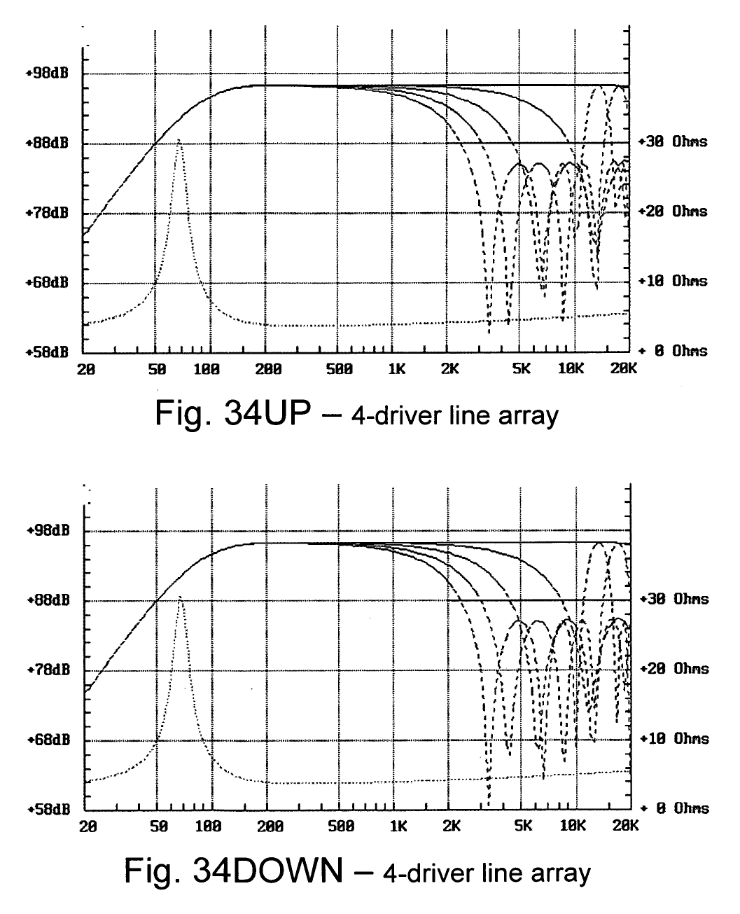

FIG. 34 illustrates a conventional 4-driver line array. FIGS. 34UP and 34DOWN illustrate its simulated frequency response. Its output is roughly 96 dB, and it begins to exhibit significant comb filtering and interference patterns above about 1 kHz.

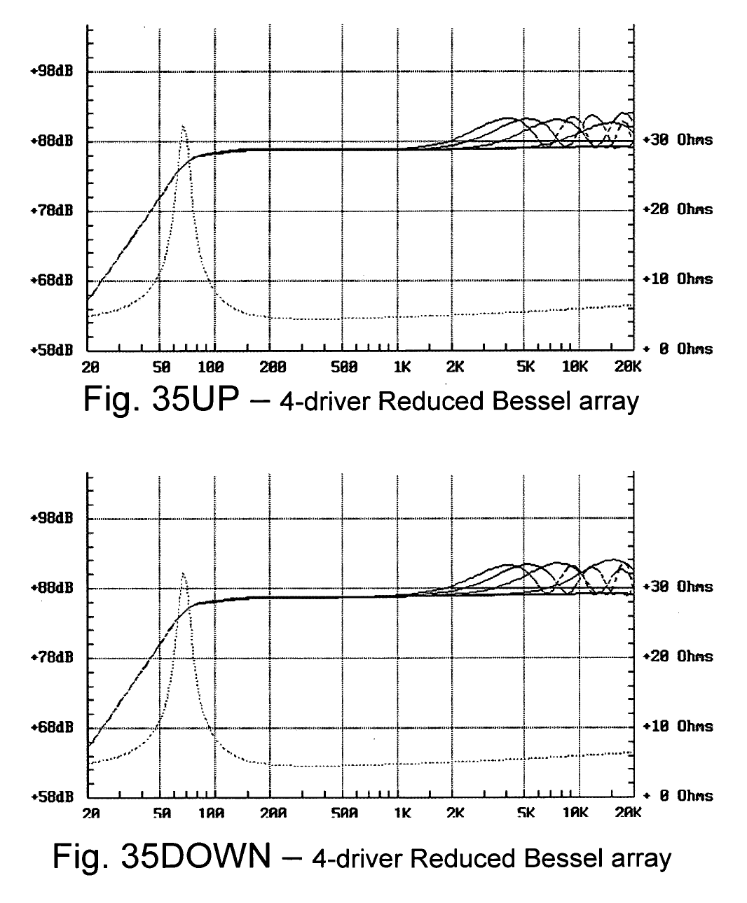

FIG. 35 illustrates a 4-transducer Reduced Bessel Array. The term “Reduced Bessel” is used to suggest that the array uses less than the full 5, 7, or 9, etc. transducer complement taught by the known Bessel array art.

The array uses four transducers 12-1 to 12-4 on equal on-center spacing, and a Reduced Bessel circuit. In one embodiment, the circuit includes a 30 Ohm resistor coupled between the amplifier's “+” output and the “+” terminal of the first transducer. The first transducer's “−” terminal is coupled to the amplifier's “−” output. Thus, the first transducer is fed a substantially reduced (less than “+1”) signal. The third and fourth transducers are fed “+1” signals with their “+” terminals are coupled to the amplifier's “+” output and their “−” terminals coupled to the amplifier's “−” output. The second transducer is fed a “−1” signal with its “−” terminal coupled to the amplifier's “+” output and its “+” terminal coupled to the amplifier's “−” output.

FIGS. 35UP and 35DOWN show the simulated off-axis frequency response of the 4-transducer Reduced Bessel Array. From about 80 Hz to about 1200 Hz, its output is just above 86 dB, versus about 96 dB of the FIG. 33 line array. However, its off-axis frequency response is remarkably improved, compared to that of the simple line array. Whereas the line array transitions into a heavy comb filter pattern above about 1.5 kHz, the Reduced Bessel array actually exhibits an off-axis average output rise above about 1.5 kHz, with a relatively small degree of comb filtering which nevertheless only knocks the output down to the 86 dB level. The skilled designer will be able to use this to his advantage, as a means of compensating for the high frequency directivity of real world drivers.

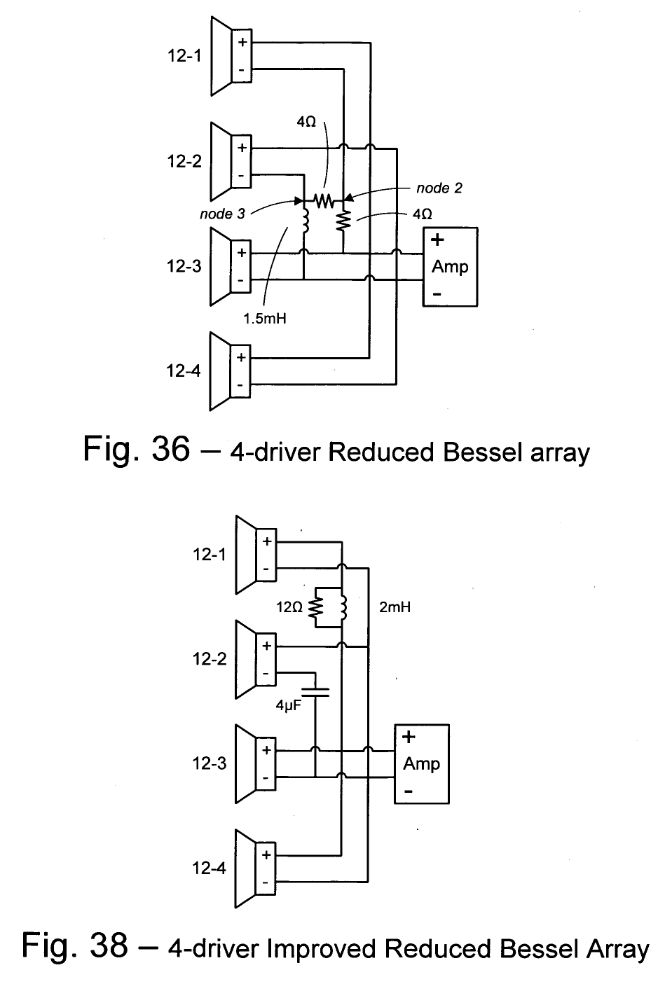

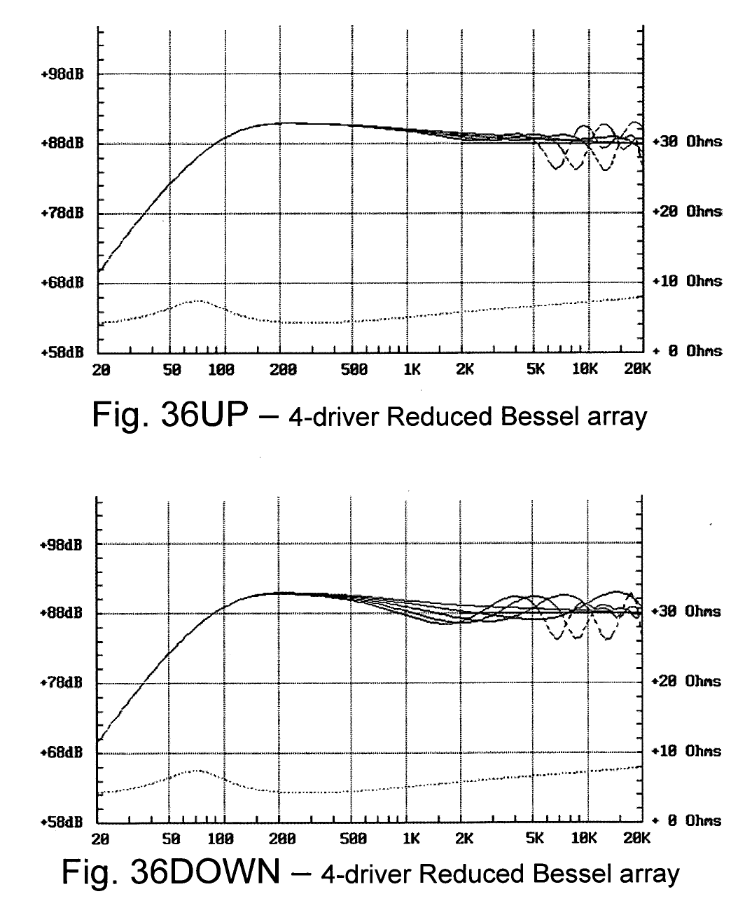

FIG. 36 illustrates a 4-transducer Reduced Bessel Array according to another embodiment of this invention, utilizing a series R-L bypassed across the second transducer. The “+” terminals of the first, third, and fourth transducers are coupled to the amplifier's “+” output, and the “−” terminals of the third and fourth transducers are coupled to the amplifier's “−” output. The third and fourth transducer thus receives “+1” signals. The “+” terminal of the second transducer is coupled to the amplifier's “−” output. The “−” terminal of the second transducer is coupled via a series-connected 1.5 mH inductor and 4 ohm resistor to the amplifier's “−” output, and via another 4 ohm resistor to the amplifier's “+” output. The first transducer's “−” terminal is coupled to the “−” terminal of the second transducer and to the amplifier's “+” output.

FIGS. 36UP and 36DOWN illustrate the simulated frequency response output of the 4-transducer Reduced Bessel Array. Output has been raised to about 91 dB, versus the approximately 87 dB output of the FIG. 35 array.

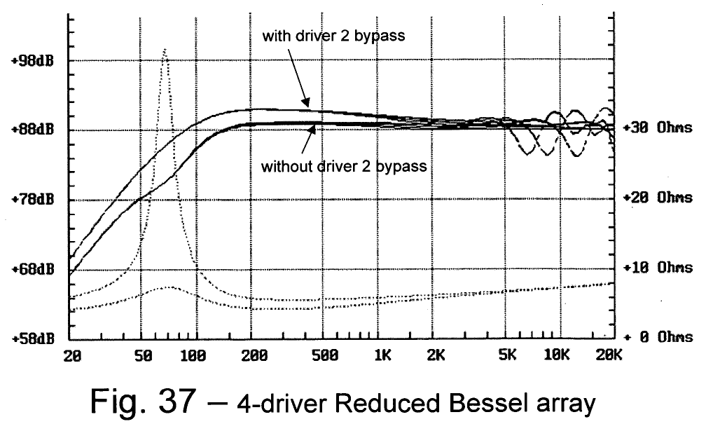

FIG. 37 shows the FIG. 36UP results with and without the series R-L active, overlaid for easier comparison.

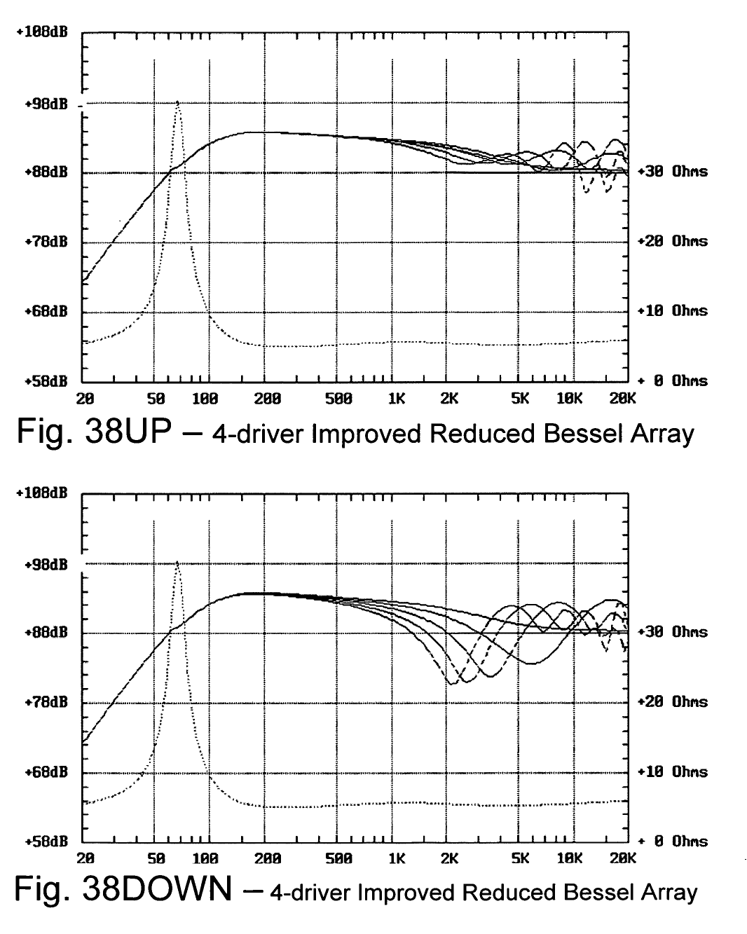

FIG. 38 shows a 4-driver Improved Reduced Bessel Array. A 4 μF capacitor is coupled between the amplifier's “−” output and the “−” terminal of the second transducer. A 12 ohm resistor and a 2 mH inductor are coupled in parallel between the amplifier's “+” output and the “+” terminal of the first transducer. FIGS. 38UP and 38DOWN illustrate the simulated frequency response output of the array.

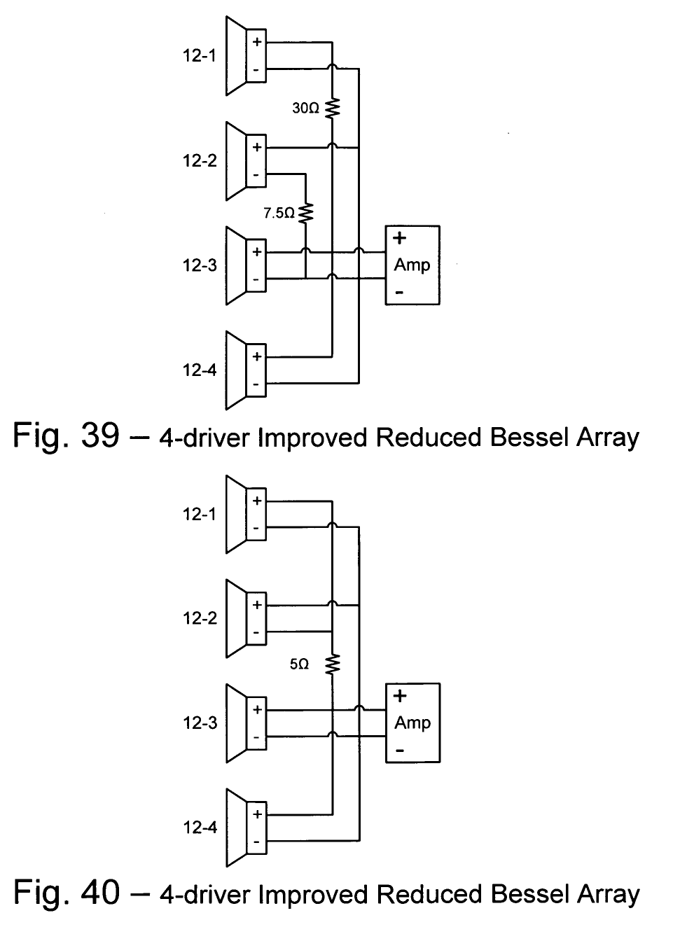

FIG. 39 shows another 4-driver Improved Reduced Bessel Array. A 7.5 ohm resistor is coupled between the amplifier's “−” output and the “−” terminal of the second transducer. A 30 ohm resistor is coupled between the amplifier's “+” output and the “+” terminal of the first transducer. FIGS. 39UP and 39DOWN illustrate the simulated frequency response output of the array.

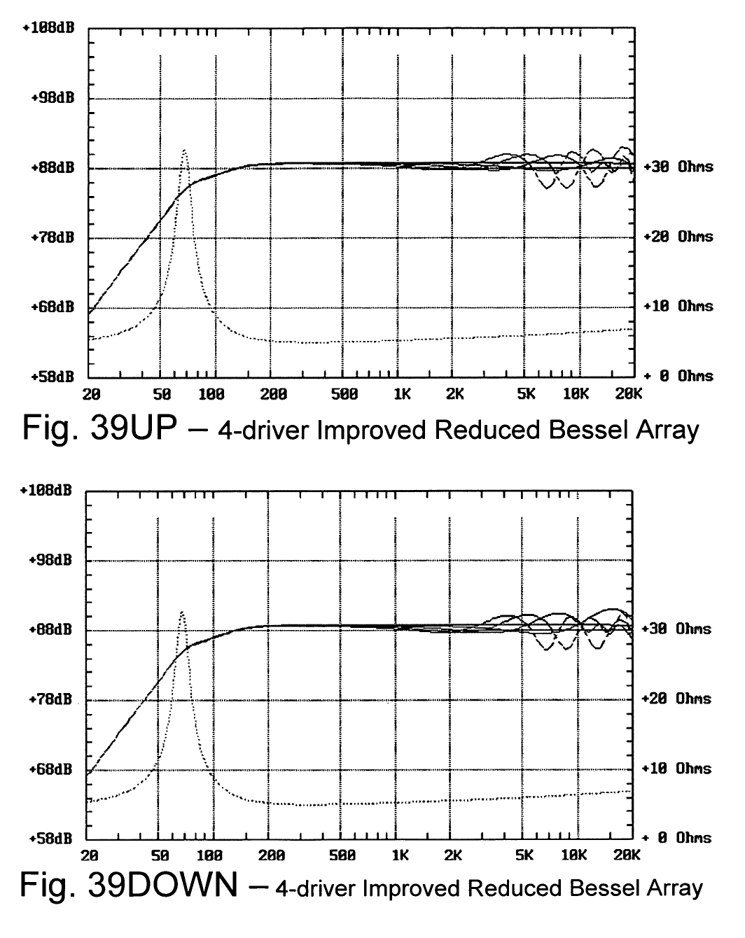

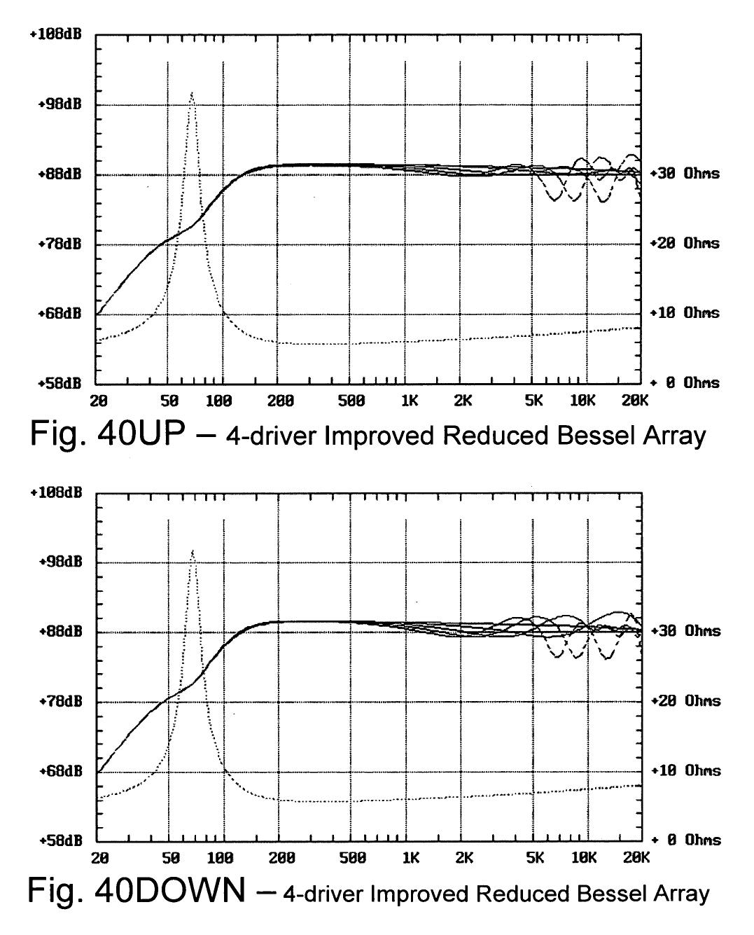

FIG. 40 shows yet another 4-driver Improved Reduced Bessel Array. A 5 ohm resistor is coupled between the amplifier's “+” output and both the “+” terminal of the first transducer and the “−” terminal of the second transducer. FIGS. 40UP and 40DOWN illustrate the simulated frequency response output of the array.

In other configurations, the Reduced Bessel Array principle can be applied to a 7-Element Bessel, using 6 transducers, or to a 9-Element Bessel, using 8 transducers, and so forth. Advantageously, one of the endmost transducers, and preferably the bottom transducer, is omitted.

### Pre-Amplifier Bessel Circuit

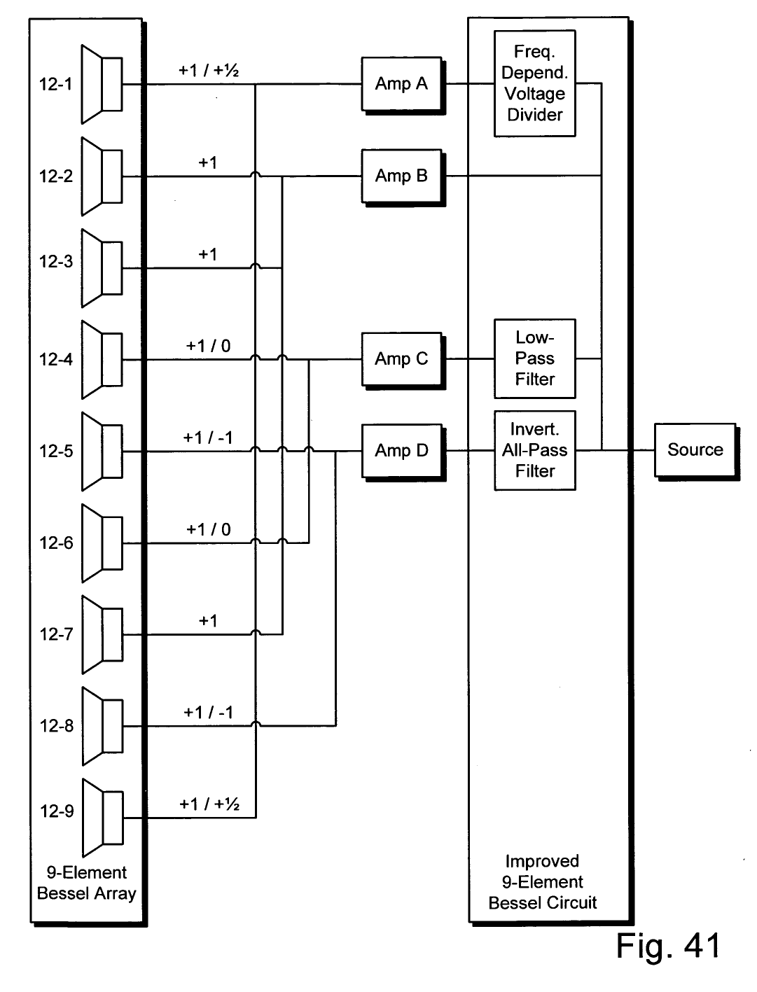

FIG. 41 illustrates an Improved 9-Element Bessel Array in which the Bessel functionality is provided “upstream” from the amplifier section. An input signal is provided from a source such as a CD player, radio, or what have you. This input signal is fed into an Improved 9-Element Bessel Circuit, and the outputs of the Bessel are then fed into the amplifier section of the system.

In some embodiments, the Bessel circuitry comprises conventional passive analog components such as resistors, capacitors, and inductors. In some such embodiments, the source provides an analog signal. In others, the source provides a digital signal which is converted into an analog signal by a digital-to-analog converter (not shown) at the input to the Bessel circuit.

In other embodiments, the Bessel functionality is provided by digital logic such as a digital signal processor executing a codec program. In some such embodiments, the source provides a digital signal. In others, the source provides an analog signal which is converted into a digital signal by an analog-to-digital converter (not shown) at the input to the Bessel circuit.

If the Bessel circuit is done digitally, its output is converted to analog either at the output of the Bessel circuit or at the input of the amplifier stage.

The amplifier stage includes a plurality of amplifiers which, although they operate separately upon their respective signal paths, may be under a common gain control mechanism (not shown). A first amplifier (Amp A) is fed by a frequency-dependent voltage divider and outputs a “+1/+½” signal to the first transducer. It may also provide that signal to the ninth transducer. Or, the ninth transducer may have its own amplifier, but that is a more expensive solution. A second amplifier (Amp B) is fed from the source and provides a “+1” signal to the second transducer, and advantageously also to the third and seventh transducers. A third amplifier (Amp C) is fed by a low pass filter and provides a “+1/0” signal to the fourth transducer, and advantageously also to the sixth transducer. A fourth amplifier (Amp D) is fed by an inverting all pass filter and provides a “±1” signal to the fifth transducer, and advantageously also to the eighth transducer.

Each amplifier provides a single “class” or characterization of signal.

### Dual Voice Coil Bessel Arrangement

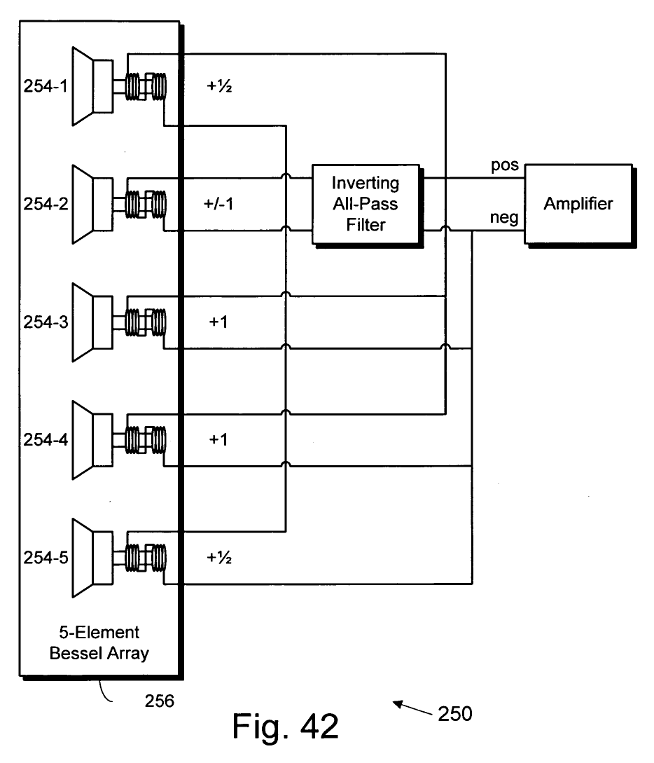

FIG. 42 illustrates an Improved 5-Element Bessel Array system 250 in which each of the transducers 254 is of the dual voice-coil variety. Although the voice coils are stylistically shown as being arranged at different axial positions, they may more typically be wound with one wrapped around the other or, in other words, layered on top of the other.

The amplifier signal is fed to both voice coils of the third and fourth transducers 254-3 and 254-4 at the “+1” positions. In one embodiment, the second transducer 254-2 is fed by an inverting all-pass filter such that it has a “±1” characteristic. In another embodiment, the second transducer is simply connected in reverse polarity to the amplifier and has a “−1” characteristic (in which case the array functions as a simple Bessel Array and not as a Super Bessel Array).

I 1 I The first and fifth transducers 254-1 and 254-5 are wired with their four voice coils in series as shown, whereby each transducer receives, in effect, a +½ signal. The two transducers combined present double the impedance of e.g. the third transducer. Thus configured, the first (+½) transducer will see half the voltage that the third transducer (+1) sees, which tends to result in a power input of ¼ that of the third transducer. As taught in the Philips patent, the Bessel coefficients refer to the input voltages applied to the respective transducers (which are assumed to be of nearly identical efficiency). The basic Bessel Array configuration is, itself, a compromise from the idealized configuration, in that the Bessel Array terminates at the ½ amplitude coefficients, whereas the mathematically idealized configuration would continue with ¼ and ⅛ etc. coefficients. So, even though the series connection of the four coils of the first and fifth transducers may not always present exactly ½ amplitude outputs, it does not unacceptably degrade the Bessel performance.

The same dual winding configuration may also be used with 7-Element, 9-Element, etc. Bessel arrays.

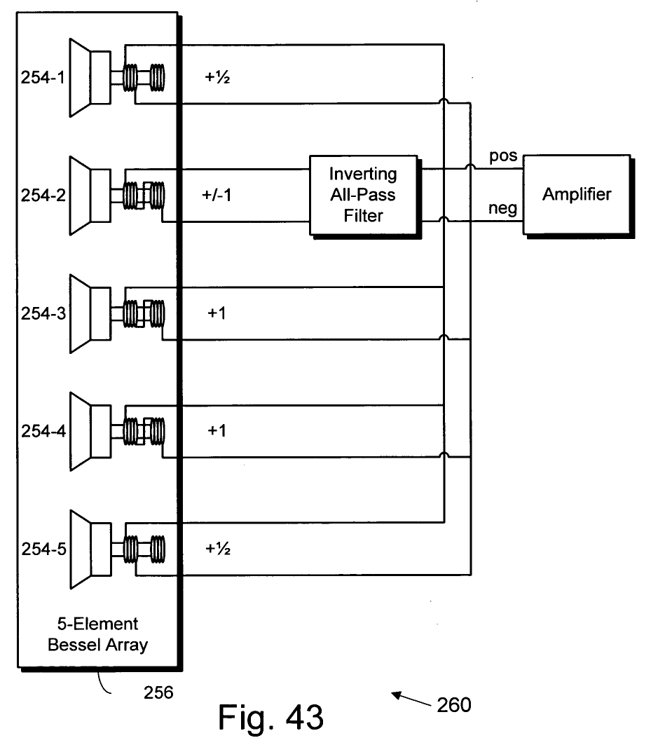

FIG. 43 illustrates a similar Improved 5-Element Bessel Array system 260 in which the two voice coils of the first transducer 254-1 are wired in series and fed a +1 signal from the amplifier, and the two voice coils of the fifth transducer 254-5 are wired in series and fed the +1 signal from the amplifier. The two voice coils of the third transducer 254-3 are wired in parallel and fed the +1 signal from the amplifier, as are the two voice coils of the fourth transducer 254-4. The two voice coils of the second transducer 254-2 are wired in parallel and driven by an inverting all-pass filter which receives the +1 signal from the amplifier. Each voice coil of the first and fifth transducers sees ½ the voltage that the other voice coils sees.

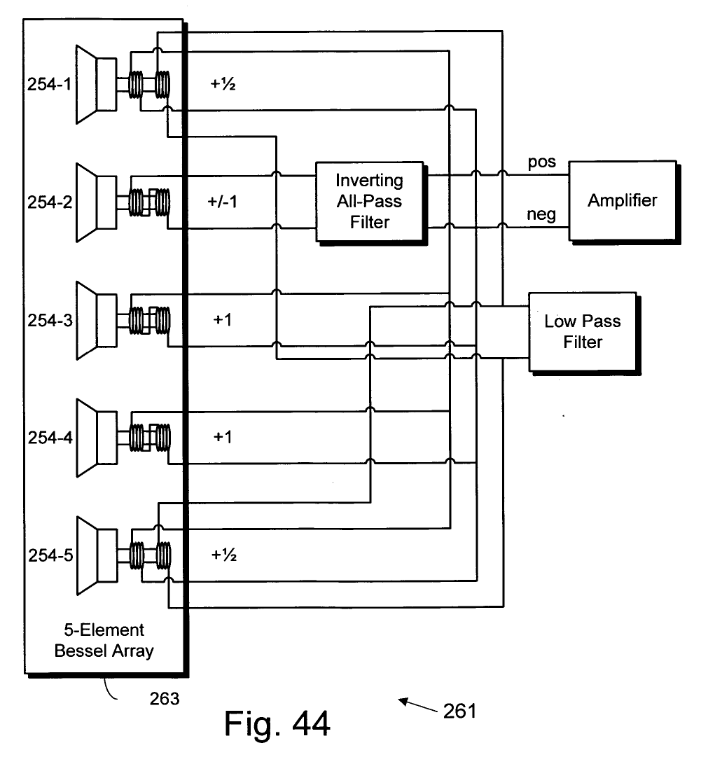

FIG. 44 illustrates yet another Super or Improved 5-Element Bessel Array system 261. The two voice coils of the third transducer 254-3 are wired in parallel and driven by the +1 signal from the amplifier, as are the two voice coils of the fourth transducer 254-4. The two voice coils of the second transducer 254-2 are wired in parallel and driven by an inverting all-pass filter which receives the +1 signal from the amplifier. One voice coil of the first transducer 254-1 is driven by the +1 signal from the amplifier, as is one voice coil of the fifth transducer 254-5. The other voice coil of the first transducer is driven by a low-pass filter, as is the other voice coil of the fifth transducer. The low-pass filter receives the +1 signal from the amplifier. In high frequencies, only one voice coil is driven in each of the first and fifth transducers, achieving the +½ coefficient. In low frequencies, the other voice coils of the first and fifth transducers are also driven, achieving a +1 output for improved bass.

### Enclosures

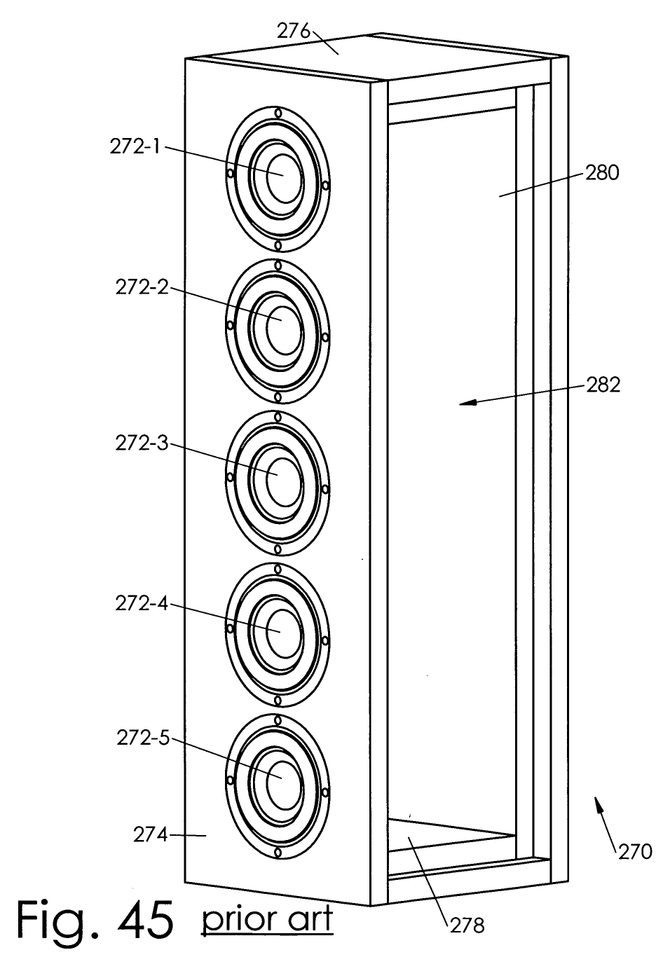

FIG. 45 illustrates a loudspeaker 270 according to the prior art. A five-driver line array of transducers 272-1 through 272-5 are coupled to a front panel 274 of an enclosure. The enclosure includes a top panel 276, bottom panel 278, rear panel 280, and side panels (left side panel not visible, right side panel removed). The enclosure contains a single enclosed air volume 282 into which all five transducers are coupled. This arrangement works because the five transducers are driven in phase with +1 signals.

Alternatively, FIG. 45 may be interpreted as representing a loudspeaker using e.g. a Improved Super Bessel Array in which all the transducers are driven +1 in the low frequency range and with their respective Bessel values in a high frequency range. If the transition frequency point is selected appropriately, the Improved Super Bessel Array can use a shared enclosed air volume; the determining fact is whether the transition frequency point is high enough that the different-value transducers will not unduly couple through the enclosed air volume.

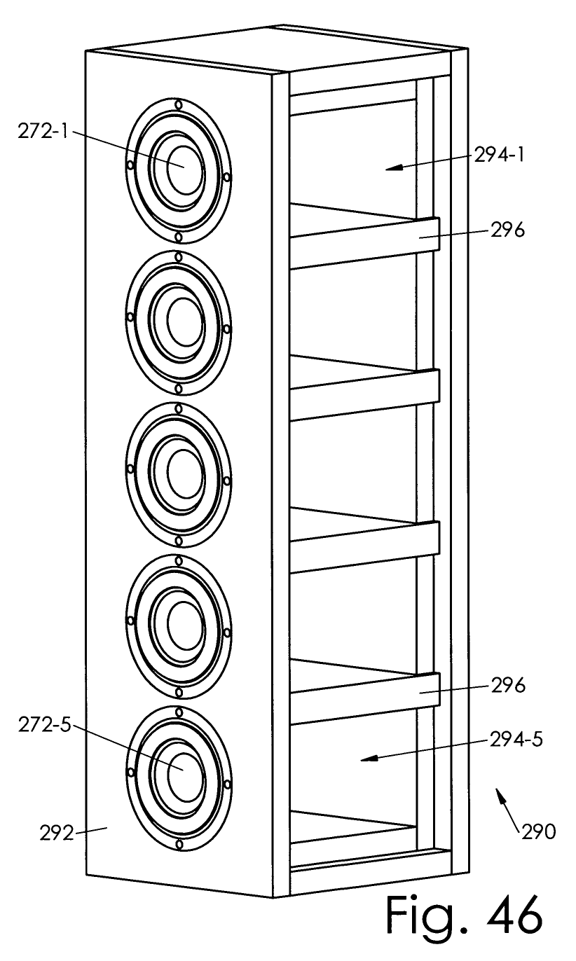

FIG. 46 illustrates a loudspeaker 290 in which five transducers 272 are coupled to a front panel 292 of an enclosure. Each transducer is coupled into its own, separate enclosed air volume 294-1 through 294-5, respectively. The air volumes are divided by partitions 296. In this configuration, the transducers can be wired as any version of standard, Improved, or Super Bessel Array, and the transition frequency point between the low and high frequency ranges can be selected without concern for cross-coupling, which is prevented by the partitions.

In most embodiments, the second and third transducers (+1) can share an enclosed air volume simply by omitting the partition between them. In some embodiments, the first and fifth (+½) transducers can share an air volume, but this will require a more complex cabinet.

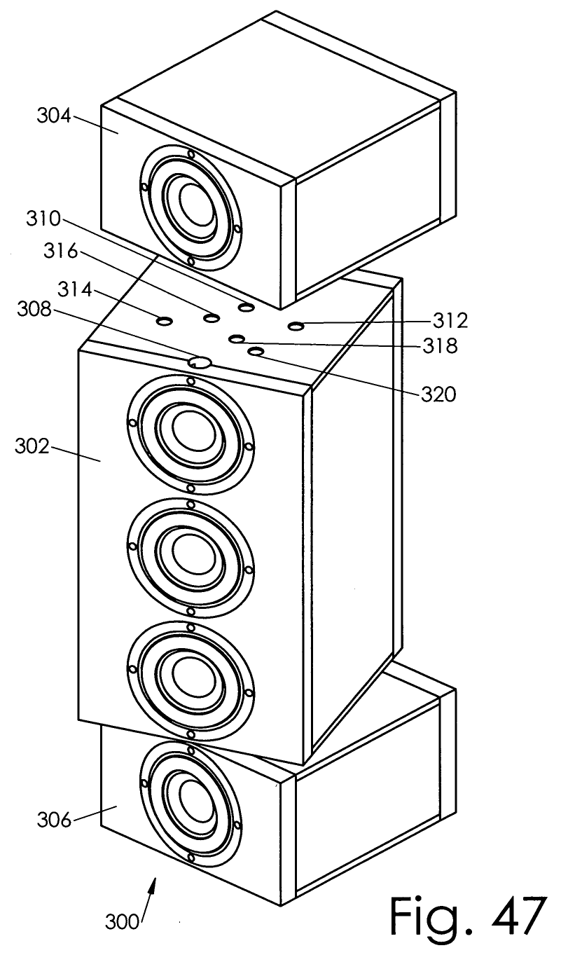

FIG. 47 illustrates a loudspeaker 300 using a different method of achieving the 12 amplitude outputs at the first and fifth transducer positions. Rather than driving those transducers with 1 amplitude signals, or using only ½ their BL, those transducers are angled differently with respect to the listening space than are the full-amplitude transducers. This takes advantage of the natural off-axis high frequency attenuation of the transducers.

The middle three (full amplitude) transducers are coupled to a middle loudspeaker cabinet 302. The first transducer is coupled to a top loudspeaker cabinet 304. And the fifth transducer is coupled to a bottom loudspeaker cabinet 306. The middle cabinet is aimed at a conventional listening position, and the top and bottom cabinets are aimed away from that listening position by some particular angular degree selected according to the geometry of the listening space and the characteristics of the transducers and cabinets.

In one embodiment, the three cabinets are coupled together such that they pivot about an axis which runs substantially through the acoustical centers of the transducers.

For ease of illustration, the top cabinet is shown in an exploded configuration, axially removed from the center cabinet. During operation, the cabinets would be correctly spaced; in one embodiment, this means the top cabinet would be physically resting on the center cabinet.

The loudspeaker may optionally also include means for reconfiguring the “wiring” of the transducers as the cabinets are rotated with respect to each other. In one embodiment, when the cabinets are arranged to face the same direction, the transducers are wired to operate as a line array, and when the top and bottom cabinets are angled outward, the transducers are wired to operate as an Improved Bessel Array. The switching of the wiring can be between any desirable combination of transducer configurations, as selected by the manufacturer.

In one embodiment, adjacent pairs of cabinets have a pivot 308 at the axis about which they can rotate with respect to each other. A first detente 310 engages at a “same orientation” configuration, and a second detente 312 engages at a “rotated orientation” configuration, providing the user with positive feedback enabling correct alignment for each configuration. As the top cabinet rotates from the straight position to the angled position, a positive transducer terminal (not visible, on the bottom of the top cabinet) disengages from a straight position connector 314 and engages with an angled position connector 316, and a negative transducer terminal (not visible, on the bottom of the top cabinet) disengages from a straight position connector 318 and engages with an angled position connector 320. Each connector of a straight/angled connector pair is equidistant from the pivot, but the respective pairs can be at different distances. Each pair is separated by the same angle as between the détentes. A similar arrangement is provided between the center and bottom cabinets. In this context, another term for “connector” is “contact”.

In one embodiment, the various configurations of Bessel array circuitry are provided on the center cabinet, and the top and bottom cabinets are provided simply with transducer terminals, pivots, and détentes.

In yet another embodiment, the transducers are fixedly coupled in their angled configuration to a single cabinet lacking the rotating feature and are wired into their Bessel Array, Improved Bessel Array, or Super Bessel Array configuration. In one such rigid cabinet embodiment, the wiring can be switched, e.g. by moving external speaker wires to different posts, between e.g. conventional Bessel Array and Super Bessel Array configurations.

The Bessel array is shown with the reduced-amplitude transducers achieving their lower on-axis output by being rotated about an axis generally parallel to the overall axis of the Bessel array; in other words, the Bessel array is vertical, and the ½ position transducers are rotated to the side, and not necessarily in the same direction. In another embodiment, they can be rotated in other directions. For example, it may be desirable to aim the upper ½ transducer somewhat upward, and the lower ½ transducer somewhat downward.

In another embodiment, the cabinets could be made to rotate at their center axis rather than at an axis which is generally at the transducers' diaphragms. In some such embodiments, the cabinets may have a polygonal cross-sectional shape such that when the top and bottom cabinets are rotated into their angled position, the exterior faces of the three cabinets are still substantially co-planar. For example, if octagonal cabinets are rotated 45° degrees, the exterior surfaces will be aligned.

### Null-Element Bessel Arrays

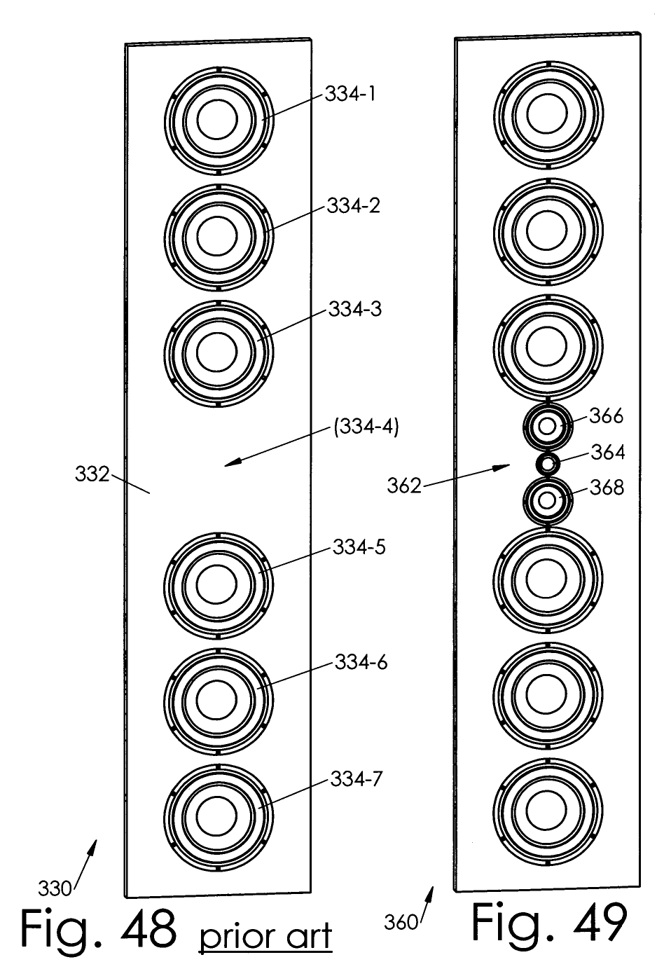

FIG. 49 illustrates a 7-Element Bessel array loudspeaker 360 in which the 0 position 362 is occupied by an MTM array including a tweeter 364 (advantageously centered on the position of the absent Bessel transducer) surrounded by midrange drivers 366, 368.

The MTM operates primarily in a higher frequency range than the woofer Bessel array, and thus does not significantly interfere with the Bessel functionality. Ideally, the crossover circuitry (not shown) will provide a somewhat steep roll-off in the crossover region. In some embodiments, it will be desirable to use active filters to perform the crossover, rather than simply passive components.

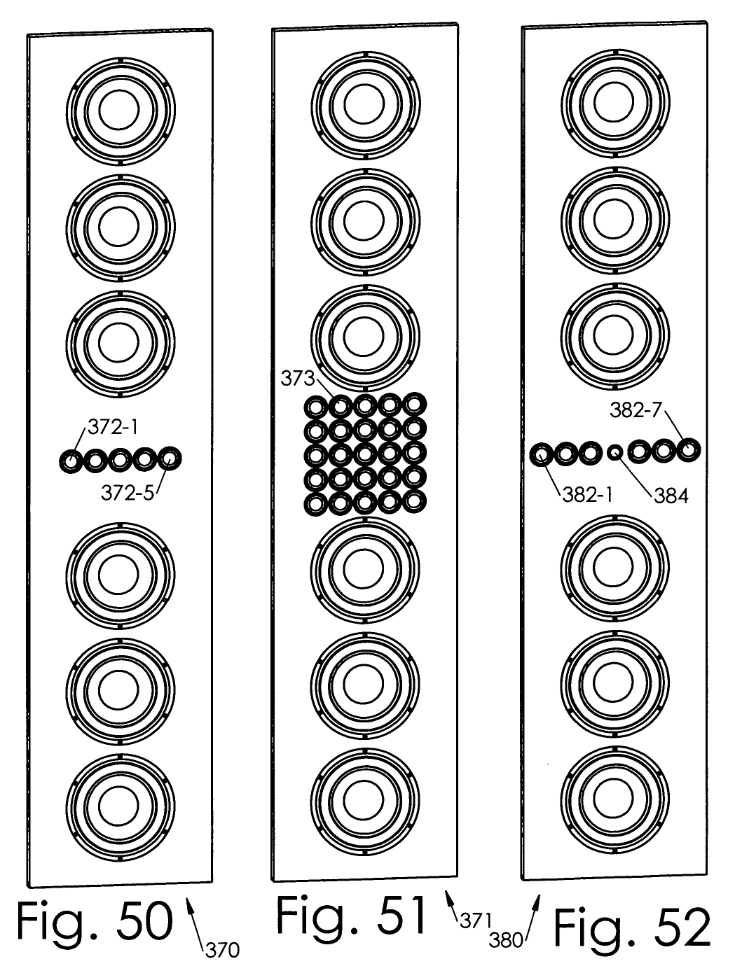

FIG. 50 illustrates a 7-Element Bessel array loudspeaker 370 in which the 0 position is occupied by a 5-Element Bessel array of transducers 372-1 to 372-5. In one embodiment, this midrange (or tweeter) Bessel array is oriented perpendicular to the woofer (or midrange) Bessel array. Using a Bessel array of tweeters (rather than simply one tweeter) in the zero or null position of the woofer Bessel array gives the advantage of enabling the loudspeaker system to have higher SPL or to be crossed over at a lower frequency.

FIG. 51 illustrates a 7-Element Bessel array loudspeaker 371 which includes a 5×5-Element Bessel array in the 0 position. The 5×5 array offers a significant amount of midrange or tweeter piston area, allowing e.g. the use of a simple two-way crossover and 10-inch woofers in the 7-Element array, and yet achieving a good power response and overall frequency response of the loudspeaker.

FIG. 52 illustrates a 7-Element Bessel array loudspeaker 380 in which the 0 position is occupied by a 7-Element Bessel array of midrange (or tweeter) drivers 382-1 through 382-7, in which the 0 position (which would be at 382-4 if there were a midrange driver there) is occupied by a tweeter 384 (or supertweeter, in the case of a Bessel array of tweeters).

FIG. 53 illustrates a 7-Element Bessel array loudspeaker 390 in which the 0 position of the woofer Bessel array is occupied by an MTM of Bessel arrays. The MTM of Bessel arrays includes a 5-Element Bessel array of tweeters 392-1 through 392-5 arranged horizontally, and a top midrange Bessel array of transducers 394-1 through 394-5 arranged horizontally above the tweeter Bessel array, and a bottom midrange Bessel array of transducers 396-1 through 396-5 arranged horizontally below the tweeter Bessel array.

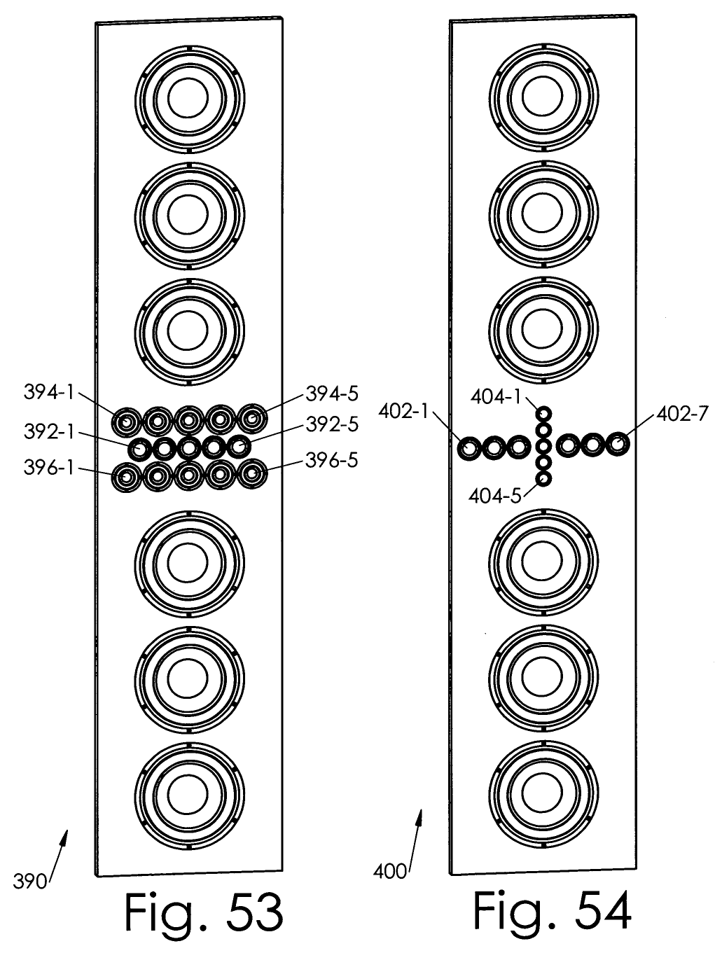

FIG. 54 illustrates a 7-Element Bessel array loudspeaker 400 in which the 0 position is occupied by a 7-Element midrange Bessel array of drivers 402-1 through 402-7 (except a space exists where 402-4 would be) arranged perpendicular to the woofer Bessel array. The 0 position of the midrange Bessel array is, in turn, occupied by a 5-Element tweeter Bessel array 404-1 through 404-5 arranged perpendicular to the midrange Bessel array.

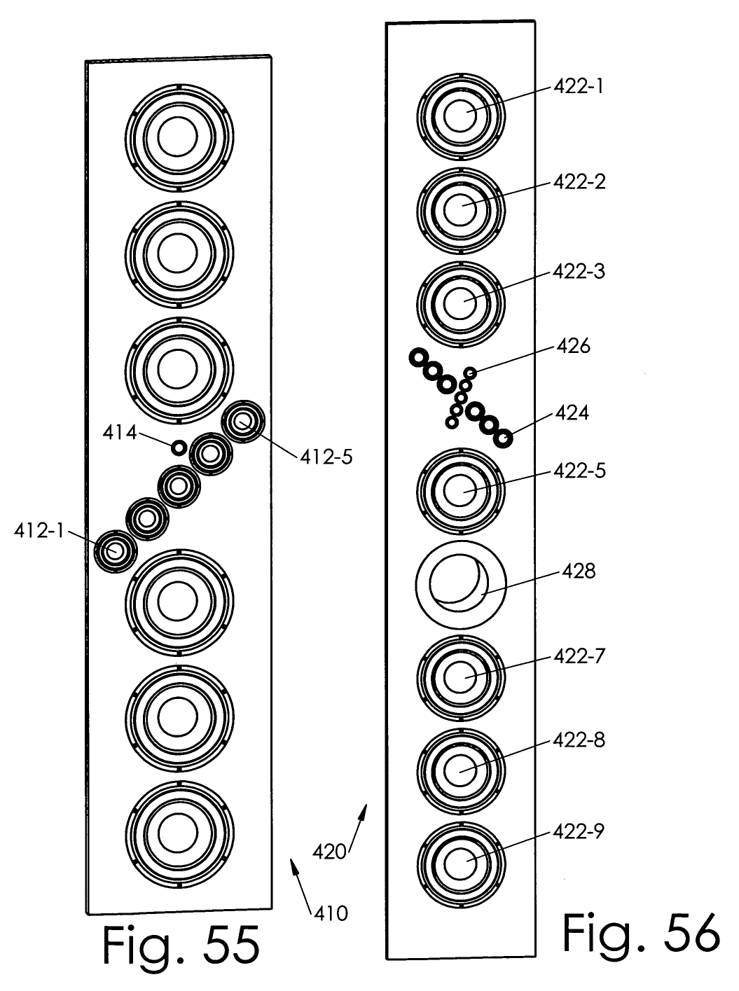

FIG. 55 illustrates a 7-Element Bessel array loudspeaker 410 in which the 0 position is occupied by a 5-Element Bessel array of transducers 412-1 through 412-5. These transducers, which may be e.g. midrange or tweeter drivers, can be made larger if their Bessel array is angled diagonally as shown. This permits the use of larger midrange drivers without having to increase the lateral or long dimension of the enclosure. Optionally, a tweeter 414 may be added, preferably on the center line of the main Bessel array, and preferably as close to its 0 position as possible without interfering with the diagonal midrange Bessel array. In some embodiments, the positions of the tweeter and the center midrange may be compromised, with one or the other or neither being exactly at the 0 position of the main Bessel array.

FIG. 56 illustrates a 9-Element Bessel array loudspeaker 420. A 9-Element Bessel array includes seven transducers (422-1 through 422-3, 422-5, and 422-7 through 422-9) at seven nine equally spaced positions. These transducers (including two empty positions) are driven with signals having amplitude/phase coefficients of +½, +1, +1, 0, −1, 0, +1, −1, and +½. The upper 0 position is occupied by a Bessel array 424 of midrange drivers and a crossing Bessel array 426 of tweeters.

The lower 0 position may optionally be utilized for locating a port 428 for venting the enclosure. This is especially useful in embodiments in which the woofer Bessel array is configured as an Improved Bessel array or a Super Bessel array as taught in the various parent applications of this application. In such embodiments, the woofers are driven in Bessel manner in their upper frequency range determined according to the spacing of the woofers—the transition point being at or near a frequency at which comb filtering begins to be unacceptably significant. Below that transition frequency point, the woofers are driven in any of a variety of manners which increase the amplitude and/or the in-phase nature of one or more of their outputs, toward +1. This enables an increased number of woofers to share a common ported or vented air space, because a port is primarily (or only) driven by the low frequency range of the drivers' output.

### Bessel MTM

FIG. 58 illustrates a Bessel MTM loudspeaker 430 according to one embodiment of this invention. Only a front panel 432 of the loudspeaker's enclosure is shown, for simplicity. The MTM includes a pair of midrange drivers 436, 438 arranged in a vertical line. Between the midrange drivers, in place of a single tweeter, the Bessel MTM loudspeaker includes a Bessel array 434 of tweeters. In one such embodiment, such as the one shown, the tweeter Bessel array is a 5-Element array of tweeters 434-1 through 434-5. This solves the common MTM problem of it being difficult to design a single tweeter that can generate the same maximum SPL and/or efficiency as two midrange drivers.

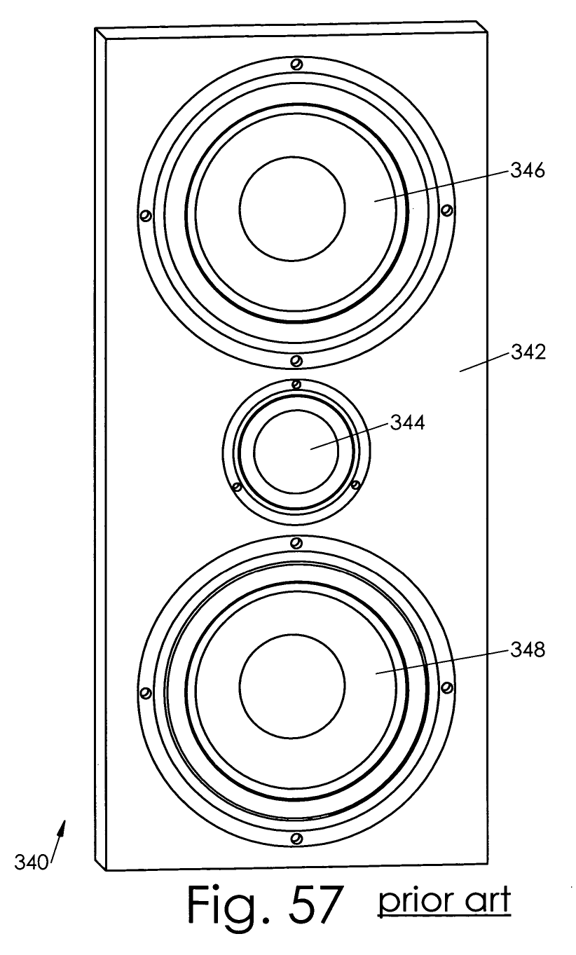

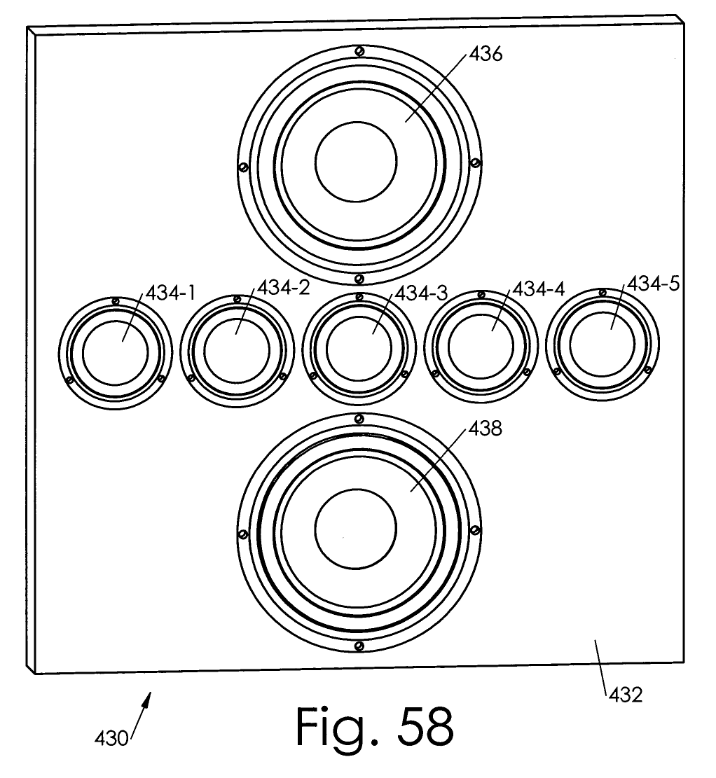

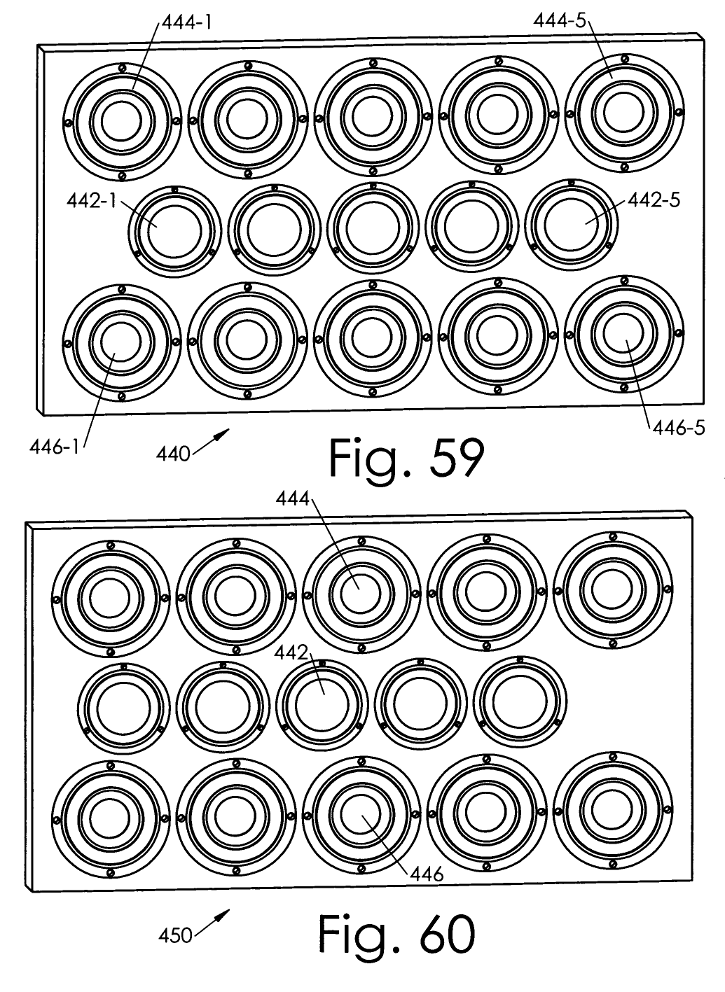

FIG. 59 illustrates a Bessel MTM loudspeaker 440 according to another embodiment of the invention. The tweeter is instantiated as a Bessel array of tweeters 442-1 through 442-5. The upper midrange is instantiated as a Bessel array of midrange transducers 444-1 through 444-5, and the lower midrange is instantiated as a Bessel array of midrange transducers 446-1 through 446-5. The center transducers of the respective Bessel arrays are arranged in a vertical line.

FIG. 60 illustrates a similar Bessel MTM loudspeaker 450 in which the tweeter Bessel array 442 is shifted slightly to one side such that the center tweeter is not in line with the upper and lower center midrange drivers. With some relative combinations of tweeter diameter, midrange diameter, tweeter spacing, and midrange spacing, this may facilitate slightly improved (tighter vertical) packing of the overall transducer array, enabling the use of a slightly reduced size enclosure and allow for a slightly higher crossover frequency for a given directivity target.

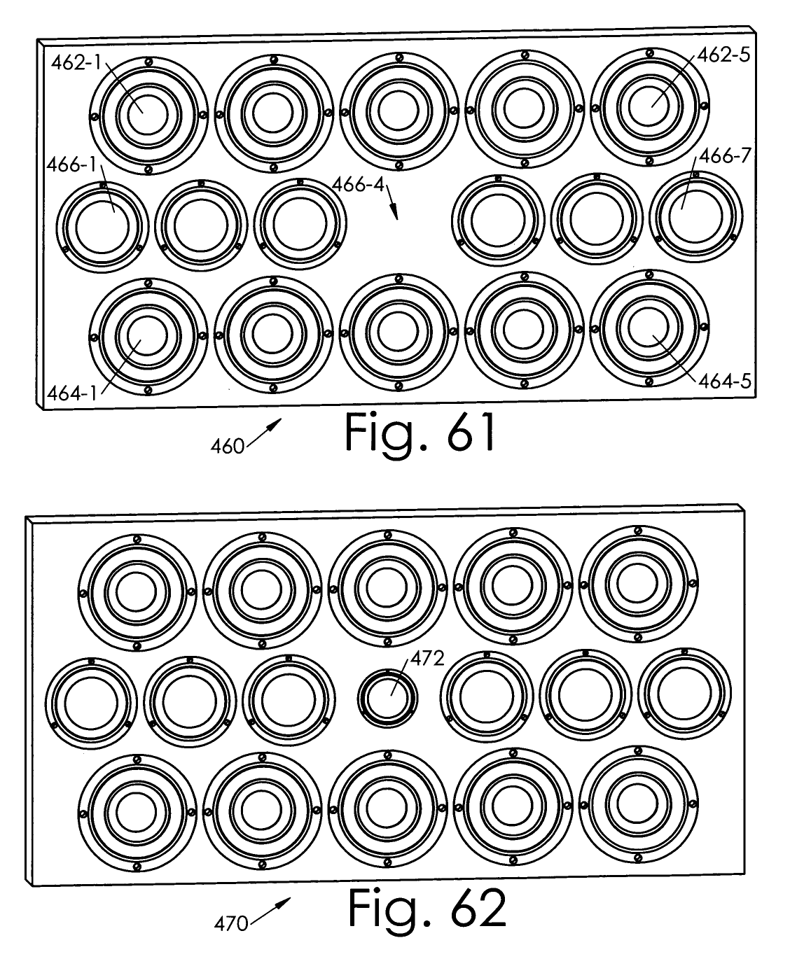

FIG. 61 illustrates a Bessel MTM loudspeaker 460 according to yet another embodiment of this invention. It uses the 5-Element upper and lower Bessel arrays 462-1 through 462-5 and 464-1 through 464-5. In the tweeter position, it uses a 7-Element Bessel array of tweeters 466-1 through 466-7. As shown, the center position 466-4 can simply be left blank, with no transducer.

FIG. 62 illustrates a Bessel MTM loudspeaker 470 similar to that of FIG. 61, with the addition of a supertweeter 472 occupying the 0 position of the tweeter array. The supertweeter operates in a frequency range higher than the high frequency range in which the Bessel array of tweeters is operating. The supertweeter can cover a frequency range so high that even a Bessel array can have a ragged off-axis frequency response.

FIG. 63 illustrates a Bessel MTM loudspeaker 461 similar to that of FIG. 61, except that the midrange arrays have been crowded as close as possible to the tweeter array. They have been crowded so closely, in fact, that the midrange arrays are no longer exactly in line. In the example shown, the midrange drivers in the 1 and 5 positions cannot be moved vertically inward as far as the other midrange drivers, without interfering (mechanically overlapping) with the tweeters in the 1 and 7 positions.

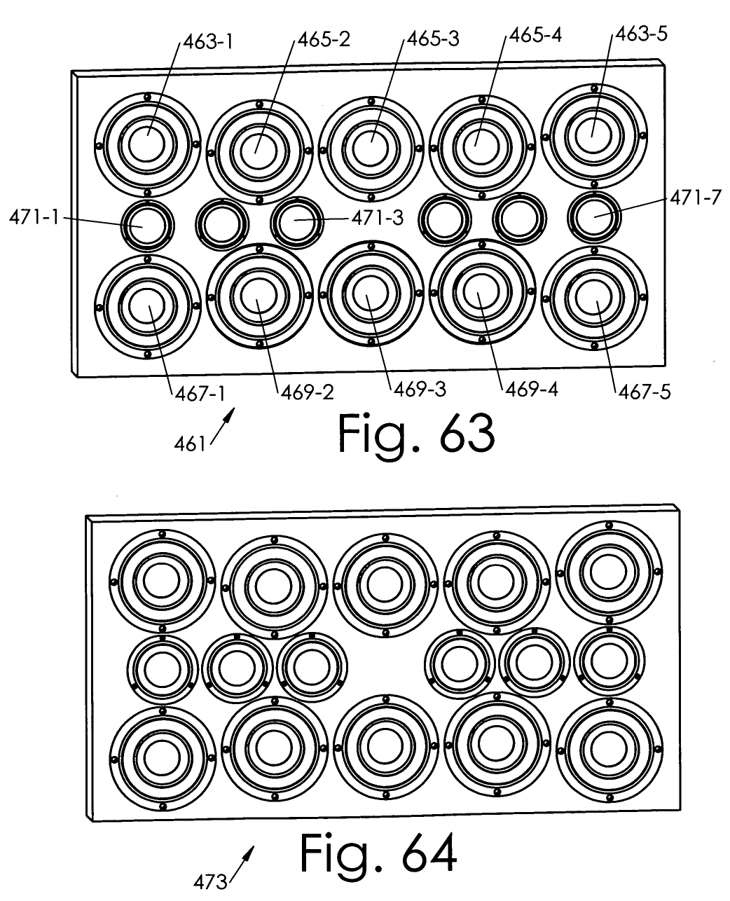

FIG. 64 illustrates a similar Bessel MTM loudspeaker 473, in which the diameter of the tweeters has been increased nearly to the largest it could be and still have the 7-Element tweeter array be no wider than the 5-Element midrange arrays. The midrange arrays are crowded vertically against the tweeter array, and are not strictly in line. Although not shown, the middle position of the tweeter array has sufficient space to accommodate a supertweeter.

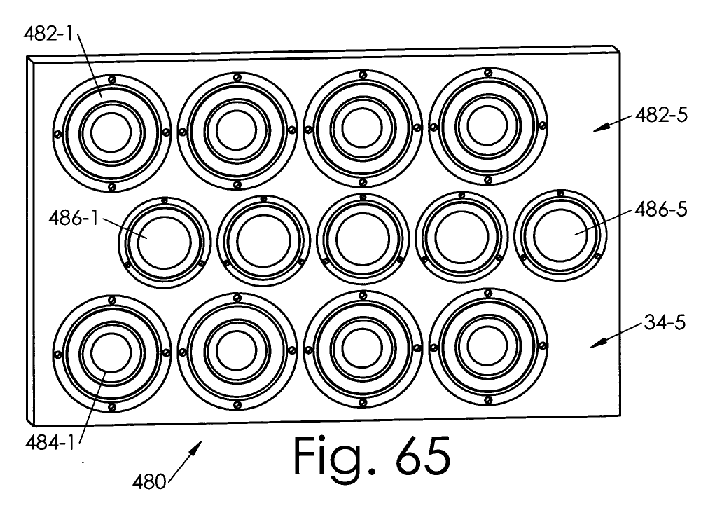

FIG. 65 illustrates a Bessel MTM loudspeaker 480 according to yet another embodiment of this invention. The midrange positions are occupied by “Reduced Bessel” arrays in which one of the end transducers has simply been omitted, to reduce the number of transducers that must be purchased and to enable the enclosure to be shrunk. Omitting one of the ½ signal transducers—such as from positions 482-5 and 484-5—will slightly reduce the benefit obtained from a full Bessel array, but will still be much better than a conventional line array, as far as off-axis response is concerned.

The missing transducers can be omitted from the same end of both arrays (in wiring or signal terms), such as position 1. Or, the missing transducers can be omitted from opposite ends—position 1 in one array, and position 5 in the other. In yet another embodiment, position 1 in one array and position 5 in the other array are on the same side. In still another embodiment, the tweeter Bessel uses the Reduced Bessel configuration. And in yet another embodiment, both the midrange Bessels and the tweeter Bessel use it. In one such embodiment, the missing transducers are omitted from one end of both midrange Bessels, and the opposite end of the tweeter Bessel. Reduced Bessel Arrays are not limited to the “4 instead of 5” variety, but can be e.g. “6 instead of 7”, “8 instead of 9”, and so forth. In some embodiments, such as that shown, the center transducers of the three Bessel arrays (including the missing positions) are in a vertical line. In other embodiments, the tweeter Bessel array could be shifted horizontally in order to reduce the enclosure size (or width, as shown).

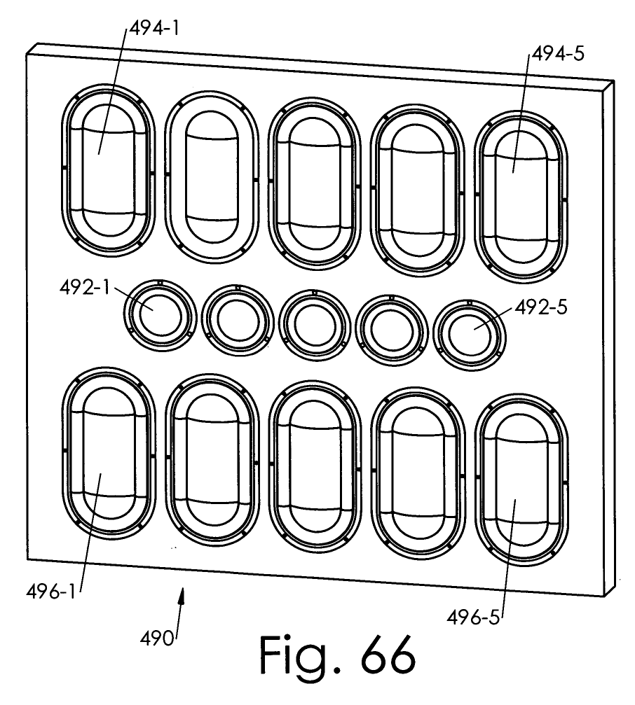

FIG. 66 illustrates a Bessel MTM loudspeaker 490 which uses a Bessel array of tweeters 492, and top and bottom midrange Bessel arrays 494, 496, in which some of the transducers use a “racetrack” shaped diaphragm. Alternatively, they could use other elongated shapes, such as rectangles, rounded (corner) rectangles, ellipses, and the like. Using an elongated shape oriented perpendicular to the array (e.g. vertically oriented diaphragms in a horizontal Bessel array) enables the transducers to be packed with a closer on-center spacing without decreasing piston area, as compared to circular diaphragms. Alternatively, with the same on-center spacing, the piston area can be increased by using elongated diaphragms. Depending on the tweeter dimensions, using the racetrack midrange drivers may allow the designer to reduce the horizontal (as shown) dimension of the enclosure, with the same midrange piston area. The tweeter array can also or alternatively use elongated diaphragms.

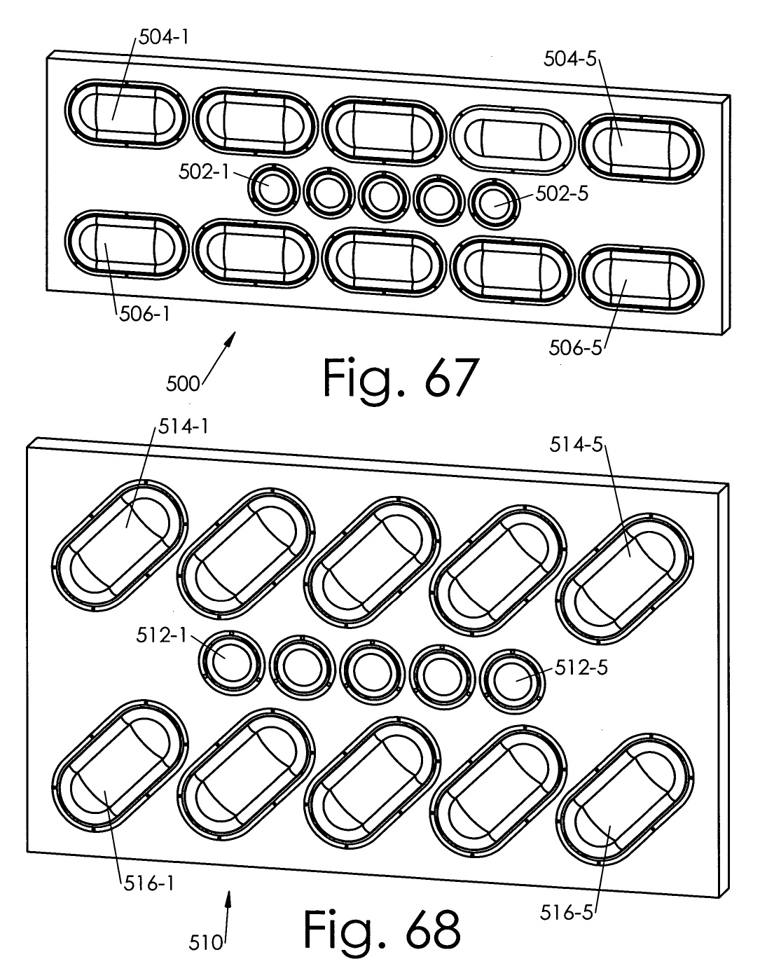

FIG. 67 illustrates a Bessel MTM loudspeaker 500 which uses a Bessel array of tweeters 502, and upper and lower midrange Bessel arrays 504, 506. The midrange drivers use racetrack diaphragms oriented in the same direction as their Bessel array. This may enable the designer to reduce the vertical (as shown) dimension of the enclosure, which is particularly desirable in some applications, such as home theater center channel speakers which are commonly located above or below a television display panel. This gives better vertical dispersion for a given crossover frequency.

FIG. 68 illustrates a Bessel MTM loudspeaker 510 in which the racetrack midrange transducers are oriented at an angle somewhere between parallel with (e.g. FIG. 67) and perpendicular to (e.g. FIG. 66) their Bessel arrays, as a compromise between increasing piston area, reducing on-center spacing, horizontal enclosure dimension, and vertical enclosure dimension. In one embodiment, as shown, the transducers of the two midrange arrays are angled in a same direction.

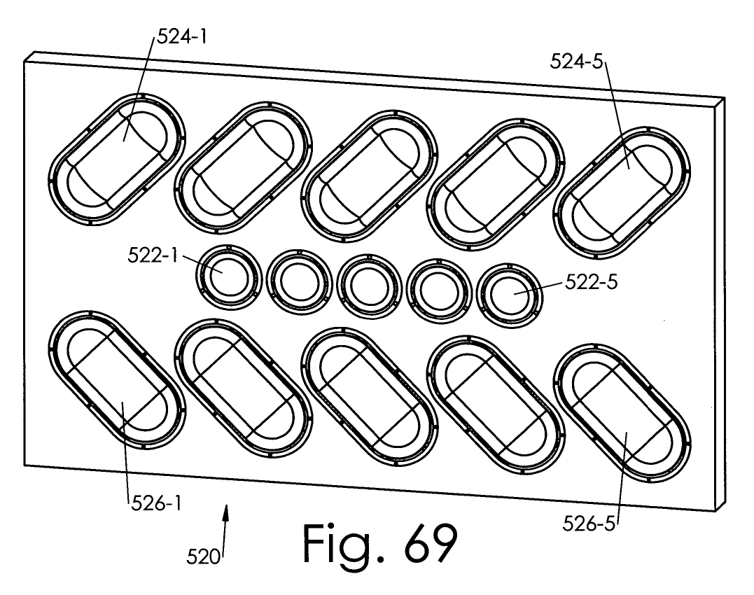

FIG. 69 illustrates a similar Bessel MTM loudspeaker 520 in which the upper and lower midrange Bessel arrays' transducers 524, 526 have their racetrack diaphragms angled in opposite directions, in a herringbone pattern.

Regardless of the particulars of the transducers utilized and their diaphragms' orientation, in some embodiments, the midrange Bessel arrays may be wired in the same Bessel pattern, e.g. left to right. In other embodiments, they may be oppositely arranged, e.g. the top midrange Bessel array arranged left to right, and the bottom midrange Bessel array arranged right to left.

In any of these Bessel MTM embodiments, any of the Bessel arrays can be implemented as Super Bessel or Improved Bessel arrays.

### Bessel Soundbar

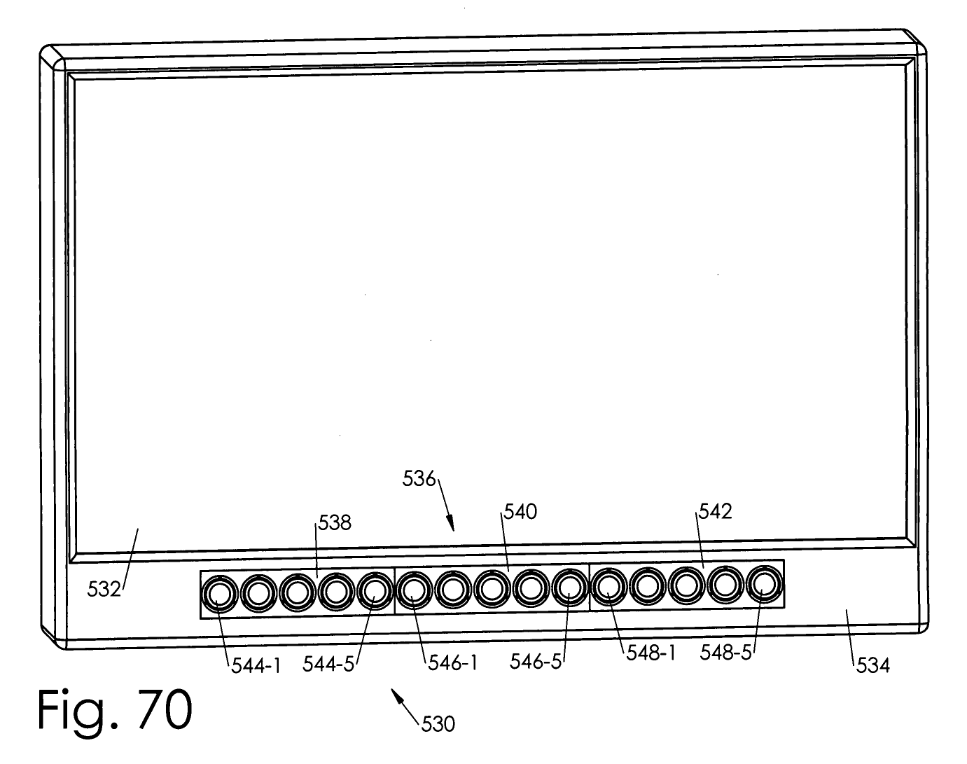

FIG. 70 illustrates a video monitor or television set 530 having a display panel 532 coupled to a chassis or body 534, and an LCR soundbar 536. The soundbar includes a left channel speaker 538, a center channel speaker 540, and a right channel speaker 542. Some or all of the speakers are implemented as horizontal Bessel arrays. In one embodiment, the speakers are coupled into a single, monolithic soundbar unit. In some embodiments, the soundbar is built into the television, as shown, while in others it may be a stand-alone component suitable for positioning above or below the television, or built into a television stand (not shown), or what have you.

The left speaker Bessel array includes transducers 544-1 to 544-5, the center channel Bessel array includes transducers 546-1 to 546-5, and the right speaker includes transducers 548-1 to 548-5 (in the case of 5-Element Bessel arrays).

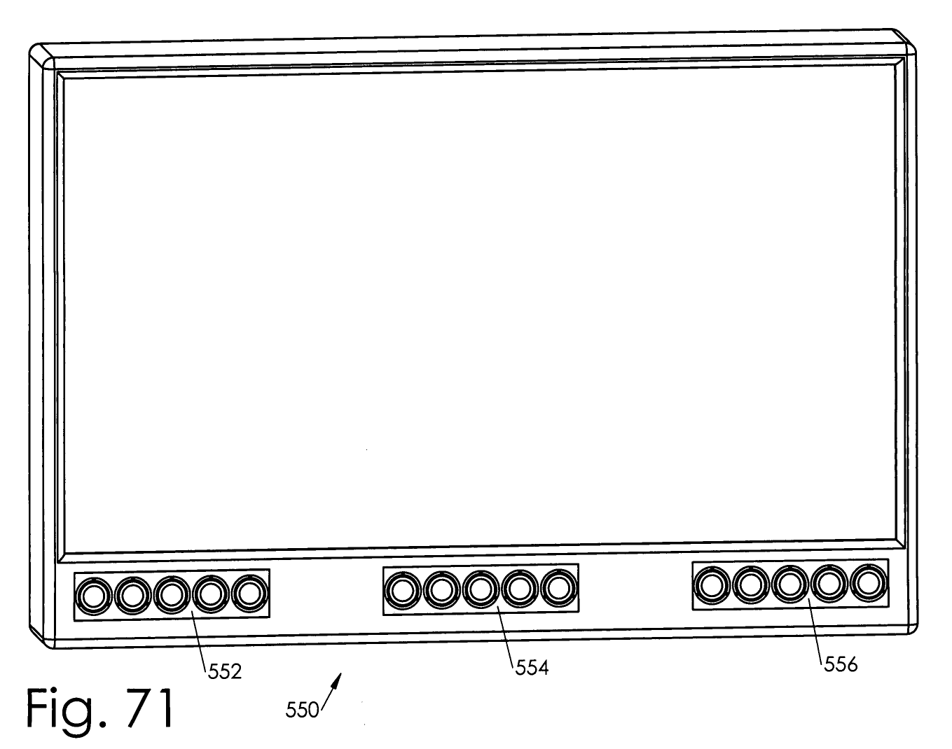

FIG. 71 illustrates a television set 550 which includes a left channel Bessel array 552, a center channel Bessel array 554, and a right channel Bessel array 556. Rather than being constructed as a monolithic soundbar, the three Bessel arrays are separated as far as permitted by the geometry of the television set, to maximize stereo separation between the left and right channels.

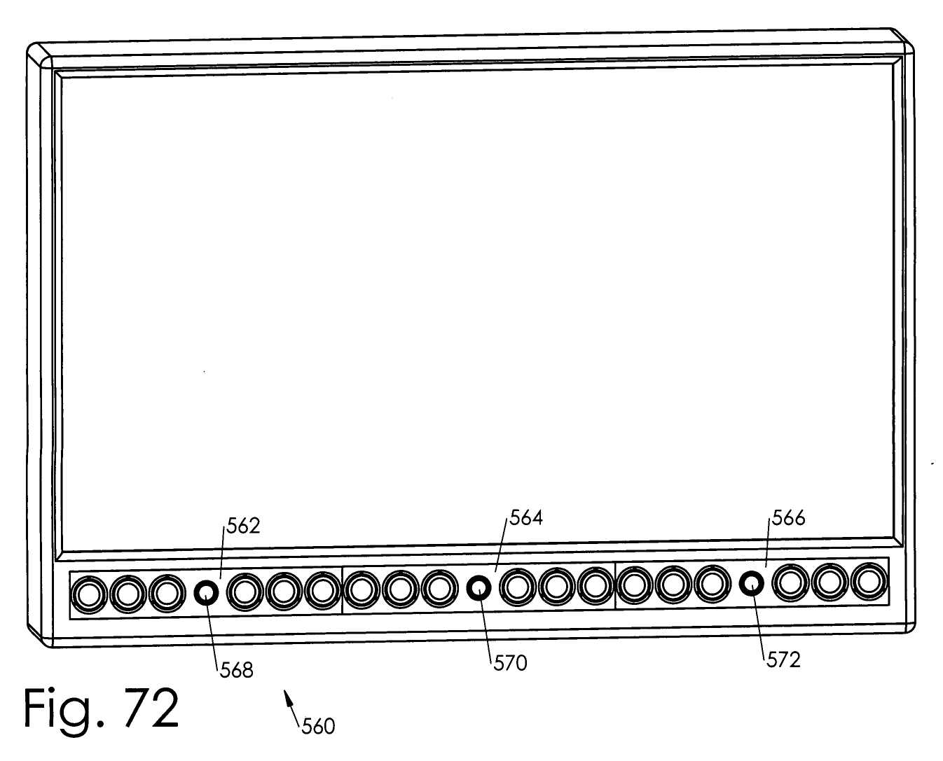

FIG. 72 illustrates a television set 560 in which the left, center, and right Bessel arrays 562, 564, 566 are 7-Element Bessel arrays, some or all of which may include tweeters 568, 570, 572 in their zero positions.

Twenty-one transducers (or, more correctly, equidistant transducer positions) is a large number to place in a row. Even using relatively small transducers having a maximum lateral dimension of two inches, the soundbar will be at least forty-two inches wide. This tends to dictate a certain minimum size television set in which the soundbar can be used.

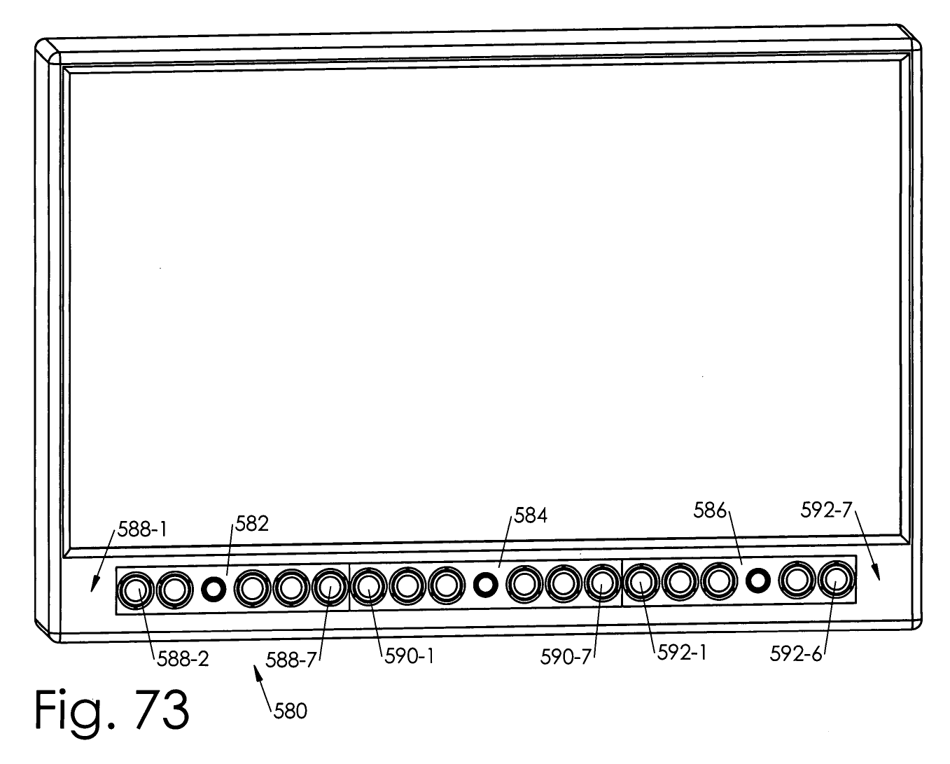

FIG. 73 illustrates a television set 580 in which the soundbar has a Reduced Bessel Array left channel speaker 582, a Bessel array center channel speaker 584, and a Reduced Bessel Array right channel speaker 586. The left channel speaker includes transducers 588-2 to 588-7 but lacks a transducer at the outermost Bessel position 588-1. The center channel speaker includes transducers 590-1 to 590-7. And the right channel speaker includes transducers 592-1 to 592-6 but lacks a transducer at the outermost Bessel position 592-7. Omitting the two outermost transducers reduces the transducer position count from twenty-one to nineteen, enabling the designer to fit the soundbar into a smaller television set, or, alternatively, to use slightly larger transducers or to provide a small amount of spacing (not shown) between the left and center, and center and right speakers. FIG. 73 shows he same size television set as is shown in FIG. 72, but this is merely to demonstrate the soundbar width reduction, and is not restrictive of the invention.

In another embodiment, the same position transducer is removed from both the left and right channel speakers; in this case, e.g. the right speaker would have its drivers in a mirror image of the left speaker's drivers. Depending on the element count of the Bessel array and the application at hand, it may be much more preferable to omit the transducer at a particular end of an array than to omit the transducer at the other end.

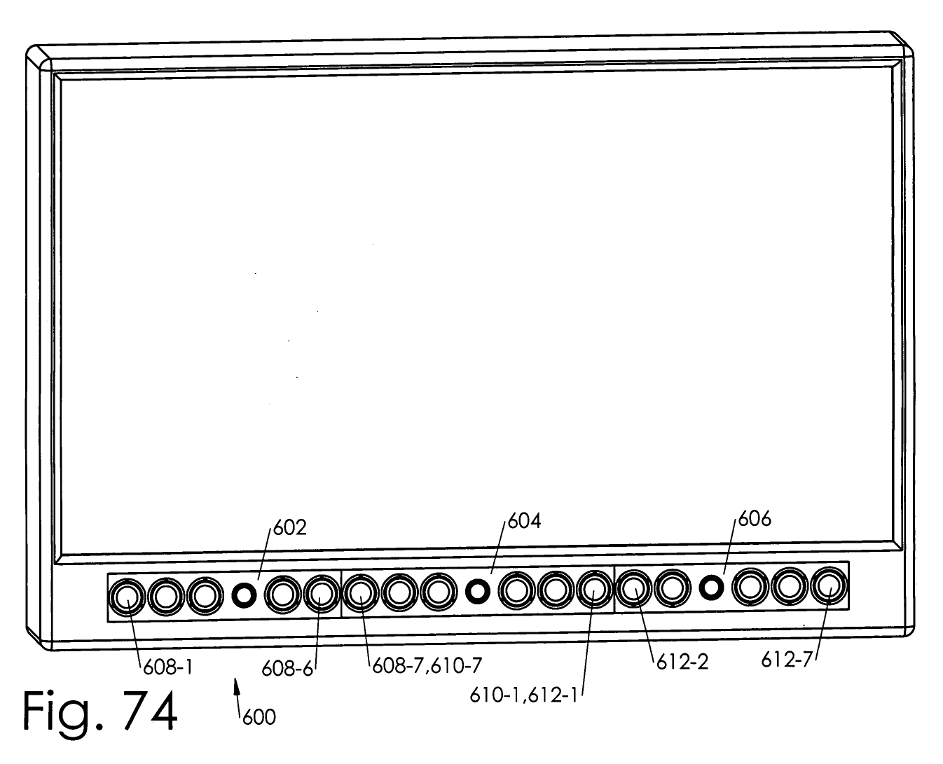

FIG. 74 illustrates a television set 600 including a left channel speaker 602, a center channel speaker 604, and a right channel speaker 606. This illustration may be validly interpreted in two different ways. The simpler way is to interpret it as having the same basic configuration as FIG. 73, with Reduced Bessel Array left and right channel speakers, which have simply been reversed (left for right) from those shown in FIG. 73. This results in a slightly different horizontal dispersion pattern.

The perhaps more interesting way is to interpret it as using “Overlapping Bessel Arrays”. The left channel speaker includes transducers 608-1 to 608-7, the center channel speaker includes transducers 610-7 to 610-1, and the right channel speaker includes transducers 612-1 to 612-7. Because transducer 608-7 and 610-7 are at ½ magnitude Bessel positions, it is convenient for those Bessel signals to be fed to a single physical transducer, which is shared between the two adjacent Bessel arrays. Similarly, Bessel signals at 610-1 and 612-1 can also be fed to a single, shared transducer.

Another possible way of doing this is to provide at the shared position a pair of (perhaps smaller) separate transducers, arranged vertically such that each is slightly off-line with its Bessel mates. (This is not shown in FIG. 74.) Smaller drivers would ideally have the same frequency response as the others, although this can be difficult to achieve.

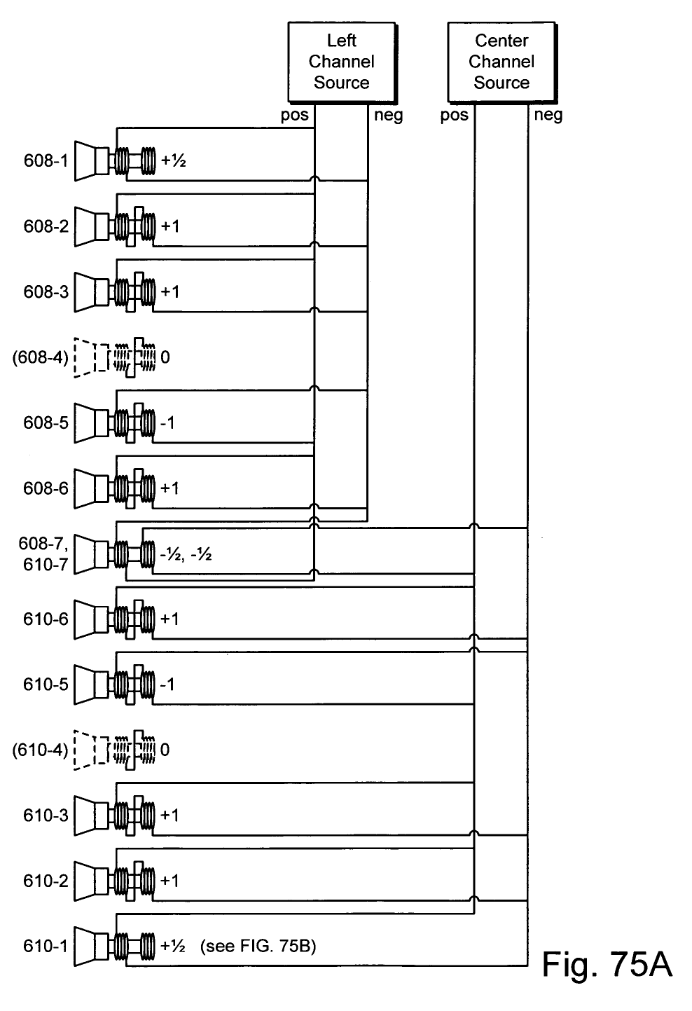

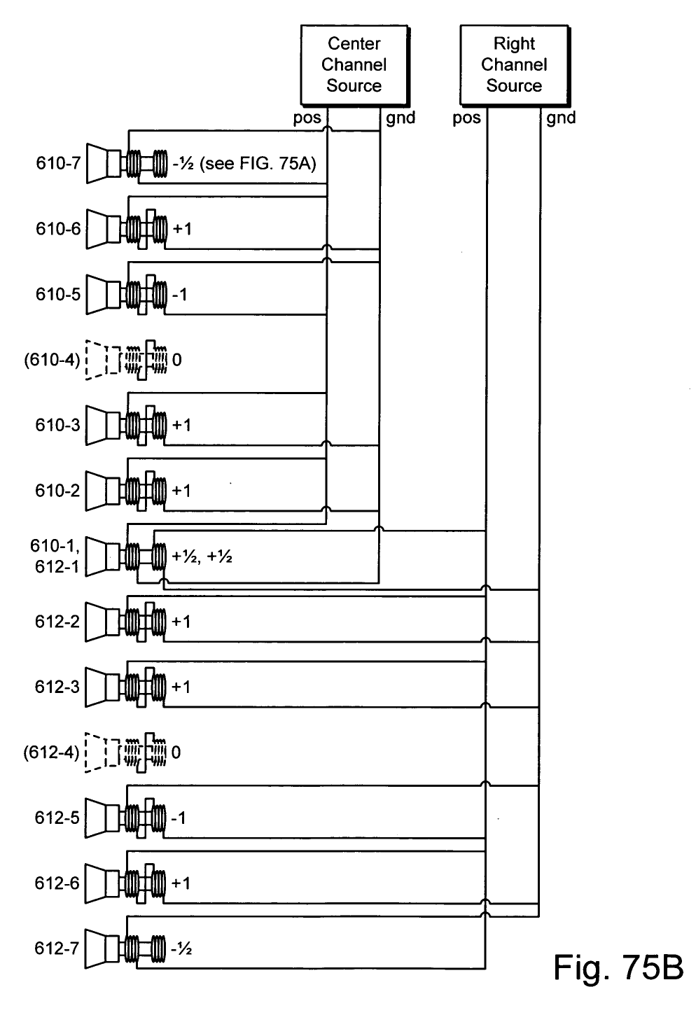

FIG. 75 is comprised of FIGS. 75A and 75B, which overlap by approximately 50% in the transducers they show. FIG. 75 illustrates a more elegant solution. Position 608-7, 610-7 can be occupied by a single transducer, the same size as the other Bessel transducers. That transducer (and, optionally, the other Bessel transducers) can have a dual voice coil structure. Dual voice coil transducers are well known in the art. In this embodiment of the invention, one of the voice coils is fed by the left channel source, and the other is fed by the center channel source. Because each signal will drive only half the BL as e.g. the signal driving transducer 608-6, the ½ value will automatically be achieved. The phase is simply a question of whether the two leads of the particular voice coil are connected to the source's positive and negative in the same, or opposite, manner as the +transducers' voice coils.

The outermost transducers 608-1 and 612-7 may be dual voice coil transducers, identical to their Bessel mates, and simply have one of their voice coils left unwired to achieve the l 2 amplitude. Or, they may be single voice coil transducers with half the windings of the dual voice coils, or what have you. They can be driven as in FIGS. 42, 43, or 44, for example.

The zero position transducers at the 608-4, 610-4, and 612-4 positions are illustrated in dashed lines, indicating that the Bessel arrays lack transducers at those positions. Other transducers such as tweeters can, of course, be physically positioned at those locations, and simply not wired as part of the Bessel arrays.

In one embodiment using 7-Element Bessel arrays, the three arrays are arranged: left-to-right, right-to-left, and left-to-right, as shown. This pairs up the −½ signals at the left-center shared position, and the +½ signals at the center-right shared position. In another embodiment, all could be e.g. left-right oriented. In yet another, the left and right channel Bessels may be opposites of each other, with the center channel Bessel matching one of them.

In another embodiment, the outermost transducers 608-1 and 612-7 can be omitted, using a hybrid Reduced/Overlapping Bessel Array configuration, and the transducer position count drops to only seventeen.

Any of the Bessel arrays in these soundbar configurations can be Improved or Super Bessel Arrays. In some home theater systems, it is desirable to use the television set's built-in drivers as a center channel speaker, e.g. when there is no suitable location for mounting an external center channel speaker, or when avoiding the expense of its purchase. In such cases, it may be desirable to provide the soundbar with a mode selection switch (not shown) which the user can actuate (or the system can electronically actuate) to select between LCR mode and C mode. In one such embodiment, selecting the C mode simply turns off the L and R Bessel arrays and leaves the C Bessel array connected. In another such embodiment, selecting the C mode leaves the C channel drivers operating as a Bessel array, and applies a low-pass filter to the C channel signal and connects the L and R drivers to be driven by the output of the low-pass filter. Optionally, the C channel drivers may be driven via a high-pass filter, in order to enable them to produce high sound pressure, low distortion C channel content (because their voice coils do not then need to make the large excursions required for producing the low frequency sounds, and the entire Xmax excursion can be devoted to high frequency sound only). Alternatively, some or all of the L and R channel drivers could remain coupled to be driven via low-pass filters by the L and R channel signals, to contribute to the total L and R bass output.

### Bessel Dipole Speaker

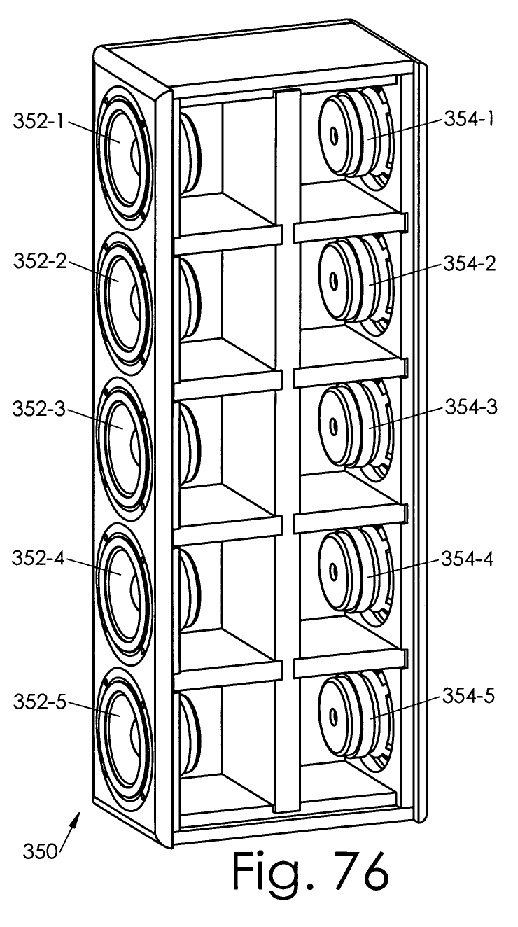

FIG. 76 illustrates a dipole Bessel speaker 350. Dipole speakers are often used as surround speakers in multi-channel systems such as home theaters, but can also be used as front channel speakers in multi-channel, two-channel, or even monaural systems. The speaker includes a Bessel array of transducers 352-1 to 352-5 on one face of the cabinet, and a Bessel array of transducers 354-1 to 354-5 on the opposite face of the cabinet. To achieve the dipole functionality, the two Bessel arrays are driven with signals which are 180° out of phase with each other; for example, if the forward-facing array is driven in-phase, the rearward-facing array is driven opposite-phase.

Using a Bessel array instead of a single transducer enables the use of a significantly narrower enclosure while having the same effective radiating piston area. This is particularly useful in surround speakers, because the narrower enclosure is less obtrusive in the listening space, as it sticks out into the listening space much less than the conventional dipole enclosure, attached to a wall, for instance.

The dipole speaker can be further improved by driving the opposite-phase Bessel array via an inverting all-pass filter. In this configuration, in the higher frequencies, the speaker as a whole functions as a dipole Bessel, but in the lower frequencies, the speaker as a whole functions as a bipole (rather than a dipole) and therefore has significantly more bass output. With conventional Bessel wiring and an all-pass filter added to the input of one of the arrays, the speaker system will produce only four transducers' worth of net output in the low frequencies: the sum of +½, −1, +1, +1, and +½=+2 from each array. This is a significant improve a Bessel dipole speaker, which will produce a net 0 in the low frequencies, because each transducer in one array is cancelled by a corresponding transducer in the other array.

An even further improvement can be had by wiring each −1 position (which could be the second or fourth position) driver with the other array, rather than its own array. In other words, the input is applied in-phase to the first, third, fourth, and fifth drivers of the front array and the second driver of the rear array, and the input is applied opposite-phase to the first, third, fourth, and fifth drivers of the rear array and the second driver of the front array, with both first and both fifth drivers receiving ½ amplitude signals. Cross-linking the −1 drivers in this manner effectively converts both arrays into Super Bessel Arrays without the need for any additional circuitry. Then, when the inverting all-pass filter kicks in in the low frequency range, all ten drivers will be producing +sound, and the speaker achieves eight transducers' worth of net output in the low frequency range. All ten transducers can be brought to +1 in the low frequency, by adding shelving circuits to the ½ amplitude positions as described above.

In another embodiment, the forward-facing array 352 is directly or independently wired as an Improved or Super Bessel Array. In one embodiment, the rearward-facing array is directly or independently wired with each transducer having the opposite phase of its corresponding forward-facing transducer, such that the two arrays form an overall dipole. In one embodiment, the two arrays are wired as the same type of Bessel array—conventional, Improved, or Super. In another embodiment, they are wired as different types.

In the embodiment shown, each transducer has its own, separate enclosed air volume. In other embodiments, various ones of the transducers may share air volumes. The most straightforward example is that the two +1 transducers of the forward-facing array may share an air volume, and, optionally their −1 counterparts of the rearward-facing array may share the same air volume. Then, each remaining forward/rearward pair may share the same air volume. In some embodiments, particularly those employing Improved Bessel or, ideally, Super Bessel arrays, all transducers may share a single enclosed air volume.

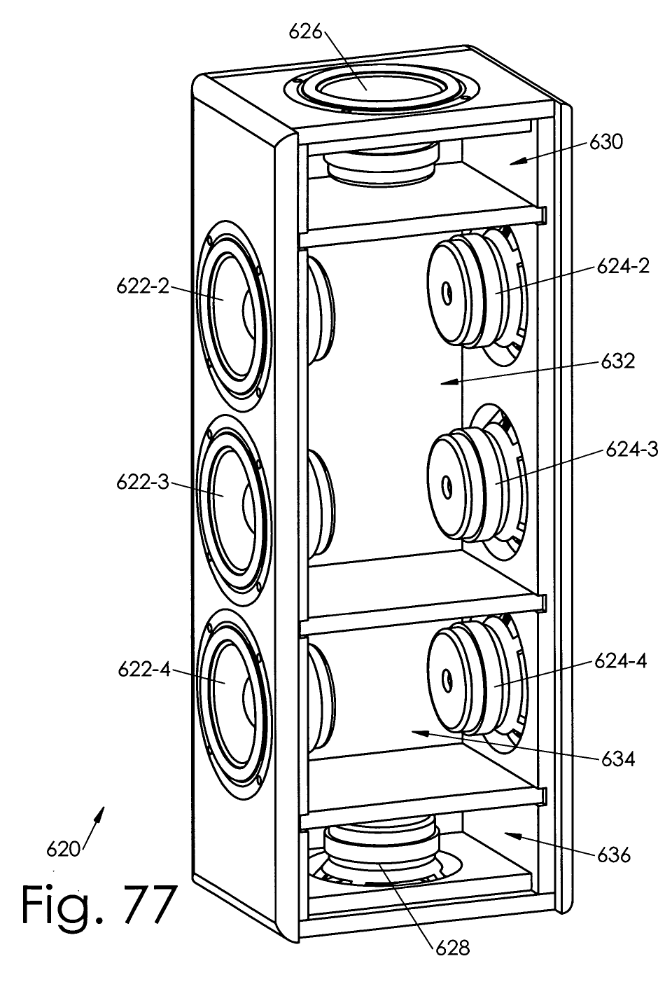

FIG. 77 illustrates an embodiment of a Bessel Dipole speaker 620 which is ideally suited as a wall-mounted surround speaker. In this embodiment, the +1, +1, and −1 components of the forward-facing Bessel array are provided by transducers 622-2, 622-3, and 622-4, respectively. And the −1, −1, and +1 opposite-phase counterparts of the rearward-facing Bessel array are provided by transducers 624-2, 624-3, and 624-4, respectively.

The top +½ component of the forward-firing Bessel array is provided by an upward-firing transducer 626 which is fed a full +1 signal. By being 90° off axis with respect to the rest of the forward-facing Bessel transducers, for a given bandwidth, its average high frequency output is reduced to roughly ½ what it would be if it, too, were forward-firing. Similarly, the bottom +½ component is provided by a downward-firing transducer 628. In order to cancel sound traveling directly from the upward-firing transducer to the listener, the downward-firing transducer is fed with a −1 signal.

The upward-firing and downward-firing transducers serve double duty as the ½ magnitude component of both the frontward-facing and rearward-facing Bessel arrays. Thus, the parts count of this speaker is reduced by two transducers, as compared to that of FIG. 86.

It should be noted that, even though the rearward-facing array is fed an inverted version of the Bessel coefficients (in which the top transducer would be fed −½), and the upward-firing transducer is fed a non-inverted +1 signal, the fact that the upward-firing transducer is 90° off-axis with the rest of the rearward-facing Bessel array provides a sufficiently good solution.

Another way of looking at this speaker is to consider each of the vertically-oriented drivers as being part of a respective one of the Bessel arrays; the speaker system may then be understood as having two 4-driver Reduced Bessel arrays.

In the example shown, the upward-firing and downward-firing transducers have their own, separate air volumes 630, 636, the second and third position transducers (which all move in unison) share a common air volume 632, and the fourth position transducers (which move in unison) share a common air volume 634. In yet another embodiment, the transducers are self-enclosed and the sharing of the air volume in the cabinet is irrelevant.

In one embodiment, the height of the cabinet is selected such that the upward-firing and downward-firing transducers' diaphragms are roughly at the same vertical height that their corresponding first and fifth Bessel position transducers would be (e.g. in FIG. 86). The designer can adjust this vertical positioning as needed, per the demands of the application at hand.

In the embodiment shown, the upward-firing and downward-firing transducers are oriented exactly perpendicular to the other transducers. In another embodiment, the ½ amplitude and phase (in-phase for the forward-facing array, and opposite-phase for the rearward-facing array) can be adjusted by e.g. tilting the upward-firing transducer slightly forward and the downward-firing transducer slightly backward, for example.

In other embodiments, the Bessel Dipole-speaker may be enhanced by the addition of, for example, a +1 forward-facing tweeter and a −1 rearward-facing tweeter, which would be particularly well-suited to be added to a dual 7-element Bessel dipole speaker. Or, a single tweeter could be added to the face (removed in the drawing) which is aimed into the listening space.

The 10-transducer Bessel Dipole speaker of FIG. 76, or the 8-transducer Bessel Dipole speaker of FIG. 77 may be constructed as a Super Bessel using a single inverting all-pass filter applied to a common pair of pos/neg inputs (not shown). The +1 drivers are fed directly by the inputs in parallel, and the −1 drivers are fed by the all-pass filter in parallel. Pairs of the ½ drivers (in FIG. 76) are wired in series and fed directly by the inputs; they may be paired within a single array (forward or rearward), or across the arrays (e.g. both top drivers) with the rearward driver wired backward to achieve its −½ value, but more preferentially they are paired within single arrays so the rearward −½ drivers can be fed by the all-pass filter. At low frequencies, all transducers are fed a +signal, thereby increasing the low frequency output and efficiency.

### Conclusion

The skilled reader will appreciate that the drawings are for illustrative purposes only, and are not scale models of optimized transducer systems.

While the invention has been described with reference to embodiments in which it is configured as an audio speaker, in other embodiments it may be configured as a microphone, or other such apparatus which may be characterized as an electroacoustic transducer.

While the invention has been described with reference to embodiments in which the transducers are of the electromagnetic type, it can equally well be practiced using transducers of the electrostatic or other types. Electromagnetic transducers, electrostatic transducers, piezoelectric transducers, and the like are collective termed electroacoustic transducers.

The term “square” should not be interpreted to limit the invention to e.g. 5×5 Bessel arrays, but should be interpreted to also cover e.g. 5×7 or 9×7 Bessel arrays or what have you.

Transducers need not be coupled to a common enclosure in order to function as a Bessel array. Indeed, low frequency performance will in many cases be improved if various ones of the transducers occupy separate enclosure volume(s) than other transducers. For example, it may generally not be ideal to have two “+1” transducers sharing an enclosure volume with a “−1” transducer, nor even with a “+½” transducer.

Although the various embodiments of the invention have been described with reference to implementations in which a single amplifier provides a signal to the Bessel circuit, the invention may just as readily be practiced in implementations in which various ones of the transducer signal paths are driven by separate amplifiers.

Although the invention has been described with reference to loudspeakers in which the multiple transducers are coupled to a single cabinet, the invention can just as easily be practiced in e.g. a modular speaker cabinet system in which subsets of the transducers are coupled to different cabinets. These multiple cabinets may then be stacked, rail mounted, or otherwise affixed such that the transducers are in the correct spacing and alignment.

For simplicity and consistency, the invention has mostly been described with respect to vertically oriented arrays of transducers, but may also be practiced with any other array orientation.

A left/right pair of loudspeakers may, in some cases, advantageously be constructed of a left Bessel array loudspeaker and a right Bessel array loudspeaker which are mirror images of each other (about the vertical axis).

7-Element, 9-Element, and other-Element Bessel arrays in which there exist one or more 0 positions may be generically termed “null-Element Bessel arrays”, distinguishing them from 5-Element and other-Element Bessel arrays in which all positions are occupied with active transducers. The latter may be generically termed “complete-Element Bessel arrays”. It should be noted that a “Reduced Bessel array” may be either null-Element or complete-Element; the omission of one of its transducers from a non-0 position (typically but not necessarily an end position) does not make it a null-Element Bessel array.

Although the Bessel soundbar has been described with reference to its use in conjunction with a television or display monitor, it could be used in other applications, as well.

Although the Bessel dipole has been described as being used as a surround channel loudspeaker, it could, of course, be used in other ways.

When one component is said to be “adjacent” another component, it should not be interpreted to mean that there is absolutely nothing between the two components, only that they are in the order indicated or that they are somehow connected. The various features illustrated in the figures may be combined in many ways, and should not be interpreted as though limited to the specific embodiments in which they were explained and shown. Those skilled in the art, having the benefit of this disclosure, will appreciate that many other variations from the foregoing description and drawings may be made within the scope of the present invention. Indeed, the invention is not limited to the details described above. Rather, it is the following claims including any amendments thereto that define the scope of the invention.

What is claimed is:

1. A loudspeaker comprising:
a Y-element first Bessel Array including X electroacoustic transducers disposed at X positions of the first Bessel Array, wherein X<Y such that the first Bessel Array includes X non-zero positions and Y-X zero positions, and wherein the Y-element first Bessel Array has a frequency range in which it operates in Bessel fashion; and
at least one sound-producing element each disposed at a respective one of the zero positions and having an operating frequency range substantially outside the frequency range in which the first Bessel Array operates in Bessel fashion.

2. The loudspeaker of claim 1 wherein the at least one sound-producing element comprises:
an MTM.

3. The loudspeaker of claim 2 wherein the MTM comprises:
at least one of (i) the Ms and (ii) the T of the MTM comprises a Bessel Array(s).

4. The loudspeaker of claim 3 wherein the MTM further comprises:
both the Ms and the T each comprises a Bessel Array.

5. The loudspeaker of claim 1 wherein the at least one sound-producing element comprises:
an X-element second Bessel Array.

6. The loudspeaker of claim 5 wherein:
the second Bessel Array is substantially collinear with the first Bessel Array.

7. The loudspeaker of claim 5 wherein:
the second Bessel Array is substantially perpendicular to the first Bessel Array.

8. The loudspeaker of claim 5 wherein:
the second Bessel Array is substantially diagonal to the first Bessel Array.

9. The loudspeaker of claim 5 wherein the at least one sound-producing element further comprising:
a Y-element third Bessel Array;
wherein a center Bessel position of the second Bessel Array and a center Bessel position of the third Bessel Array are disposed substantially at the zero position of the first Bessel Array.

10. The loudspeaker of claim 5 wherein the X-element second Bessel Array comprises:
a square Bessel Array.

11. The loudspeaker of claim 1 wherein the at least one sound-producing element comprises:
a port.

12. The loudspeaker of claim 1 wherein the at least one sound-producing element comprises:
a tweeter.

13. The loudspeaker of claim 1 further comprising:
circuitry coupled to at least one of the X electroacoustic transducers for altering at least one of a phase and an amplitude of output of the transducer outside the frequency range in which the first Bessel Array operates in Bessel fashion.

14. A 2-way Bessel Array loudspeaker comprising:
an enclosure;
X first electromagnetic transducers coupled to the enclosure at non-zero positions of a Y-element Bessel configuration, wherein each of the first electromagnetic transducers is adapted for producing sound in a first frequency range; and
at least one second electromagnetic transducer coupled to the enclosure at a zero position of the Y-element Bessel configuration, wherein each of the second electromagnetic transducers is adapted for producing sound above the first frequency range.

15. The 2-way Bessel Array of claim 14 wherein the at least one second electromagnetic transducer comprises:
M electromagnetic transducers coupled to the enclosure at non-zero positions of an N-element Bessel configuration.

16. The 2-way Bessel Array of claim 15 wherein:
the N-element Bessel configuration is substantially parallel to the Y-element Bessel configuration.

17. The 2-way Bessel Array of claim 15 wherein:
the N-element Bessel configuration is substantially diagonal to the Y-element Bessel configuration.

18. The 2-way Bessel Array of claim 15 wherein:
the N-element Bessel configuration is substantially perpendicular to the Y-element Bessel configuration.

19. The 2-way Bessel Array of claim 14 wherein the at least one second electromagnetic transducer further comprises:
a third electroacoustic transducer coupled to the enclosure and adapted for producing sound above a frequency range in which the M electromagnetic transducers operate in Bessel fashion;
whereby the 2-way Bessel Array is further a 3 -way Bessel Array.

20. A loudspeaker comprising:
an enclosure;
a null-element first Bessel Array of transducers coupled to the enclosure;
a second Bessel Array of transducers coupled to the enclosure substantially at a zero position of the null-element first Bessel Array;
wherein the second Bessel Array of transducers operates in a frequency range higher than a frequency range in which the first Bessel Array of transducers operates.

21. The loudspeaker of claim 20 wherein:
the transducers of the first Bessel Array each comprises a woofer having an effective Sd of at least 9 inches in diameter; and
the transducers of the second Bessel Array each comprises a driver having an effective Sd of less than 2.5 inches in diameter.

22. The loudspeaker of claim 20 further comprising:
a third transducer coupled to the enclosure substantially at a zero position of the second Bessel Array of transducers;
wherein the third transducer operates in a frequency range higher than the frequency range in which the second Bessel Array of transducers operates.

23. The loudspeaker of claim 20 further comprising:
a third Bessel Array of transducers coupled to the enclosure substantially at a zero position of the second Bessel Array of transducers;
wherein the third Bessel Array of transducers operates in a frequency range higher than the frequency range in which the second Bessel Array of transducers operates.
